(19) United States
(12) Patent Application Publication
(10) Pub. No.: US 2023/0132685 A1
(43) Pub. Date: May 4, 2023

(54) ORGANIC ELECTROLUMINESCENT ELEMENT AND FUSED POLYCYCLIC COMPOUND FOR ORGANIC ELECTROLUMINESCENT ELEMENT

(71) Applicant: Samsung Display Co., Ltd., Yongin-si (KR)

(72) Inventors: SUN YOUNG PAK, Suwon-si (KR); TAEIL KIM, Hwaseong-si (KR); JUNHA PARK, Gwacheon-si (KR); JANG YEOL BAEK, Yongin-si (KR); Kyoung SUNWOO, Hwaseong-si (KR); MUN-KI SIM, Seoul (KR); CHANSEOK OH, Seoul (KR); MINJUNG JUNG, Hongcheon-gun (KR)

(21) Appl. No.: 17/805,794

(22) Filed: Jun. 7, 2022

(30) Foreign Application Priority Data
Aug. 24, 2021 (KR) 10-2021-0111762

(51) Int. Cl. C07F 5/02; H01L 51/00

(52) U.S. Cl. CPC C07F 5/027; H01L 51/0064; H01L 51/0067; H01L 51/0071; H01L 51/0072; H01L 51/0073; H01L 51/0074; H01L 51/008; H01L 51/5275

(57) ABSTRACT

An organic electroluminescent element of an embodiment includes an oppositely disposed first electrode and second electrode, and multiple organic layers disposed between the first electrode and the second electrode, wherein at least one among the organic layers includes a fused polycyclic compound represented by Formula 1, thereby showing improved emission efficiency:

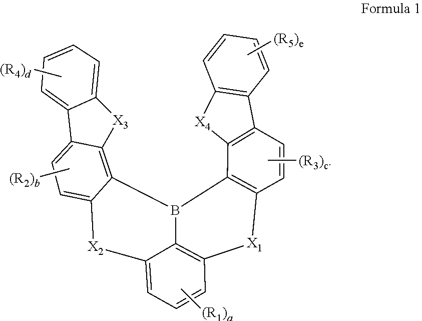

### CROSS-REFERENCE TO RELATED APPLICATIONS

This application claims priority to and the benefit of Korean Patent Application No. 10-2021-0111762, filed on Aug. 24, 2021, the entire content of which is incorporated herein by reference.

### BACKGROUND

### 1. Field

One or more aspects of embodiments of the present disclosure relate to an organic electroluminescent element, and for example, to an organic electroluminescent element including a fused polycyclic compound as a light-emitting material.

### 2. Description of the Related Art

Organic electroluminescence displays are being actively developed as image displays. The organic electroluminescence display is different from a liquid crystal display and is so-called a self-luminescent display, in which holes and electrons injected from a first electrode and a second electrode recombine in an emission layer so that a light-emitting material including an organic compound in the emission layer emits light to achieve display.

In the application of an organic electroluminescent element to a display, a decreased driving voltage, and increased emission efficiency and/or life (life span) of the organic electroluminescent element are desired, and improved materials for an organic electroluminescent element stably achieving such requirements are desired.

For example, in order to achieve an organic electroluminescent element with high efficiency, materials capable of phosphorescence emission (which uses energy in a triplet state), delayed fluorescence emission (which uses the generating phenomenon of singlet excitons by the collision of triplet excitons (triplet-triplet annihilation, TTA)), or thermally activated delayed fluorescence (TADF) are recently being developed.

### SUMMARY

One or more aspects of embodiments of the present disclosure are directed toward an organic electroluminescent element with improved emission efficiency.

One or more embodiments of the present disclosure provide an organic electroluminescent element including a first electrode, a hole transport region provided on the first electrode, an emission layer provided on the hole transport region, an electron transport region provided on the emission layer, and a second electrode provided on the electron transport region, wherein the hole transport region includes an amine compound represented by Formula H-1, and the emission layer includes a fused polycyclic compound represented by Formula 1.

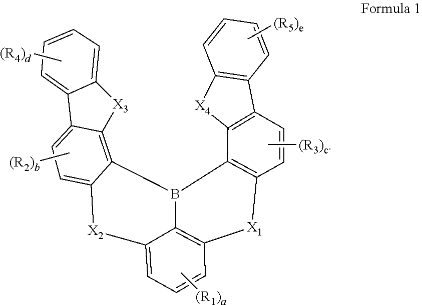

In Formula 1, X₁ to X₄ may each independently be CRₐ₁Rₐ₂, NRₐ₃, O, S, or Se; R₁ to R₅ and Rₐ₁ to Rₐ₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; “a” may be an integer of 0 to 3; “b” and “c” may each independently be an integer of 0 to 2; and “d” and “e” may each independently be an integer of 0 to 4.

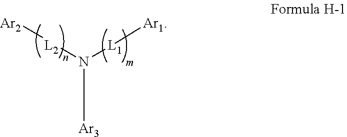

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms; “m” and “n” may each independently be an integer of 0 to 10; Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms; and Ar₃ is a substituted or unsubstituted aryl group of 6 to 30 ring-forming carbon atoms.

In an embodiment, the emission layer may be to emit delayed fluorescence.

In an embodiment, the emission layer may include a host and a dopant, and the dopant may include the fused polycyclic compound represented by Formula 1.

In an embodiment, the hole transport region may include a hole injection layer disposed on the first electrode and a hole transport layer disposed on the hole injection layer, and the hole transport layer may include the amine compound represented by Formula H-1.

In an embodiment, the hole transport region may further include an electron blocking layer disposed on the hole transport layer.

In an embodiment, the organic electroluminescent element may further include a capping layer disposed on the second electrode and having a refractive index of about 1.6 or more.

In an embodiment, X₁ and X₂ may be the same.

In an embodiment, “b” and “c” may be integers of 1 or more; and R₂ and R₃ may each independently be a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 1 may be represented by Formula 2.

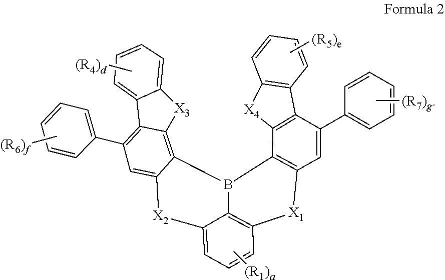

In Formula 2, R₆ and R₇ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, “f” and “g” may each independently be an integer of 0 to 5, and X₁ to X₄, R₁, R₄, R₅, “a”, “d”, and “e” may each independently be the same as defined in Formula 1.

In an embodiment, the fused polycyclic compound represented by Formula 2 may be represented by Formula 3.

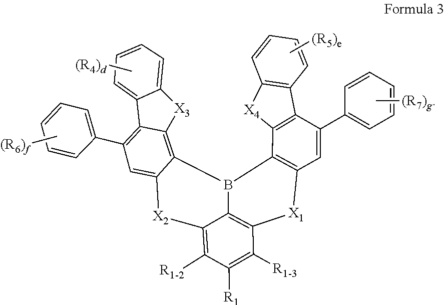

In Formula 3, R₁ is a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; R₁₋₂ and R₁₋₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; and X₁ to X₄, R₄ to R₇, and “d” to “g” may each independently be the same as defined in Formula 2.

In an embodiment, R₁₋₂ and R₁₋₃ may each independently be a hydrogen atom; and R₁ may be a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 3 may be represented by Formula 4.

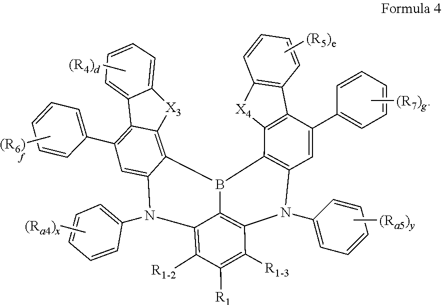

In Formula 4, Rₐ₄ and Rₐ₅ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; “x” and “y” may each independently be an integer of 0 to 5, and X₃, X₄, R₁, R₁₋₂, R₁₋₃, R₄ to R₇, and “d” to “g” may each independently be the same as defined in Formula 3.

One or more embodiments of the present disclosure provide a fused polycyclic compound represented by Formula 1.

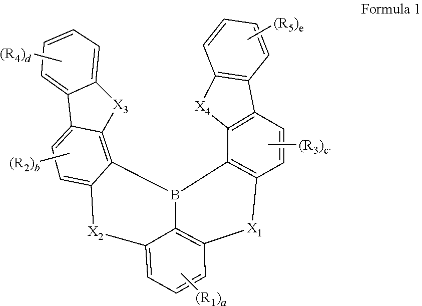

In Formula 1, X₁ to X₄ may each independently be CRₐ₁Rₐ₂, NRₐ₃, O, S, or Se; R₁ to R₅ and Rₐ₁ to Rₐ₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; “a” may be an integer of 0 to 3; “b” and “c” may each independently be an integer of 0 to 2; and “d” and “e” may each independently be an integer of 0 to 4.

In an embodiment, “b” and “c” may be integers of 1 or more; and R₂ and R₃ may each independently be a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 1 may be represented by Formula 2.

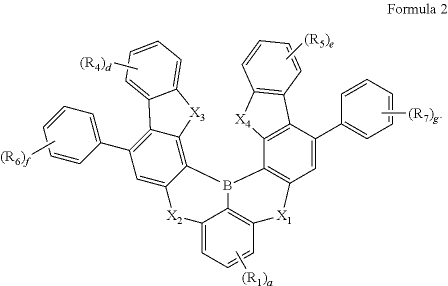

In Formula 2, R₆ and R₇ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; “f” and “g” may each independently be an integer of 0 to 5; and X₁ to X₄, R₁, R₄, R₅, “a”, “d”, and “e” may each independently be the same as defined in Formula 1.

In an embodiment, the fused polycyclic compound represented by Formula 2 may be represented by Formula 3.

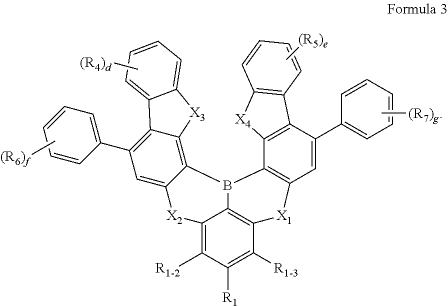

In Formula 3, R₁ may be a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; R₁₋₂ and R₁₋₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; and X₁ to X₄, R₄ to R₇, and “d” to “g” may each independently be the same as defined in Formula 2.

In an embodiment, R₁₋₂ and R₁₋₃ may each independently be a hydrogen atom; and R₁ may be a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 3 may be represented by Formula 4.

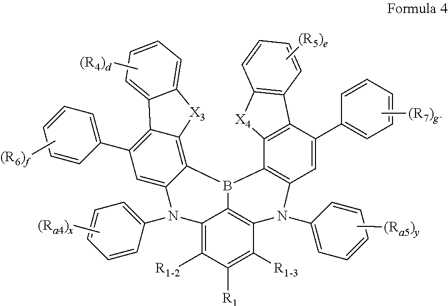

In Formula 4, Rₐ₄ and Rₐ₅ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; “x” and “y” may each independently be an integer of 0 to 5; and X₃, X₄, R₁, R₁₋₂, R₁₋₃, R₄ to R₇, and “d” to “g” may each independently be the same as defined in Formula 3.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus according to an embodiment of the present disclosure;

FIG. 2 is a cross-sectional view showing a display apparatus according to an embodiment of the present disclosure;

FIG. 3 is a cross-sectional view schematically showing an organic electroluminescent element according to an embodiment of the present disclosure;

FIG. 4 is a cross-sectional view schematically showing an organic electroluminescent element according to an embodiment of the present disclosure;

FIG. 5 is a cross-sectional view schematically showing an organic electroluminescent element according to an embodiment of the present disclosure;

FIG. 6 is a cross-sectional view schematically showing an organic electroluminescent element according to an embodiment of the present disclosure;

FIG. 7 is a cross-sectional view showing a display apparatus according to an embodiment of the present disclosure; and

FIG. 8 is a cross-sectional view showing a display apparatus according to an embodiment of the present disclosure.

### DETAILED DESCRIPTION

The present disclosure may have various suitable modifications and may be embodied in different forms, and example embodiments will be explained in more detail with reference to the accompany drawings. The present disclosure may, however, be embodied in different forms and should not be construed as being limited to the embodiments set forth herein. Rather, all modifications, equivalents, and substituents within the spirit and technical scope of the present disclosure should be included in the present disclosure.

In the description, it will be understood that when an element (or region, layer, part, etc.) is referred to as being “on”, “connected to” or “coupled to” another element, it can be directly on, connected or coupled to the other element or intervening elements may be present. When an element is referred to as being “directly on,” “directly connected to,” or “directly coupled to” another element, there are no intervening elements present.

Like reference numerals refer to like elements throughout, and duplicative descriptions thereof may not be provided. In the drawings, thicknesses, ratios, and dimensions of constituent elements may be exaggerated for effective explanation of technical contents.

The term “and/or” includes one or more combinations which may be defined by relevant elements.

It will be understood that, although the terms first, second, etc. may be used herein to describe various elements, these elements should not be limited by these terms. These terms are only used to distinguish one element from another element.

For example, a first element could be termed a second element without departing from the teachings of the present disclosure. Similarly, a second element could be termed a first element. As used herein, singular forms such as “a,” “an,” and “the” are intended to include the plural forms as well, unless the context clearly indicates otherwise.

The terms “below”, “beneath”, “on” and “above” are used to explain spatial relationships between elements shown in the drawings. The terms are relative concepts and are selected on the basis of the directions shown in the drawing.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes,” “including,” “comprises,” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

As used herein, expressions such as “at least one of,” “one of,” and “selected from,” when preceding a list of elements, modify the entire list of elements and do not modify the individual elements of the list. For example, the expressions “at least one of a, b and c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items. The term “may” will be understood to refer to “one or more embodiments,” some of which include the described element and some of which exclude that element and/or include an alternate element. Similarly, alternative language such as “or” refers to “one or more embodiments,” each including a corresponding listed item.

Hereinafter, an organic electroluminescent element according to an embodiment of the present disclosure will be explained referring to the drawings.

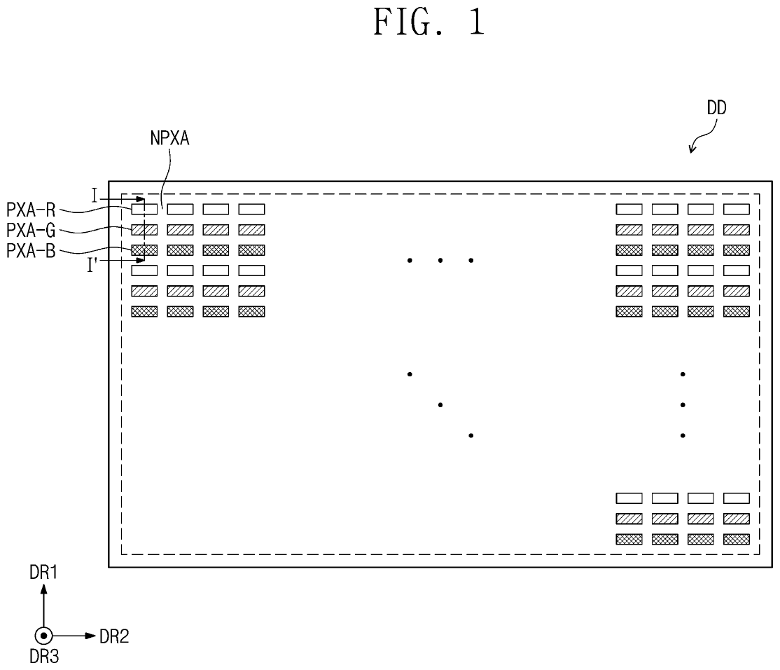

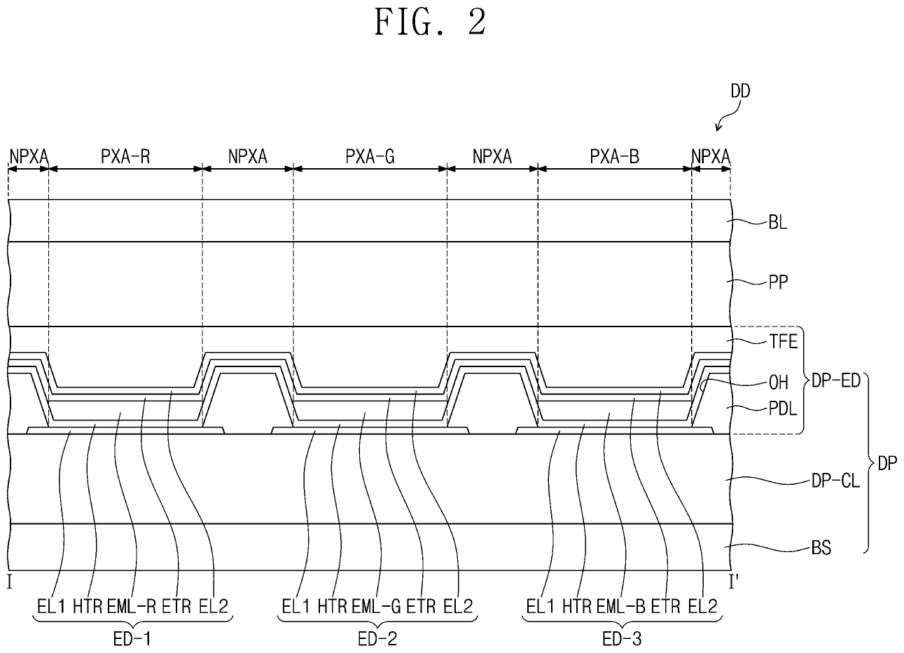

FIG. 1 is a plan view showing an embodiment of a display apparatus DD. FIG. 2 is a cross-sectional view of a display apparatus DD of an embodiment. FIG. 2 is a cross-sectional view showing a part corresponding to line I-I′.

The display apparatus DD may include a display panel DP and an optical layer PP disposed on the display panel DP. The display panel DP includes organic electroluminescent elements ED-1, ED-2, and ED-3. The display apparatus DD may include multiple organic electroluminescent elements ED-1, ED-2, and ED-3. The optical layer PP may be disposed on the display panel DP and may control or attenuate reflected external light at the display panel DP. The optical layer PP may include, for example, a polarization layer and/or a color filter layer. In some embodiments, the optical layer PP may not be provided in the display apparatus DD of an embodiment.

On the optical layer PP, a base substrate BL may be disposed. The base substrate BL may provide a base (e.g., planarized) surface where the optical layer PP is disposed. The base substrate BL may be a glass substrate, a metal substrate, a plastic substrate, etc. However, embodiments of the present disclosure are not limited thereto, and for example the base substrate BL may be an inorganic layer, an organic layer, or a composite material layer. In some embodiments, the base substrate BL may not be provided.

The display apparatus DD according to an embodiment may further include a plugging layer. The plugging layer may be disposed between a display device layer DP-ED and a base substrate BL. The plugging layer may be an organic layer. The plugging layer may include at least one among an acrylic resin, a silicon-based resin, and an epoxy-based resin.

The display panel DP may include a base layer BS, a circuit layer DP-CL provided on the base layer BS, and a display device layer DP-ED. The display device layer DP-ED may include a pixel definition layer PDL, organic electroluminescent elements ED-1, ED-2, and ED-3 disposed in the pixel definition layer PDL, and an encapsulating layer TFE disposed on the organic electroluminescent elements ED-1, ED-2, and ED-3.

The base layer BS may provide a base (e.g., planarized) surface where the display device layer DP-ED is disposed. The base layer BS may be a glass substrate, a metal substrate, a plastic substrate, etc. However, embodiments of the present disclosure are not limited thereto, and the base layer BS may be an inorganic layer, an organic layer or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the organic electroluminescent elements ED-1, ED-2, and ED-3 of the display device layer DP-ED.

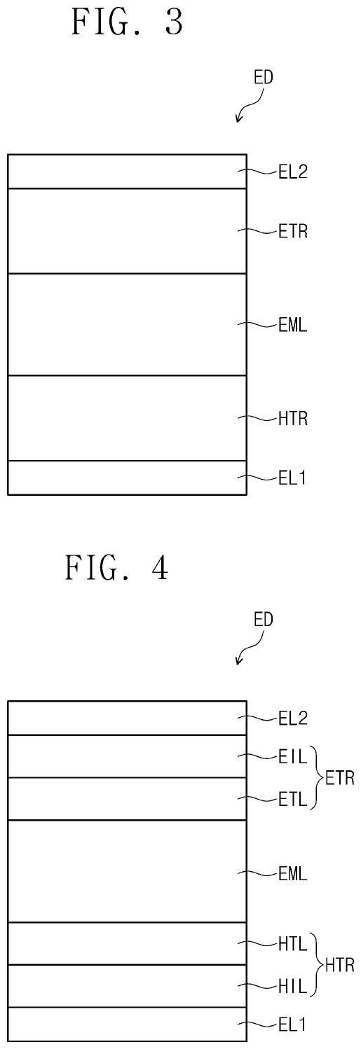

Each of the organic electroluminescent elements ED-1, ED-2, and ED-3 may have the structures of organic electroluminescent elements ED of embodiments according to FIG. 3 to FIG. 6, which will be further described herein below. Each of the organic electroluminescent elements ED-1, ED-2, and ED-3 may include a first electrode EL1, a hole transport region HTR, emission layers EML-R, EML-G, and EML-B, an electron transport region ETR and a second electrode EL2.

In FIG. 2, shown is an embodiment where the emission layers EML-R, EML-G, and EML-B of organic electroluminescent elements ED-1, ED-2, and ED-3, which are in opening portions OH defined in a pixel definition layer PDL, are disposed, and a hole transport region HTR, an electron transport region ETR and a second electrode EL2 are provided as common layers in all organic electroluminescent elements ED-1, ED-2, and ED-3. However, embodiments of the present disclosure are not limited thereto. In some embodiments, the hole transport region HTR and the electron transport region ETR may be patterned and provided in each of the opening portions OH defined in the pixel definition layer PDL. For example, in an embodiment, the hole transport region HTR, the emission layers EML-R, EML-G, and EML-B, and the electron transport region ETR of the organic electroluminescent elements ED-1, ED-2, and ED-3 may be patterned by an ink jet printing method and provided.

An encapsulating layer TFE may cover the organic electroluminescent elements ED-1, ED-2, and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE may include at least one organic layer (hereinafter, encapsulating organic layer) and at least one encapsulating inorganic layer.

The encapsulating inorganic layer may protect the display device layer DP-ED from moisture/oxygen, and the encapsulating organic layer may protect the display device layer DP-ED from foreign materials (such as dust particles). The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display apparatus DD may include a non-luminous area NPXA and luminous areas PXA-R, PXA-G, and PXA-B. The luminous areas PXA-R, PXA-G, and PXA-B may be to emit light produced from the organic electroluminescent elements ED-1, ED-2, and ED-3, respectively. The luminous areas PXA-R, PXA-G, and PXA-B may be separated from each other in a plane (e.g., the plane defined by the directions DR1 and DR2).

The luminous areas PXA-R, PXA-G, and PXA-B may be separated from each other by the pixel definition layer PDL. The non-luminous areas NPXA may be areas between neighboring luminous areas PXA-R, PXA-G, and PXA-B, and may correspond to the pixel definition layer PDL. In some embodiments, each of the luminous areas PXA-R, PXA-G, and PXA-B may correspond to a pixel. The pixel definition layer PDL may divide the organic electroluminescent elements ED-1, ED-2, and ED-3. The emission layers EML-R, EML-G, and EML-B of the organic electroluminescent elements ED-1, ED-2, and ED-3 may be disposed and divided in the opening portions OH defined in the pixel definition layer PDL.

The luminous areas PXA-R, PXA-G, and PXA-B may be divided into multiple groups according to the color of light produced from the organic electroluminescent elements ED-1, ED-2, and ED-3. In the display apparatus DD of an embodiment, shown in FIG. 1 and FIG. 2, three luminous areas PXA-R, PXA-G, and PXA-B emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple organic electroluminescent elements ED-1, ED-2, and ED-3 may be to emit light having different wavelength regions. For example, in an embodiment, the display apparatus DD may include a first organic electroluminescent element ED-1 to emit red light, a second organic electroluminescent element ED-2 to emit green light, and a third organic electroluminescent element ED-3 to emit blue light. For example, the red luminous area PXA-R, the green luminous area PXA-G, and the blue luminous area PXA-B of the display apparatus DD may correspond to the first organic electroluminescent element ED-1, the second organic electroluminescent element ED-2, and the third organic electroluminescent element ED-3, respectively.

However, embodiments of the present disclosure are not limited thereto, and the first to third organic electroluminescent elements ED-1, ED-2, and ED-3 may be to emit light in substantially the same wavelength region, or at least one thereof may be to emit light in a different wavelength region. For example, all the first to third organic electroluminescent elements ED-1, ED-2, and ED-3 may be to emit blue light.

The luminous areas PXA-R, PXA-G, and PXA-B in the display apparatus DD according to an embodiment may be arranged in a stripe shape. Referring to FIG. 1, multiple red luminous areas PXA-R, multiple green luminous areas PXA-G and multiple blue luminous areas PXA-B may be arranged with each other along a second direction axis DR2. In some embodiments, the red luminous area PXA-R, the green luminous area PXA-G and the blue luminous area PXA-B may be arranged by turns (e.g., alternatingly with each other) along a first direction axis DR1.

In FIG. 1 and FIG. 2, the areas of the luminous areas PXA-R, PXA-G, and PXA-B are shown as being similar, but embodiments of the present disclosure are not limited thereto. The areas of the luminous areas PXA-R, PXA-G and PXA-B may be selected to be different from each other according to the wavelength region of light emitted. As referred to herein, the areas of the luminous areas PXA-R, PXA-G, and PXA-B may be areas within the plane defined by the first direction axis DR1 and the second direction axis DR2.

The arrangement type or pattern of the luminous areas PXA-R, PXA-G, and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required for the display apparatus DD. For example, the arrangement type or pattern of the luminous areas PXA-R, PXA-G, and PXA-B may be a PENTILE© arrangement (e.g., an RGBG matrix, RGBG structure, or RGBG matrix structure), or a diamond arrangement type or pattern. PENTILE© is a duly registered trademark of Samsung Display Co., Ltd.

In some embodiments, the areas (planar areas) of the luminous areas PXA-R, PXA-G, and PXA-B may be different from each other. For example, in an embodiment, the area of the green luminous area PXA-G may be smaller than the area of the blue luminous area PXA-B, but embodiments of the present disclosure are not limited thereto.

Hereinafter, FIG. 3 to FIG. 6 are cross-sectional views schematically showing organic electroluminescent elements according to embodiments. In the organic electroluminescent element ED of an embodiment, a first electrode EL1 and a second electrode EL2 are oppositely disposed, and between the first electrode EL1 and the second electrode EL2, multiple organic layers may be disposed. Multiple organic layers may include a hole transport region HTR, an emission layer EML, and an electron transport region ETR. For example, the organic electroluminescent element ED according to an embodiment may include a first electrode EL1, a hole transport region HTR, an emission layer EML, an electron transport region ETR, and a second electrode EL2 stacked in order.

The organic electroluminescent element ED of an embodiment may include a fused polycyclic compound of an embodiment, which will be further described herein below, in at least one organic layer among the multiple organic layers disposed between the first electrode EL1 and the second electrode EL2. For example, the organic electroluminescent element ED of an embodiment may include a fused polycyclic compound of an embodiment, which will be further described herein below, in an emission layer EML disposed between the first electrode EL1 and the second electrode EL2. However, embodiments of the present disclosure are not limited thereto. The organic electroluminescent element ED of an embodiment may include the fused polycyclic compound according to an embodiment, which will be further described herein below, in at least one organic layer included in a hole transport region HTR and an electron transport region ETR (which are multiple organic layers disposed between the first electrode EL1 and the second electrode EL2 in addition to the emission layer EML), or may include the fused polycyclic compound according to an embodiment, which will be further described herein below, in a capping layer CPL disposed on the second electrode EL2.

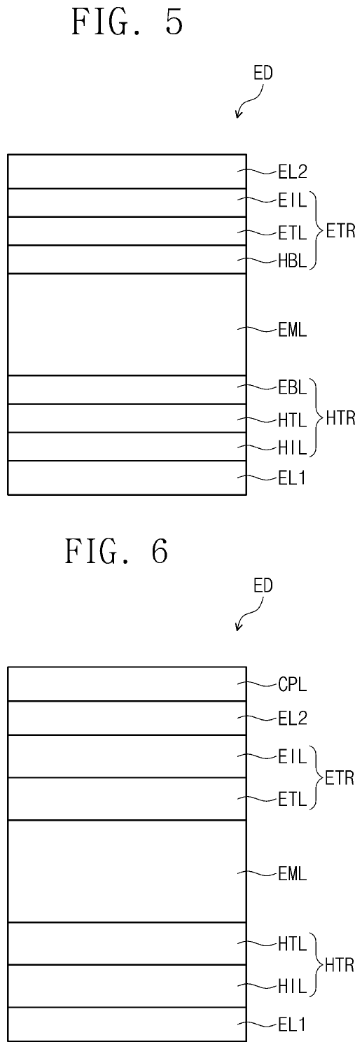

Compared to FIG. 3, FIG. 4 shows a cross-sectional view of an organic electroluminescent element ED of an embodiment, in which the hole transport region HTR includes a hole injection layer HIL and a hole transport layer HTL, and the electron transport region ETR includes an electron injection layer EIL and an electron transport layer ETL. Compared to FIG. 3, FIG. 5 shows the cross-sectional view of an organic electroluminescent element ED of an embodiment, in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. Compared to FIG. 4, FIG. 6 shows the cross-sectional view of an organic electroluminescent element ED of an embodiment, including a capping layer CPL disposed on a second electrode EL2.

Hereinafter, the emission layer EML of the organic electroluminescent element ED will be explained to include the fused polycyclic compound according to an embodiment, which will be further described herein below, but embodiments of the present disclosure are not limited thereto. The fused polycyclic compound according to an embodiment, which will be further described herein below, may be included in a hole transport region HTR, an electron transport region ETR, and/or a capping layer CPL.

In some embodiments, in the description, the term “substituted or unsubstituted” corresponds to a state of being unsubstituted, or substituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boryl group, a phosphine oxide group, a phosphine sulfide group, an alkyl group, an alkenyl group, an alkoxy group, a hydrocarbon ring group, an aryl group, and a heterocyclic group. Each of the exemplified substituents may be substituted or unsubstituted. For example, a biphenyl group may be interpreted as a named aryl group, or as a phenyl group substituted with a phenyl group.

In the description, the term “halogen atom” may include a fluorine atom, a chlorine atom, a bromine atom or an iodine atom.

In the description, the term “alkyl group” may include a linear, branched or cyclic group. The carbon number of the alkyl group may be 1 to 50, 1 to 30, 1 to 20, 1 to 10, or 1 to 6. Examples of the alkyl group may be or include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, the term “alkenyl group” refers to a hydrocarbon group including one or more carbon (carbon-carbon) double bonds in the middle or at the terminal end of an alkyl group including two or more carbon atoms. The alkenyl group may be a linear chain or a branched chain. The carbon number is not specifically limited but may be 2 to 30, 2 to 20, or 2 to 10. Examples of the alkenyl group may be or include a vinyl group, a 1-butenyl group, a 1-pentenyl group, a 1,3-butadienyl aryl group, a styrenyl group, a styrylvinyl group, etc., without limitation.

In the description, the term “alkynyl group” refers to a hydrocarbon group including one or more carbon (carbon-carbon) triple bonds in the middle or at the terminal end of an alkyl group including two or more carbon atoms. The alkynyl group may be a linear chain or a branched chain. The carbon number is not specifically limited but may be 2 to 30, 2 to 20, or 2 to 10. Examples of the alkynyl group may be or include an ethynyl group, a propynyl group, etc., without limitation.

In the description, the term “hydrocarbon ring” refers to a functional group or substituent derived from an aliphatic hydrocarbon ring or n functional group or substituent derived from an aromatic hydrocarbon ring. The carbon number for forming rings of the hydrocarbon ring may be 5 to 60, 6 to 30, or 5 to 20.

In the description, the term “aryl group” refers to a functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may be or include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a fluorenyl group may be substituted, and two substituents (e.g., at the 9H-position) may be combined with each other to form a spiro structure.

Examples of cases where the fluorenyl group is substituted are as follows. However, embodiments of the present disclosure are not limited thereto.

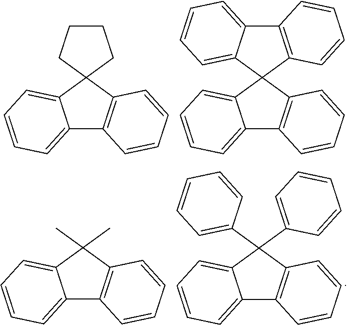

In the description, the term “heterocyclic group” refers to a functional group or substituent derived from a ring including one or more among B, O, N, P, Si, and S as heteroatoms. The term “heterocyclic group” includes an aliphatic heterocyclic group and an aromatic heterocyclic group. The aromatic heterocyclic group may be a heteroaryl group. The aliphatic heterocycle and aromatic heterocycle may each independently be a monocycle or a polycycle.

In the description, the term “heterocyclic group” may include one or more among B, O, N, P, Si, and S as heteroatoms. When the heterocyclic group includes two or more heteroatoms, the two or more heteroatoms may be the same or different.

The heterocyclic group may be a monocyclic heterocyclic group or a polycyclic heterocyclic group and in some embodiments may be a heteroaryl group. The carbon number for forming rings of the heterocyclic group may be 2 to 30, 2 to 20, or 2 to 10.

In the description, a heteroaryl group may include one or more among B, O, N, P, Si, and S as heteroatoms. When the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may be or include thiophene, furan, pyrrole, imidazole, triazole, pyridine, bipyridine, pyrimidine, pyrazine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isoxazole, oxazole, oxadiazole, thiadiazole, phenothiazine, dibenzosilole, dibenzofuran, etc., without limitation.

In the description, the term “silyl group” includes an alkyl silyl group and an aryl silyl group. Examples of the silyl group may be or include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the term “thio group” may include an alkyl thio group and an aryl thio group. The term “thio group” may refer to the above-defined alkyl group or aryl group combined with a sulfur atom. Examples of the thio group may be or include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, the term “oxy group” may refer to the above-defined alkyl group or aryl group combined with an oxygen atom. The oxy group may be or include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may be or include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, a carbon number of the amine group is not specifically limited, but may be 1 to 30. The amine group may be or include an alkyl amine group, an aryl amine group or a heteroaryl amine group. Examples of the amine group may be or include a methylamine group, a dimethylamine group, a phenylamine group, a diphenylamine group, a naphthylamine group, a 9-methyl-anthracenylamine group, etc., without limitation.

In the description, the alkyl group(s) in an alkyl silyl group, an alkyl thio group, an alkyl aryl group, and/or an alkyl amine group is (are) the same as the above-described alkyl group.

In the description, the aryl group(s) in an aryl oxy group, an aryl thio group, an aryl amine group and an aryl silyl group is (are) the same as the above-described aryl group.

In the description, a “direct linkage” may refer to a single bond.

A first electrode EL1 has conductivity (e.g., is a conductor). The first electrode EL1 may be formed utilizing a metal material, a metal alloy or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. When the first electrode EL1 is a transmissive electrode, the first electrode EL1 may include a transparent metal oxide (such as indium tin oxide (ITO), indium zinc oxide (IZO), zinc oxide (ZnO), and/or indium tin zinc oxide (ITZO)). When the first electrode EL1 is a transflective electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), tungsten (W), compounds thereof, or mixtures thereof (for example, a mixture of Ag and Mg). In some embodiments, the first electrode EL1 may have a structure of multiple layers including a reflective layer or a transflective layer formed utilizing the above materials, and a transmissive conductive layer formed utilizing ITO, IZO, ZnO, or ITZO. For example, the first electrode EL1 may include a three-layer structure of ITO/Ag/ITO.

However, embodiments of the present disclosure are not limited thereto. The first electrode EL1 may include the above-described metal materials, combinations of two or more metal materials selected from the above-described metal materials, or oxides of the above-described metal materials. The thickness of the first electrode EL1 may be about 700 Å to about 10,000 Å. For example, the thickness of the first electrode EL1 may be about 1,000 Å to about 3,000 Å.

A hole transport region HTR is provided on the first electrode EL1. The hole transport region HTR may include at least one among a hole injection layer HIL, a hole transport layer HTL, a buffer layer, an emission auxiliary layer, and an electron blocking layer EBL. The thickness of the hole transport region HTR may be about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, or may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods (such as a vacuum deposition method, a spin coating method, a cast method, a Langmuir-Blodgett (LB) method, an inkjet printing method, a laser printing method, and/or a laser induced thermal imaging (LITI) method).

The hole transport region HTR may include a compound represented by Formula H-1. For example, in the case where the hole transport region HTR includes a hole injection layer HIL and a hole transport layer HTL, the hole transport layer HTL may include a compound represented by Formula H-1.

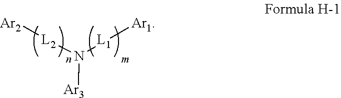

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “m” and “n” may each independently be an integer of 0 to 10. When “m” or “n” is an integer of 2 or more, the multiple L₁ or L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. Ar₃ may be a substituted or unsubstituted aryl group of 6 to 30 ring-forming carbon atoms. In an embodiment, Ar₃ may be a substituted or unsubstituted phenyl group, a substituted or unsubstituted naphthyl group, a substituted or unsubstituted biphenyl group, a substituted or unsubstituted triphenyl group, or a substituted or unsubstituted fluorenyl group.

The compound represented by Formula H-1 may be a monoamine compound (e.g., may include only one amine group). In some embodiments, the compound represented by Formula H-1 may be a diamine compound (e.g., including two amine groups) where at least one among Ar₁ to Ar₃ includes an amine group as a substituent. In some embodiments, the compound represented by Formula H-1 may be a carbazole-based compound in which at least one among Ar₁ and Ar₂ includes a substituted or unsubstituted carbazole group, or may be a fluorene-based compound in which at least one among Ar₁ and Ar₂ includes a substituted or unsubstituted fluorene group.

The compound represented by Formula H-1 may be represented by any one among the compounds in Compound Group H. However, the compounds shown in Compound Group H are only example illustrations, and the compound represented by Formula H-1 is not limited to the compounds represented in Compound Group H.

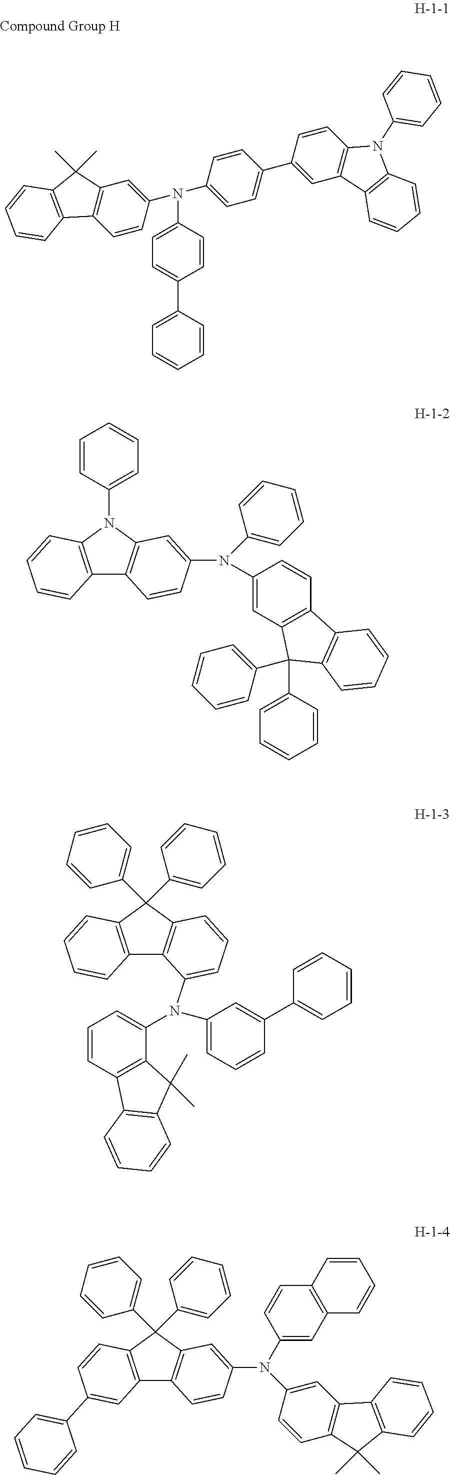 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

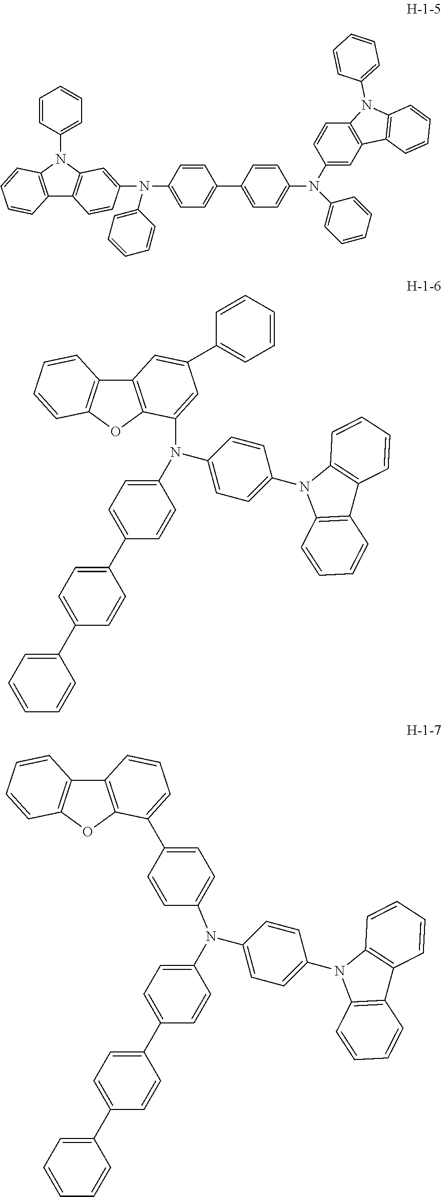

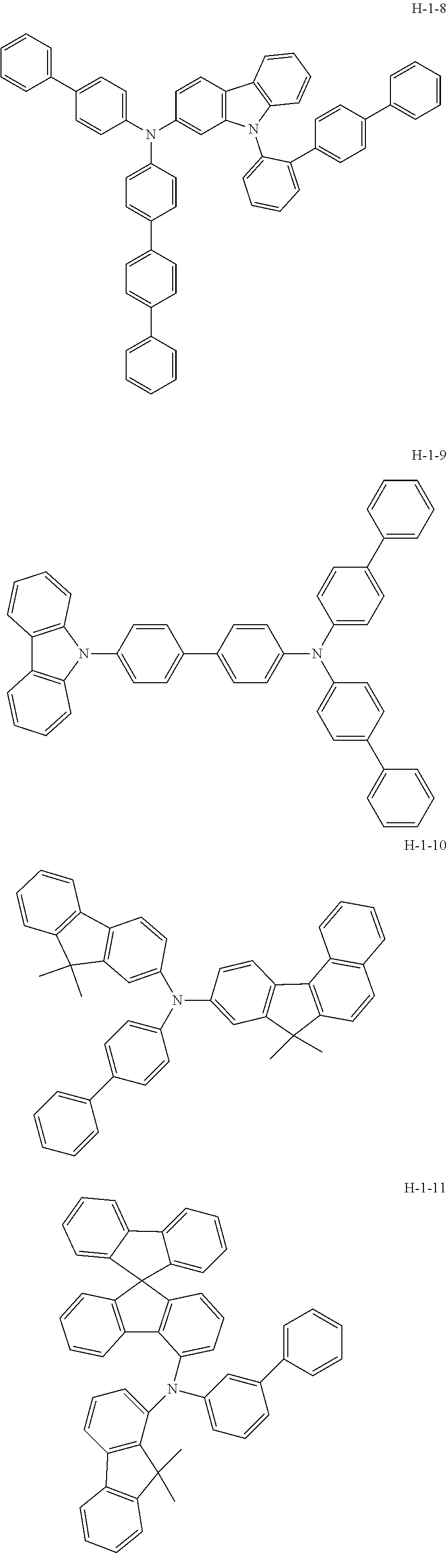

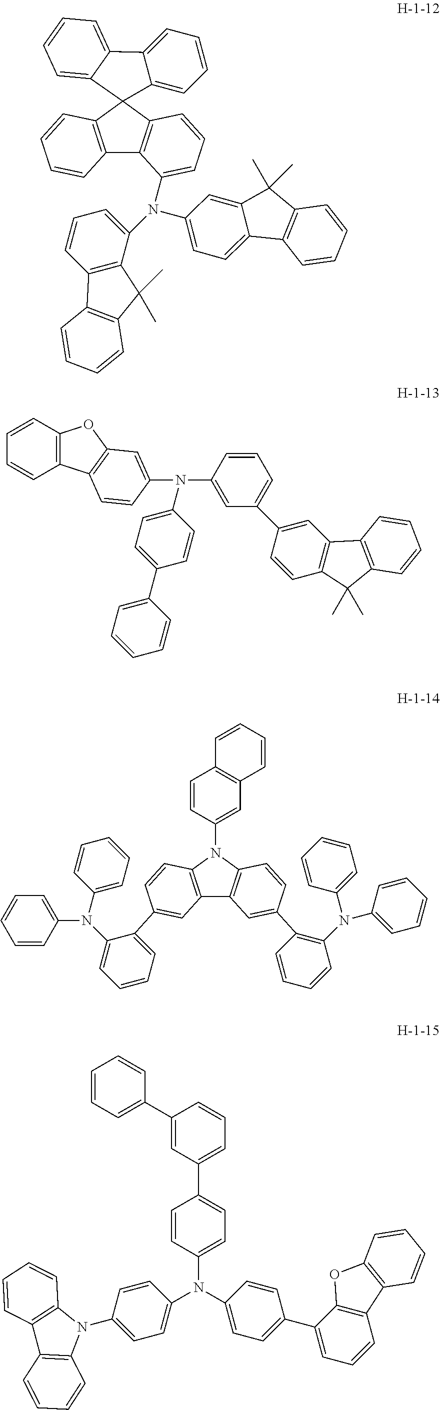 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

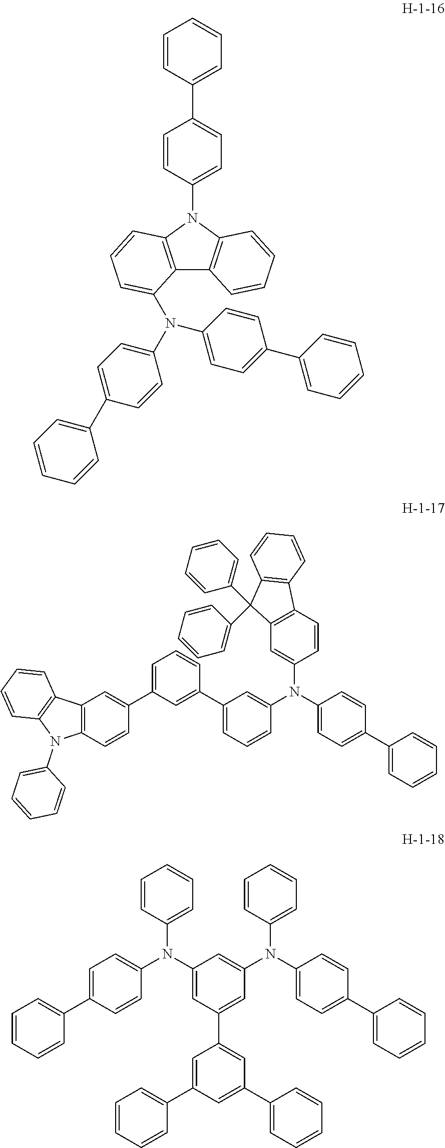 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

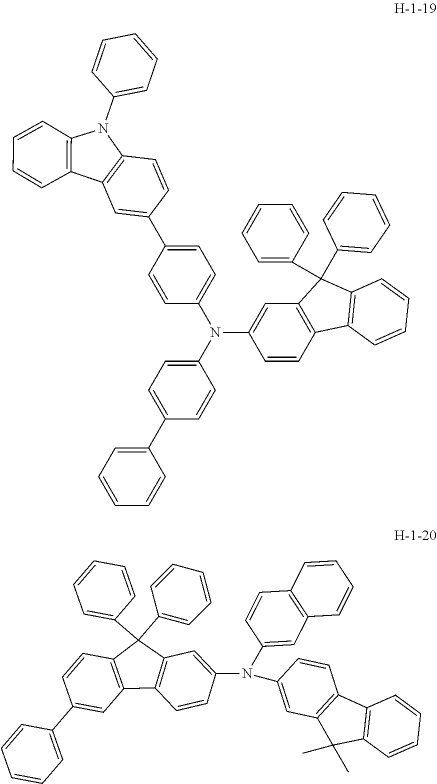 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

The hole transport region HTR may include a phthalocyanine compound (such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylene dioxythiophene)/poly(4-styrene sulfonate) (PEDOT/PSS), polyaniline/dodecylbenzene sulfonic acid (PANI/DBSA), polyaniline/camphor sulfonic acid (PANI/CSA), polyaniline/poly(4-styrene sulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HATCN)).

The hole transport region HTR may include carbazole derivatives (such as N-phenyl carbazole and/or polyvinyl carbazole), fluorene-based derivatives, N,N′-bis(3-methylphenyl)-N,N′-diphenyl-[1,1′-biphenyl]-4,4′-diamine (TPD), triphenylamine-based derivatives (such as 4,4′,4″-tris(N-carbazolyl)triphenylamine (TCTA)), 4,4′-cyclohexylidene bis[N,N-bis(4-methylphenyl)benzeneamine (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one among the hole injection layer HIL, hole transport layer HTL, and electron blocking layer EBL.

The thickness of the hole transport region HTR may be about 100 Å to about 10,000 Å, for example, about 100 Å to about 5,000 Å. When the hole transport region HTR includes a hole injection layer HIL, the thickness of the hole injection region HIL may be, for example, about 30 Å to about 1,000 Å. When the hole transport region HTR includes a hole transport layer HTL, the thickness of the hole transport layer HTL may be about 30 Å to about 1,000 Å. For example, when the hole transport region HTR includes an electron blocking layer EBL, the thickness of the electron blocking layer EBL may be about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of metal halide compounds, quinone derivatives, metal oxides, and/or cyano group-containing compounds, without limitation. For example, non-limiting examples of the p-dopant may be or include metal halide compounds (such as CuI and/or RbI), quinone derivatives (such as tetracyanoquinodimethane (TCNQ) and/or 2,3,5,6-tetrafluoro-7,7′,8,8-tetracyanoquinodimethane (F4-TCNQ)), metal oxides (such as tungsten oxide and/or molybdenum oxide), cyano group-containing compounds (such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9)), etc., without limitation.

As described above, the hole transport region HTR may further include at least one of a buffer layer and/or an electron blocking layer EBL in addition to the hole injection layer HIL and the hole transport layer HTL. The buffer layer may compensate for a wavelength resonance distance of light emitted from an emission layer EML to thereby increase the light-emitting efficiency of the device. The same materials included in the buffer layer may be included in the hole transport region HTR. The electron blocking layer EBL may block or reduce injection of electrons from an electron transport region ETR to a hole transport region HTR.

The emission layer EML is provided on the hole transport region HTR. The emission layer EML may have a thickness of, for example, about 100 Å to about 1,000 Å or about 100 Å to about 300 Å. The emission layer EML may be a single layer formed utilizing a single material, a single layer formed utilizing multiple different materials, or a multilayer structure having multiple layers formed utilizing multiple different materials.

In the organic electroluminescent element ED of an embodiment, the emission layer EML may include the fused polycyclic compound of an embodiment.

The fused polycyclic compound of an embodiment may be represented by Formula 1.

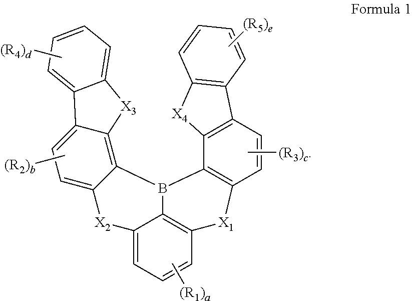

In Formula 1, X₁ to X₄ may each independently be CRₐ₁Rₐ₂, NRₐ₃, O, S, or Se.

In Formula 1, R₁ to R₅ and Rₐ₁ to Rₐ₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula 1, “a” may be an integer of 0 to 3. When “a” is 2 or more, the multiple R₁ groups may each independently be the same or different.

In Formula 1, “b” and “c” may each independently be an integer of 0 to 2. When “b” is 2, the multiple R₂ groups may each independently be the same or different, and when “c” is 2, the multiple R₃ groups may each independently be the same or different.

In Formula 1, “d” and “e” may each independently be an integer of 0 to 4. When “d” is 2 or more, the multiple R₄ groups may each independently be the same or different, and when “e” is 2 or more, the multiple R₅ groups may each independently be the same or different.

In the fused polycyclic compound represented by Formula 1, one or more hydrogen atoms may be optionally substituted (e.g., replaced) with a deuterium atom, a cyano group or a halogen atom.

In an embodiment, X₁ and X₂ of Formula 1 may be the same.

In an embodiment, “b” and “c” of Formula 1 may each independently be 1, and R₂ and R₃ may each independently be a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 1 may be represented by Formula 2.

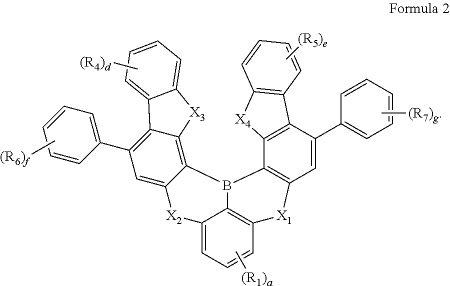

In Formula 2, R₆ and R₇ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula 2, “f” and “g” may each independently be an integer of 0 to 5. When “f” is 2 or more, the multiple R₆ groups may each independently be the same or different, and when “g” is 2 or more, the multiple R₇ groups may each independently be the same or different.

In Formula 2, X₁ to X₄, R₁, R₄, R₅, “a”, “d”, and “e” may each independently be the same as defined in Formula 1.

In an embodiment, the fused polycyclic compound represented by Formula 2 may be represented by Formula 3.

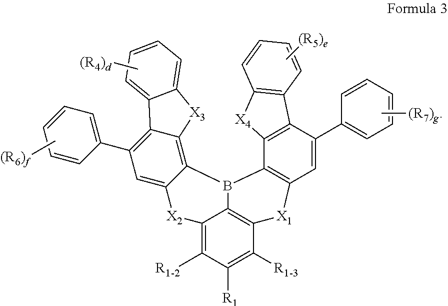

In Formula 3, R₁ may be a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula 3, R₁₋₂ and R₁₋₃ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula 3, X₁ to X₄, R₄ to R₇, and “d” to “g” may each independently be the same as defined in Formula 2.

In an embodiment, R₁₋₂ and R₁₋₃ of Formula 3 may each independently be a hydrogen atom, and R₁ may be a substituted or unsubstituted aryl group of 6 to 60 ring-forming carbon atoms, or a substituted or unsubstituted heteroaryl group of 2 to 60 ring-forming carbon atoms.

In an embodiment, the fused polycyclic compound represented by Formula 3 may be represented by Formula 4.

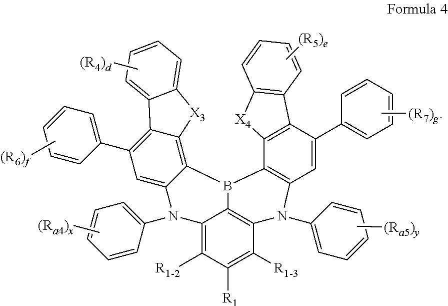

In Formula 4, Rₐ₄ and Rₐ₅ may each independently be a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring.

In Formula 4, “x” and “y” may each independently be an integer of 0 to 5. When “x” is 2 or more, the multiple Rₐ₄ groups may each independently be the same or different, and when “y” is 2 or more, the multiple Rₐ₅ groups may each independently be the same or different.

In Formula 4, X₃, X₄, R₁, R₁₋₂, R₁₋₃, R₄ to R₇, and “d” to “g” may each independently be the same as defined in Formula 3.

The fused polycyclic compound of an embodiment may be represented by at least one among the compounds represented in Compound Group 1. The organic electroluminescent element ED of an embodiment may include at least one fused polycyclic compound among the compounds represented in Compound Group 1 in an emission layer EML.

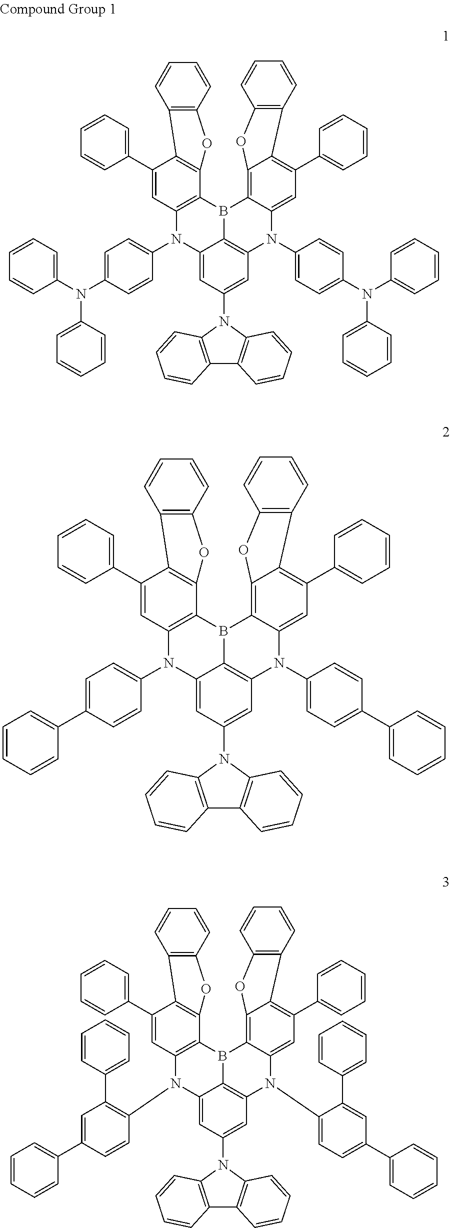 [SMILES: c1ccc(-c2cc3c(c4oc5ccccc5c24)B2c4c(cc(-n5c6ccccc6c6ccccc65)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1]

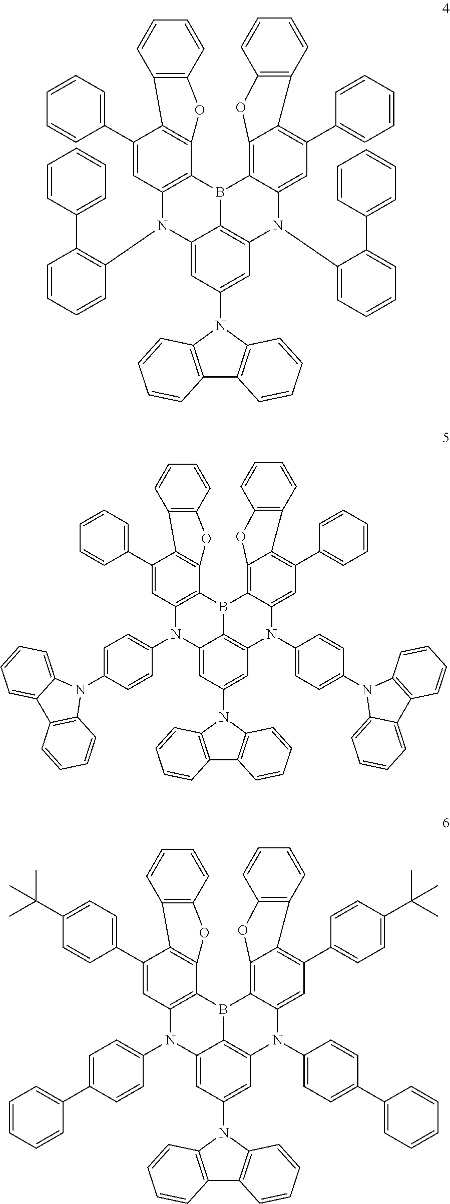 [SMILES: c1ccc(-c2ccccc2N2c3cc(-n4c5ccccc5c5ccccc54)cc4c3B(c3c2cc(-c2ccccc2)c2c3oc3ccccc32)c2c(cc(-c3ccccc3)c3c2oc2ccccc23)N4c2ccccc2-c2ccccc2)cc1 ; c1ccc(-c2cc3c(c4oc5ccccc5c24)B2c4c(cc(-n5c6ccccc6c6ccccc65)cc4N(c4ccc(-n5c6ccccc6c6ccccc65)cc4)c4cc(-c5ccccc5)c5c(oc6ccccc65)c42)N3c2ccc(-n3c4ccccc4c4ccccc43)cc2)cc1 ; CC(C)(C)c1ccc(-c2cc3c(c4oc5ccccc5c24)B2c4c(cc(-n5c6ccccc6c6ccccc65)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1]

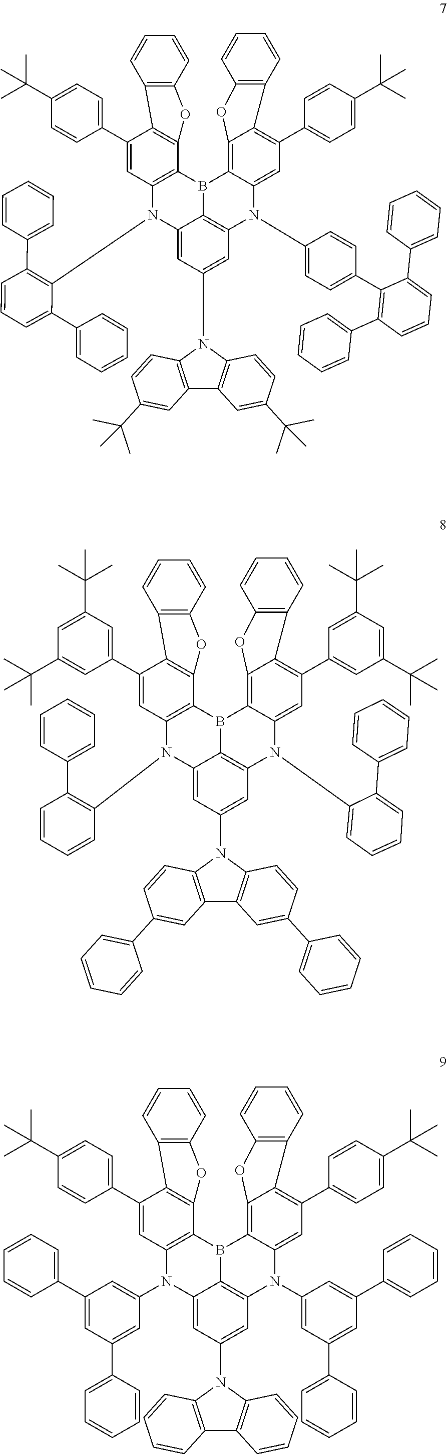

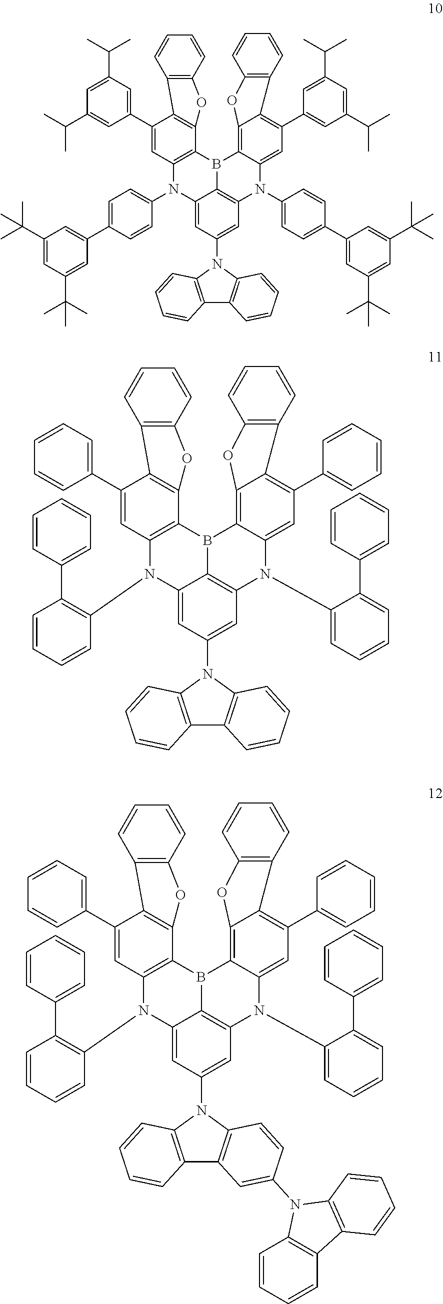

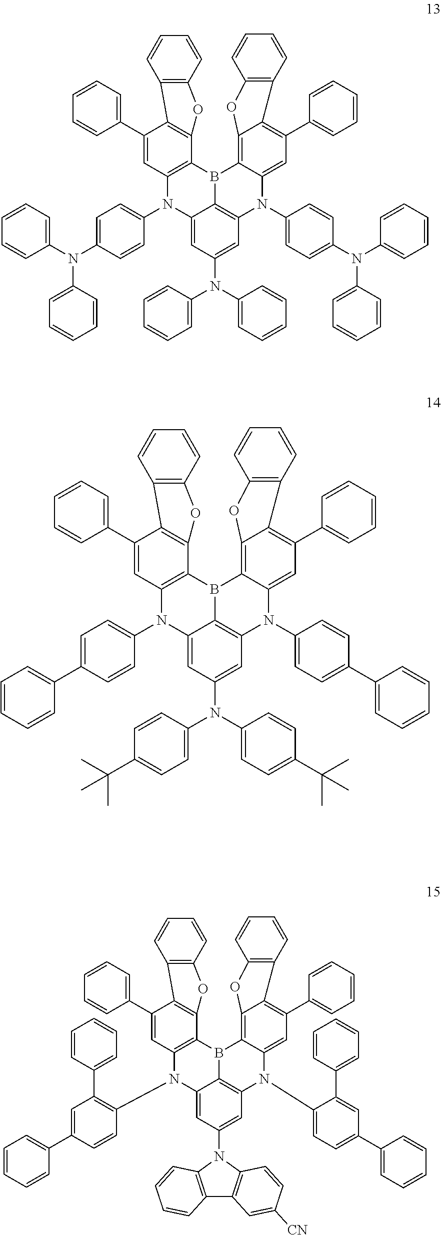 [SMILES: c1ccc(-c2cc3c(c4oc5ccccc5c24)B2c4c(cc(N(c5ccccc5)c5ccccc5)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; CC(C)(C)c1ccc(N(c2ccc(C(C)(C)C)cc2)c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc1 ; N#Cc1ccc2c(c1)c1ccccc1n2-c1cc2c3c(c1)N(c1ccc(-c4ccccc4)cc1-c1ccccc1)c1cc(-c4ccccc4)c4c(oc5ccccc54)c1B3c1c(cc(-c3ccccc3)c3c1oc1ccccc13)N2c1ccc(-c2ccccc2)cc1-c1ccccc1]

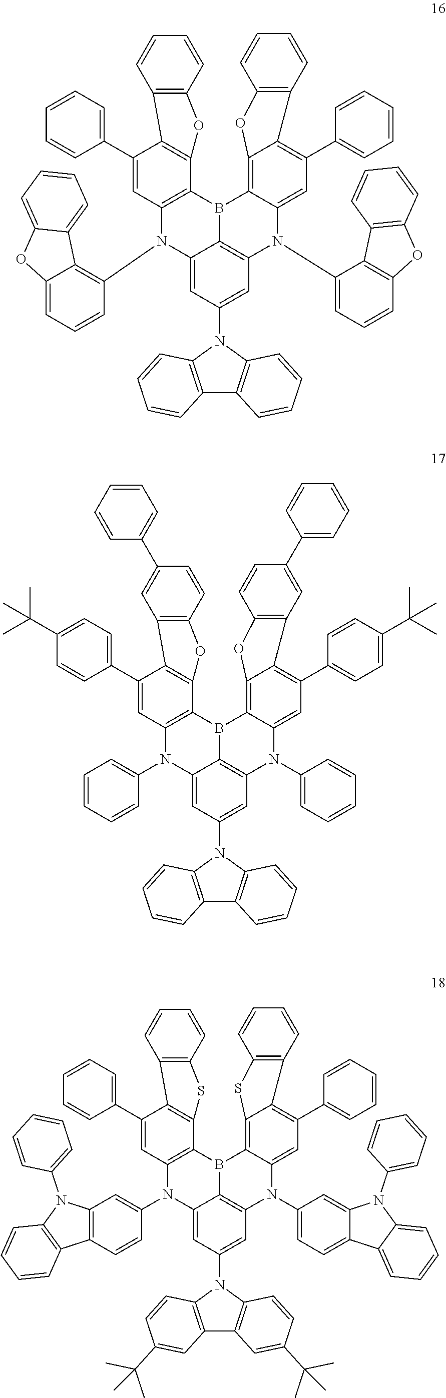 [SMILES: c1ccc(-c2cc3c(c4oc5ccccc5c24)B2c4c(cc(-n5c6ccccc6c6ccccc65)cc4N(c4cccc5oc6ccccc6c45)c4cc(-c5ccccc5)c5c(oc6ccccc65)c42)N3c2cccc3oc4ccccc4c23)cc1 ; CC(C)(C)c1ccc(-c2cc3c(c4oc5ccc(-c6ccccc6)cc5c24)B2c4c(cc(-n5c6ccccc6c6ccccc65)cc4N(c4ccccc4)c4cc(-c5ccc(C(C)(C)C)cc5)c5c(oc6ccc(-c7ccccc7)cc65)c42)N3c2ccccc2)cc1 ; CC(C)(C)c1ccc2c(c1)c1cc(C(C)(C)C)ccc1n2-c1cc2c3c(c1)N(c1ccc4c5ccccc5n(-c5ccccc5)c4c1)c1cc(-c4ccccc4)c4c(sc5ccccc54)c1B3c1c(cc(-c3ccccc3)c3c1sc1ccccc13)N2c1ccc2c3ccccc3n(-c3ccccc3)c2c1]

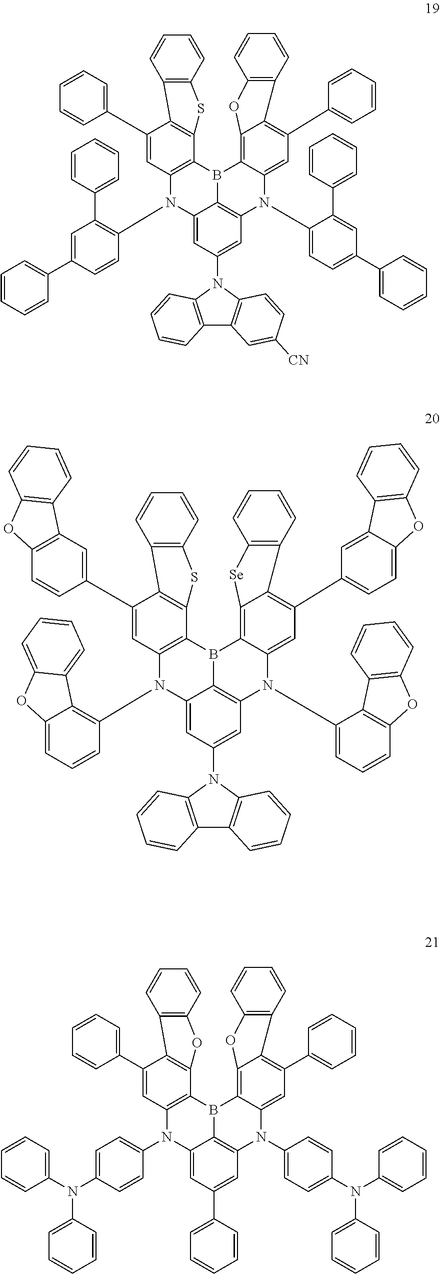 [SMILES: N#Cc1ccc2c(c1)c1ccccc1n2-c1cc2c3c(c1)N(c1ccc(-c4ccccc4)cc1-c1ccccc1)c1cc(-c4ccccc4)c4c(sc5ccccc54)c1B3c1c(cc(-c3ccccc3)c3c1oc1ccccc13)N2c1ccc(-c2ccccc2)cc1-c1ccccc1 ; c1ccc2c(c1)oc1ccc(-c3cc4c(c5sc6ccccc6c35)B3c5c(cc(-n6c7ccccc7c7ccccc76)cc5N(c5cccc6oc7ccccc7c56)c5cc(-c6ccc7oc8ccccc8c7c6)c6c([se]c7ccccc76)c53)N4c3cccc4oc5ccccc5c34)cc12 ; c1ccc(-c2cc3c4c(c2)N(c2ccc(N(c5ccccc5)c5ccccc5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)cc1]

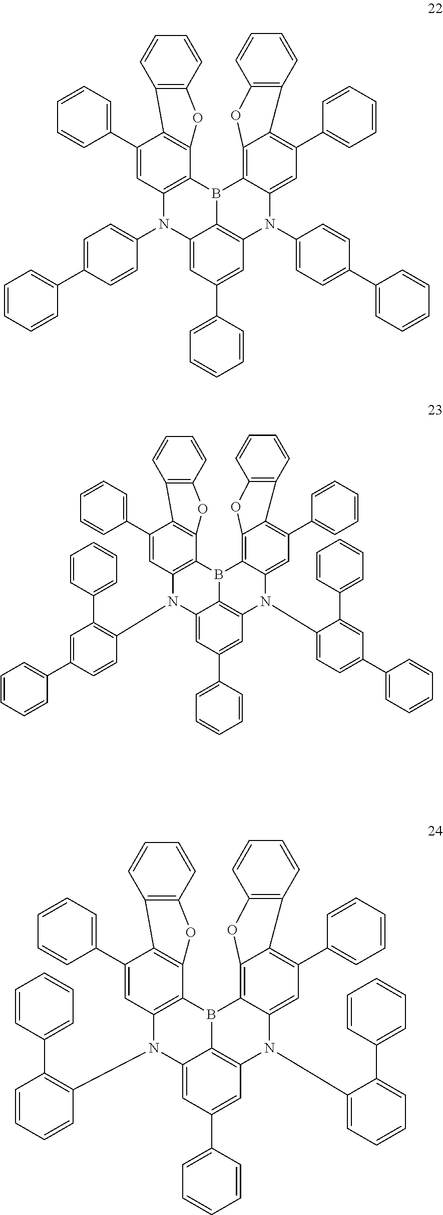 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1]

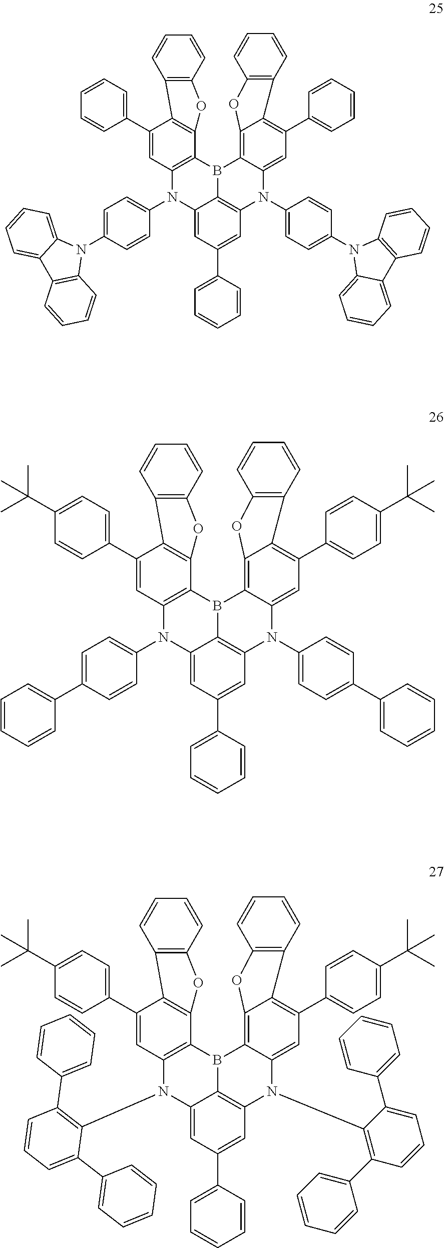 [SMILES: c1ccc(-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1 ; CC(C)(C)c1ccc(-c2cc3c(c4oc5ccccc5c24)B2c4c(cc(-c5ccccc5)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1 ; CC(C)(C)c1ccc(-c2cc3c(c4oc5ccccc5c24)B2c4c(cc(-c5ccccc5)cc4N(c4c(-c5ccccc5)cccc4-c4ccccc4)c4cc(-c5ccc(C(C)(C)C)cc5)c5c(oc6ccccc65)c42)N3c2c(-c3ccccc3)cccc2-c2ccccc2)cc1]

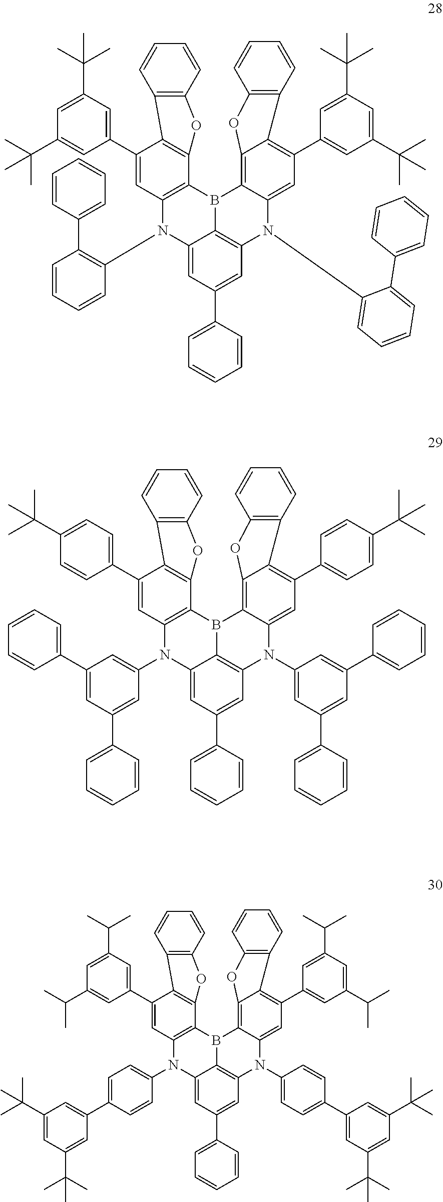

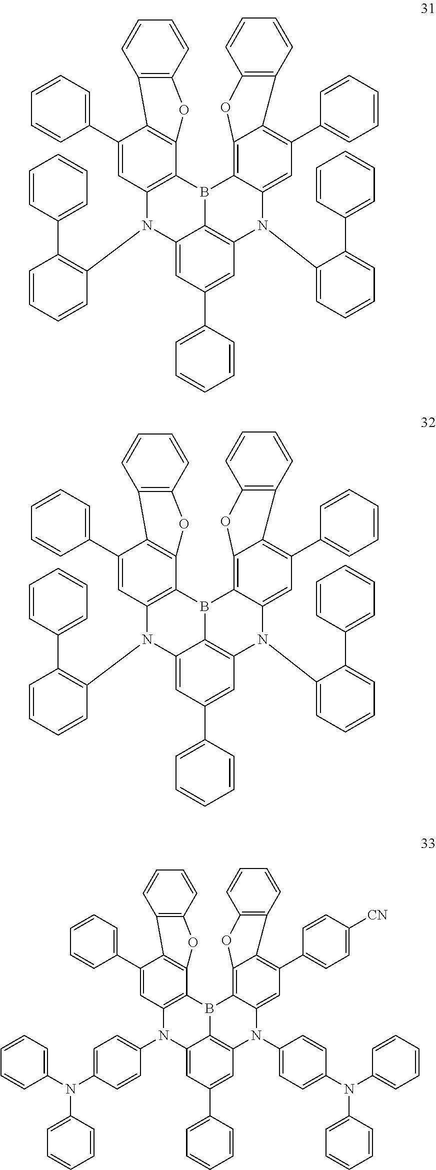 [SMILES: c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; N#Cc1ccc(-c2cc3c(c4oc5ccccc5c24)B2c4c(cc(-c5ccccc5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1]

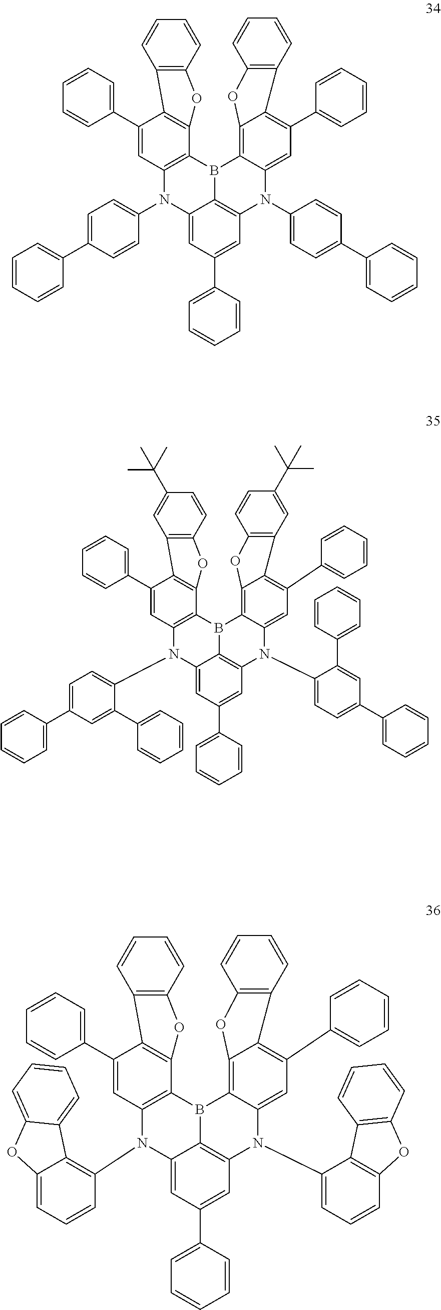 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; CC(C)(C)c1ccc2oc3c4c(cc(-c5ccccc5)c3c2c1)N(c1ccc(-c2ccccc2)cc1-c1ccccc1)c1cc(-c2ccccc2)cc2c1B4c1c(cc(-c3ccccc3)c3c1oc1ccc(C(C)(C)C)cc13)N2c1ccc(-c2ccccc2)cc1-c1ccccc1 ; c1ccc(-c2cc3c4c(c2)N(c2cccc5oc6ccccc6c25)c2cc(-c5ccccc5)c5c(oc6ccccc65)c2B4c2c(cc(-c4ccccc4)c4c2oc2ccccc24)N3c2cccc3oc4ccccc4c23)cc1]

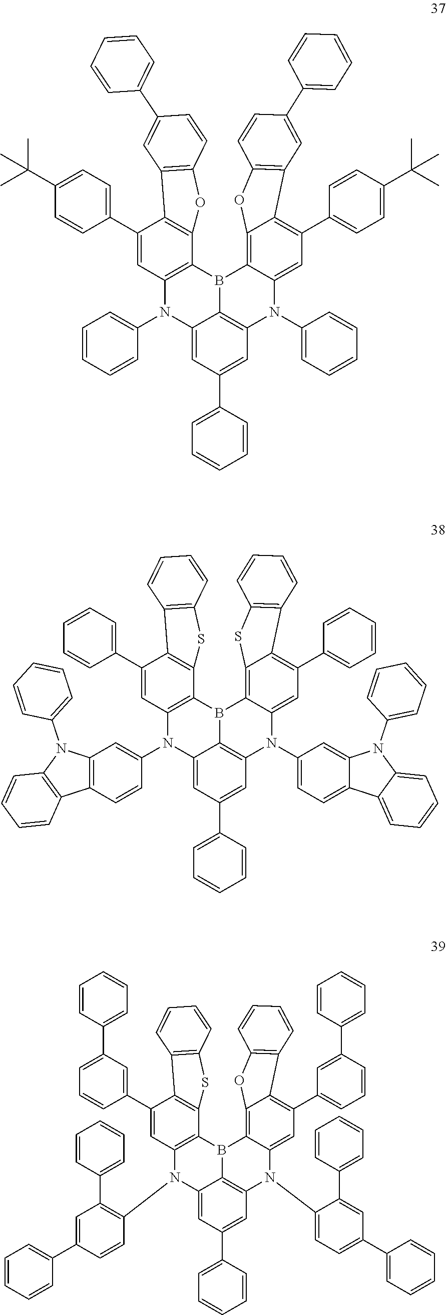 [SMILES: CC(C)(C)c1ccc(-c2cc3c(c4oc5ccc(-c6ccccc6)cc5c24)B2c4c(cc(-c5ccccc5)cc4N(c4ccccc4)c4cc(-c5ccc(C(C)(C)C)cc5)c5c(oc6ccc(-c7ccccc7)cc65)c42)N3c2ccccc2)cc1 ; c1ccc(-c2cc3c4c(c2)N(c2ccc5c6ccccc6n(-c6ccccc6)c5c2)c2cc(-c5ccccc5)c5c(sc6ccccc65)c2B4c2c(cc(-c4ccccc4)c4c2sc2ccccc24)N3c2ccc3c4ccccc4n(-c4ccccc4)c3c2)cc1 ; c1ccc(-c2cccc(-c3cc4c(c5oc6ccccc6c35)B3c5c(cc(-c6ccccc6)cc5N(c5ccc(-c6ccccc6)cc5-c5ccccc5)c5cc(-c6cccc(-c7ccccc7)c6)c6c(sc7ccccc76)c53)N4c3ccc(-c4ccccc4)cc3-c3ccccc3)c2)cc1]

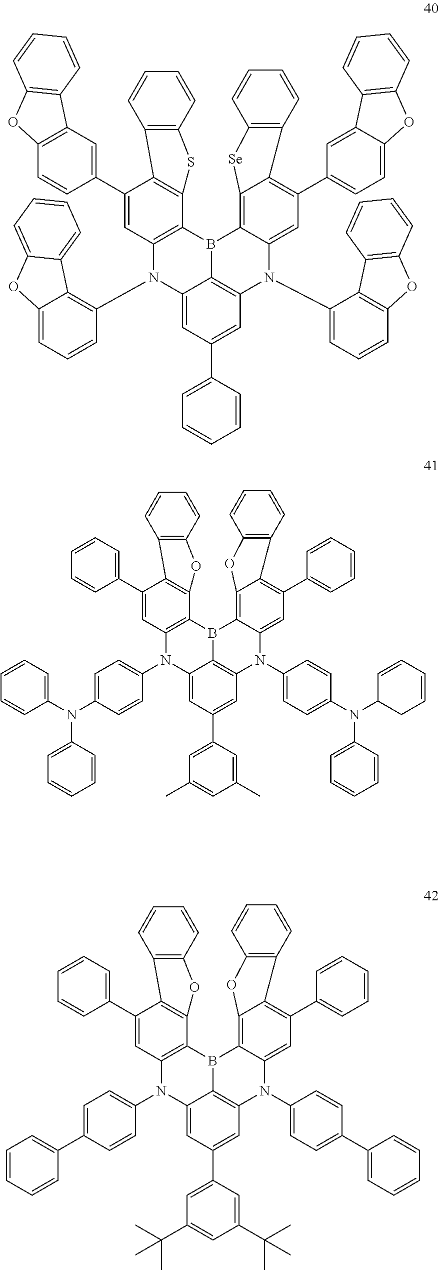 [SMILES: c1ccc(-c2cc3c4c(c2)N(c2cccc5oc6ccccc6c25)c2cc(-c5ccc6oc7ccccc7c6c5)c5c([se]c6ccccc65)c2B4c2c(cc(-c4ccc5oc6ccccc6c5c4)c4c2sc2ccccc24)N3c2cccc3oc4ccccc4c23)cc1 ; Cc1cc(C)cc(-c2cc3c4c(c2)N(c2ccc(N(c5ccccc5)C5C=CC=CC5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)c1 ; CC(C)(C)c1cc(-c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc(C(C)(C)C)c1]

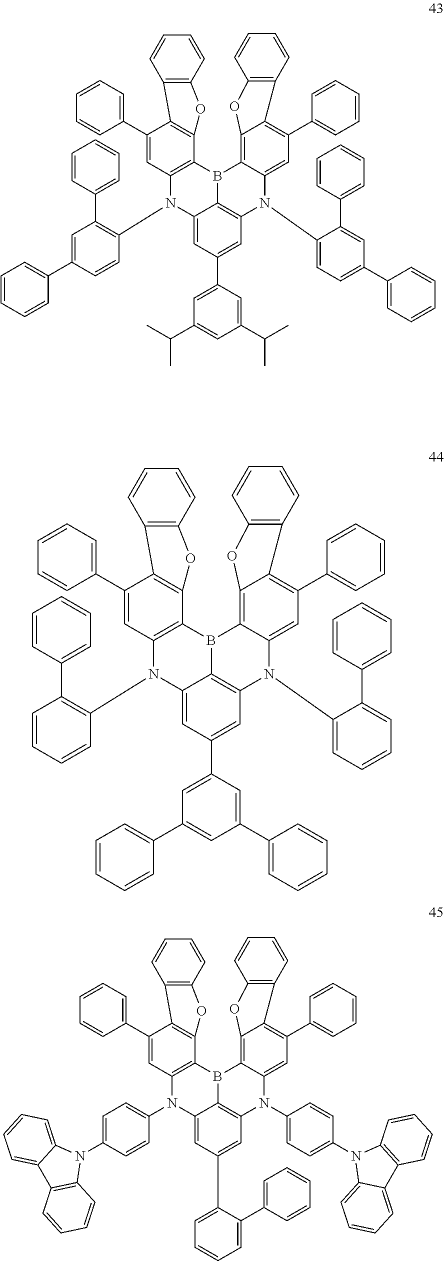 [SMILES: CC(C)c1cc(-c2cc3c4c(c2)N(c2ccc(-c5ccccc5)cc2-c2ccccc2)c2cc(-c5ccccc5)c5c(oc6ccccc65)c2B4c2c(cc(-c4ccccc4)c4c2oc2ccccc24)N3c2ccc(-c3ccccc3)cc2-c2ccccc2)cc(C(C)C)c1 ; c1ccc(-c2cc(-c3ccccc3)cc(-c3cc4c5c(c3)N(c3ccccc3-c3ccccc3)c3cc(-c6ccccc6)c6c(oc7ccccc76)c3B5c3c(cc(-c5ccccc5)c5c3oc3ccccc35)N4c3ccccc3-c3ccccc3)c2)cc1 ; c1ccc(-c2ccccc2-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1]

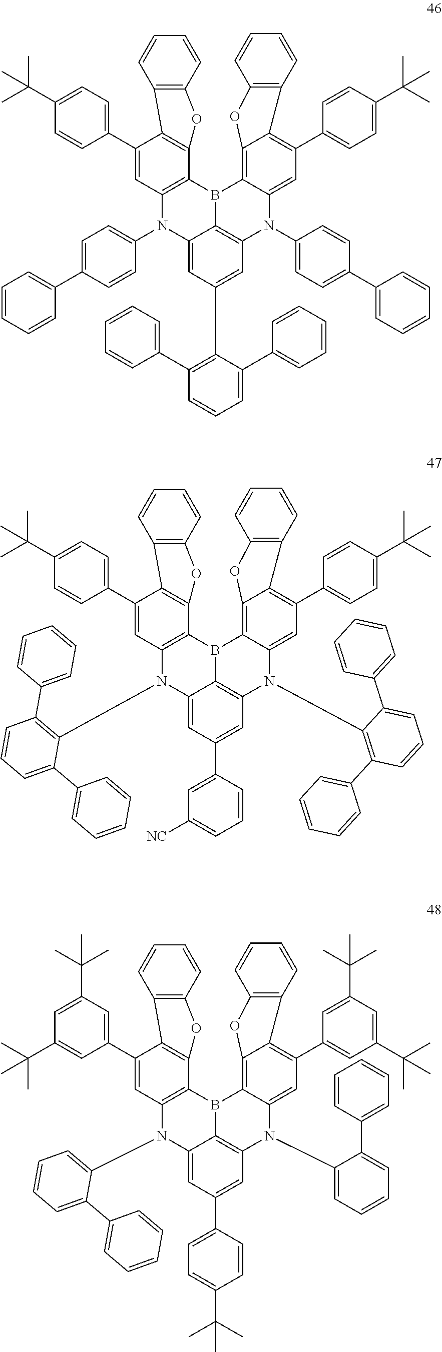

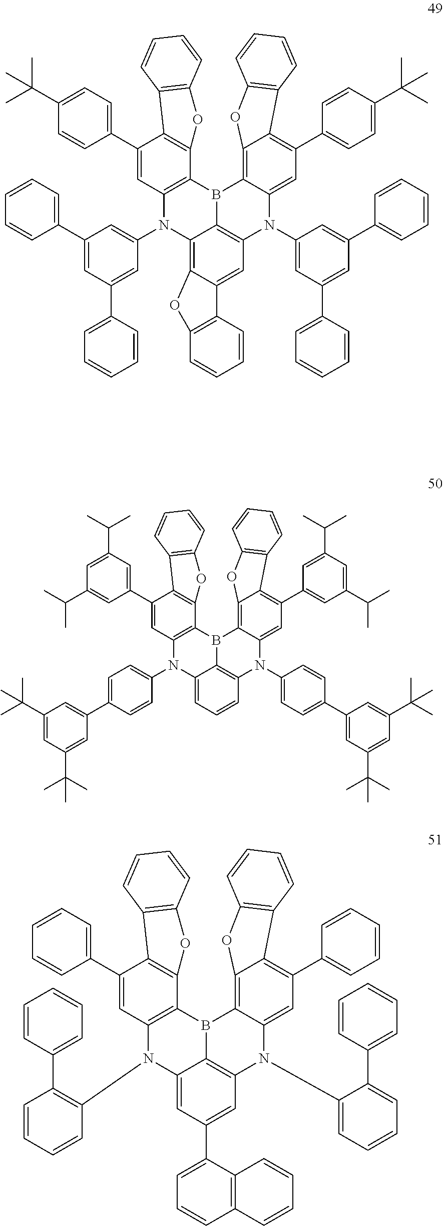 [SMILES: CC(C)(C)c1ccc(-c2cc3c(c4oc5ccccc5c24)B2c4c(cc5c(oc6ccccc65)c4N(c4cc(-c5ccccc5)cc(-c5ccccc5)c4)c4cc(-c5ccc(C(C)(C)C)cc5)c5c(oc6ccccc65)c42)N3c2cc(-c3ccccc3)cc(-c3ccccc3)c2)cc1 ; CC(C)c1cc(-c2cc3c(c4oc5ccccc5c24)B2c4c(cccc4N(c4ccc(-c5cc(C(C)(C)C)cc(C(C)(C)C)c5)cc4)c4cc(-c5cc(C(C)C)cc(C(C)C)c5)c5c(oc6ccccc65)c42)N3c2ccc(-c3cc(C(C)(C)C)cc(C(C)(C)C)c3)cc2)cc(C(C)C)c1 ; c1ccc(-c2ccccc2N2c3cc(-c4cccc5ccccc45)cc4c3B(c3c2cc(-c2ccccc2)c2c3oc3ccccc32)c2c(cc(-c3ccccc3)c3c2oc2ccccc23)N4c2ccccc2-c2ccccc2)cc1]

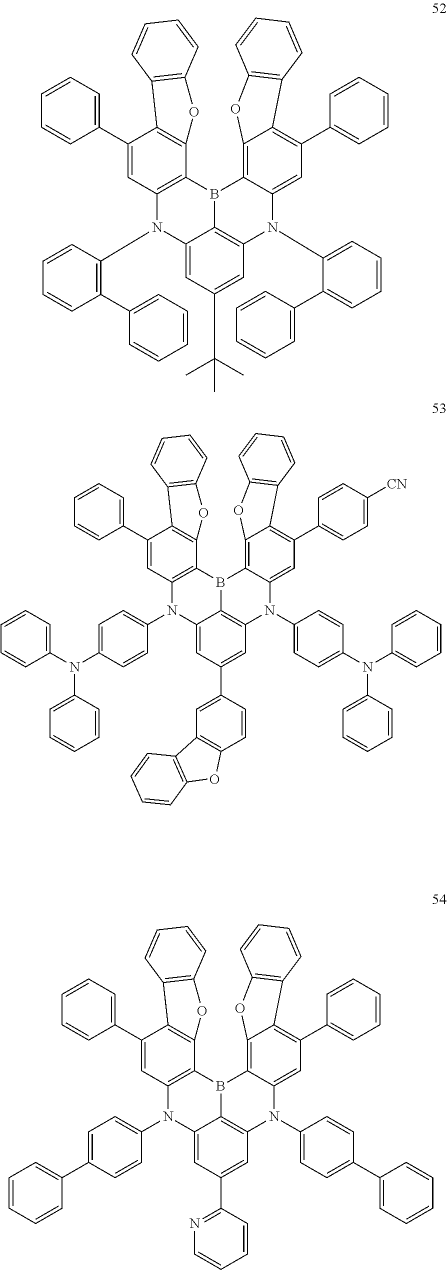 [SMILES: CC(C)(C)c1cc2c3c(c1)N(c1ccccc1-c1ccccc1)c1cc(-c4ccccc4)c4c(oc5ccccc54)c1B3c1c(cc(-c3ccccc3)c3c1oc1ccccc13)N2c1ccccc1-c1ccccc1 ; N#Cc1ccc(-c2cc3c(c4oc5ccccc5c24)B2c4c(cc(-c5ccc6oc7ccccc7c6c5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1 ; c1ccc(-c2ccc(N3c4cc(-c5ccccn5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1]

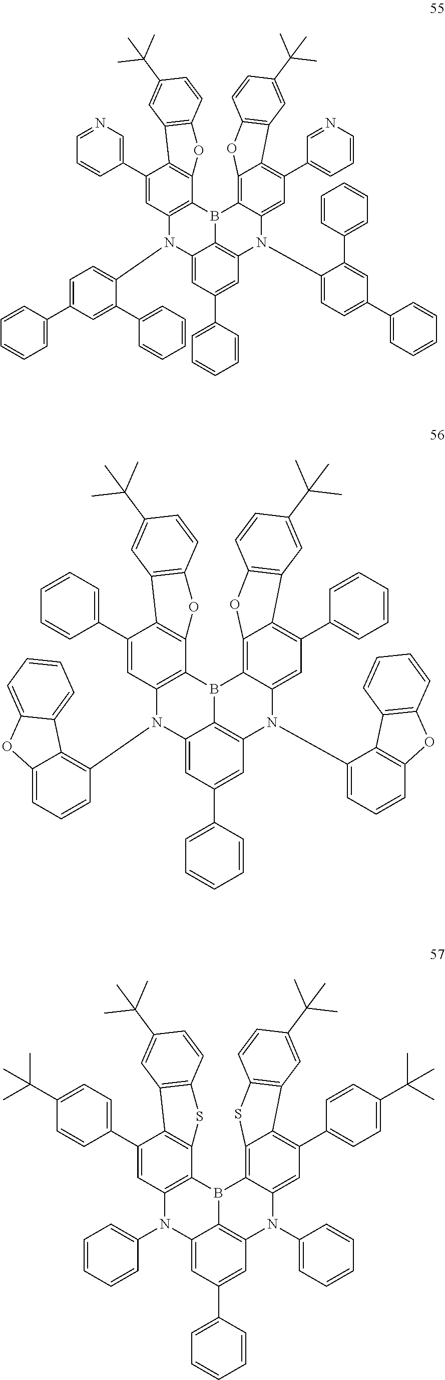 [SMILES: CC(C)(C)c1ccc2oc3c4c(cc(-c5cccnc5)c3c2c1)N(c1ccc(-c2ccccc2)cc1-c1ccccc1)c1cc(-c2ccccc2)cc2c1B4c1c(cc(-c3cccnc3)c3c1oc1ccc(C(C)(C)C)cc13)N2c1ccc(-c2ccccc2)cc1-c1ccccc1 ; CC(C)(C)c1ccc2oc3c4c(cc(-c5ccccc5)c3c2c1)N(c1cccc2oc3ccccc3c12)c1cc(-c2ccccc2)cc2c1B4c1c(cc(-c3ccccc3)c3c1oc1ccc(C(C)(C)C)cc13)N2c1cccc2oc3ccccc3c12 ; CC(C)(C)c1ccc(-c2cc3c(c4sc5ccc(C(C)(C)C)cc5c24)B2c4c(cc(-c5ccccc5)cc4N(c4ccccc4)c4cc(-c5ccc(C(C)(C)C)cc5)c5c(sc6ccc(C(C)(C)C)cc65)c42)N3c2ccccc2)cc1]

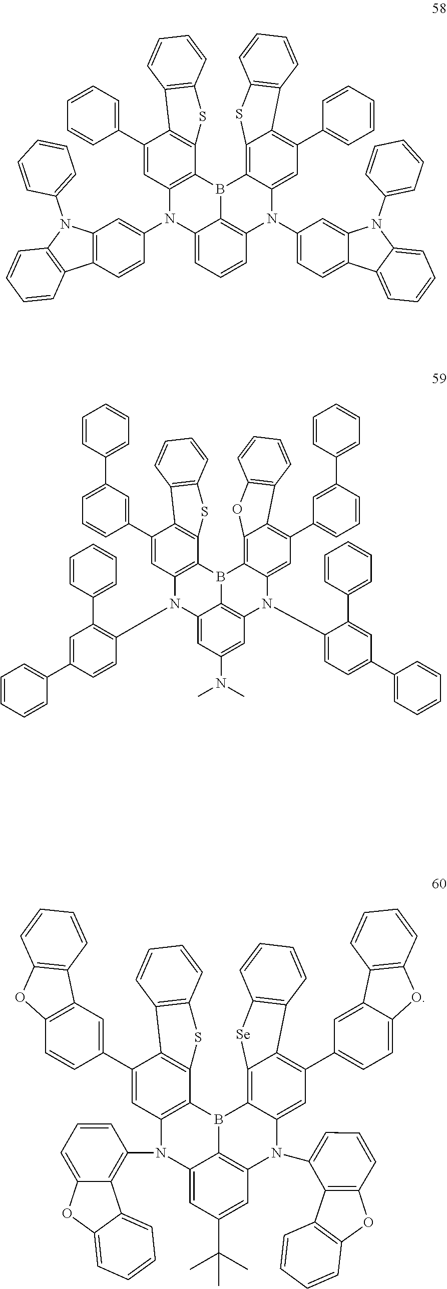 [SMILES: c1ccc(-c2cc3c(c4sc5ccccc5c24)B2c4c(cccc4N(c4ccc5c6ccccc6n(-c6ccccc6)c5c4)c4cc(-c5ccccc5)c5c(sc6ccccc65)c42)N3c2ccc3c4ccccc4n(-c4ccccc4)c3c2)cc1 ; CN(C)c1cc2c3c(c1)N(c1ccc(-c4ccccc4)cc1-c1ccccc1)c1cc(-c4cccc(-c5ccccc5)c4)c4c(sc5ccccc54)c1B3c1c(cc(-c3cccc(-c4ccccc4)c3)c3c1oc1ccccc13)N2c1ccc(-c2ccccc2)cc1-c1ccccc1 ; CC(C)(C)c1cc2c3c(c1)N(c1cccc4oc5ccccc5c14)c1cc(-c4ccc5oc6ccccc6c5c4)c4c([se]c5ccccc54)c1B3c1c(cc(-c3ccc4oc5ccccc5c4c3)c3c1sc1ccccc13)N2c1cccc2oc3ccccc3c12]

The fused polycyclic compound of an embodiment as represented by Formula 1 may be a material to emit thermally activated delayed fluorescence (TADF). In some embodiments, the fused polycyclic compound of an embodiment as represented by Formula 1 may be a thermally activated delayed fluorescence dopant.

The fused polycyclic compound of an embodiment as represented by Formula 1 may be a material to emit light in a blue region. The blue color may refer to a wavelength region of, for example, about 430 nm to about 490 nm. However, embodiments of the present disclosure are not limited thereto, and in the case of utilizing the fused polycyclic compound of an embodiment as a light-emitting material, the fused polycyclic compound may be utilized as a material to emit light in one or more suitable wavelength regions, (e.g., red light and/or green light).

The fused polycyclic compound according to the present disclosure may be utilized in the organic electroluminescent element ED of an embodiment to improve the efficiency and/or life span of the organic electroluminescent element. For example, the fused polycyclic compound according to the present disclosure may be utilized in an emission layer EML of the organic electroluminescent element ED of an embodiment to improve the emission efficiency and life of the organic electroluminescent element.

In an embodiment, the emission layer EML may be a delayed fluorescence emission layer including a first compound and a second compound, and the fused polycyclic compound of an embodiment as represented by Formula 1 may be included in the first compound of the emission layer EML. In an embodiment, the first compound may be a dopant, and the second compound may be a host. For example, the first compound may be a dopant to emit delayed fluorescence, and the second compound may be a host to emit delayed fluorescence.

In some embodiments, the organic electroluminescent element ED of an embodiment may include multiple emission layers. The multiple emission layers may be stacked in order, for example, and the organic electroluminescent element ED including the multiple emission layers may be to emit white light. The organic electroluminescent element including the multiple emission layers may be an organic electroluminescent element with a tandem structure. When the organic electroluminescent element ED includes multiple emission layers, at least one emission layer EML may include the fused polycyclic compound according to the present disclosure as described above.

In the organic electroluminescent element ED of an embodiment, the emission layer EML may include anthracene derivatives, pyrene derivatives, fluoranthene derivatives, chrysene derivatives, dihydrobenzanthracene derivatives, and/or triphenylene derivatives. For example, the emission layer EML may include anthracene derivatives and/or pyrene derivatives.

In an embodiment, the emission layer EML may further include a compound represented by Formula E-1. For example, the compound represented by Formula E-1 may be utilized as the second compound.

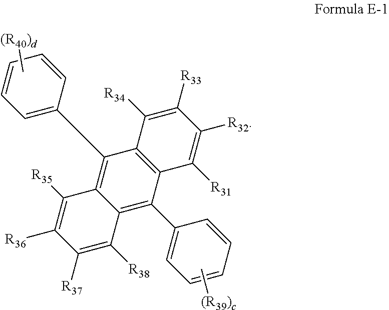

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

Formula E-1 may be represented by any one among Compound E1 to Compound E19.

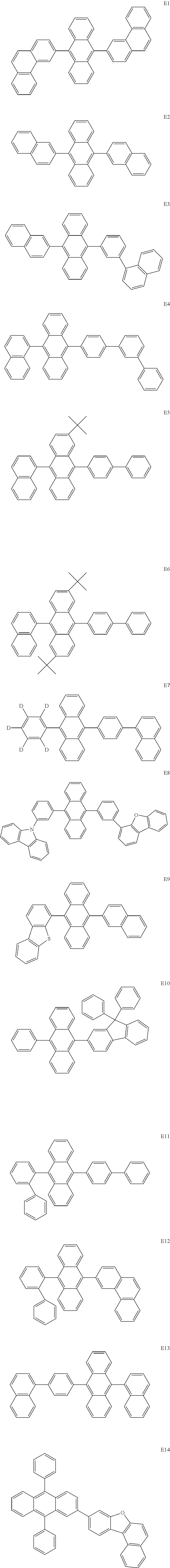

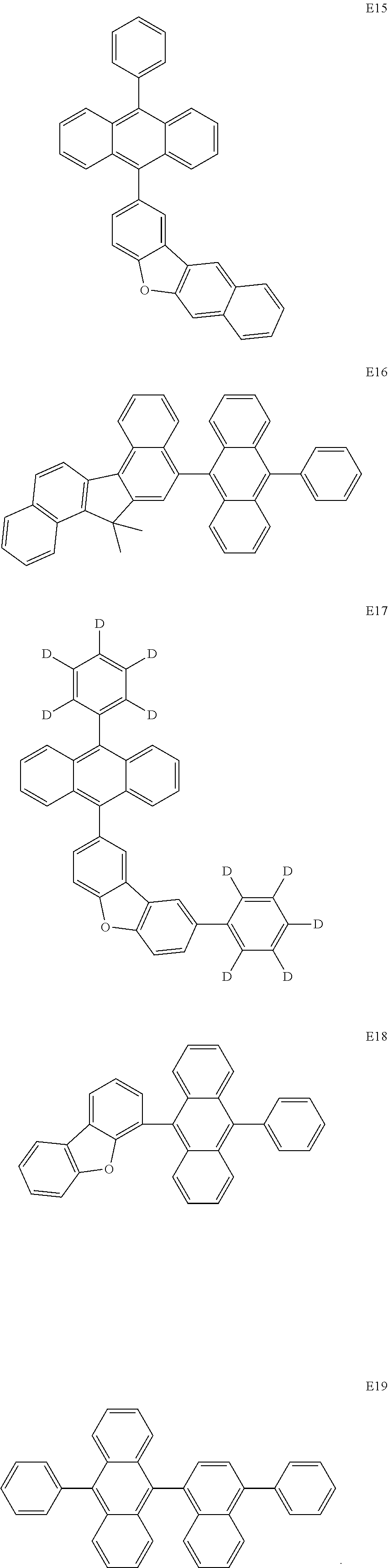

In an embodiment, the emission layer EML may further include a compound represented by Formula E-2a or Formula E-2b. For example, the compound represented by Formula E-2a or Formula E-2b may be utilized as a second compound.

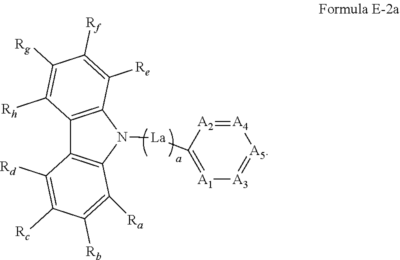

In Formula E-2b, “a” may be an integer of 0 to 10; and La may be a direct linkage, a substituted or unsubstituted arylene group of 6 to 30 ring-forming carbon atoms, or a substituted or unsubstituted heteroarylene group of 2 to 30 ring-forming carbon atoms. When “a” is an integer of 2 or more, the multiple La groups may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRi.

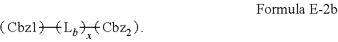

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “x” may be an integer of 0 to 10, and when “x” is an integer of 2 or more, multiple L_{b} groups may be the same or different.

The compound represented by Formula E-2a or Formula E-2b may be represented by any one among the compounds in Compound Group E-2. However, the compounds shown in Compound Group E-2 are only illustrations, and the compound represented by Formula E-2a or Formula E-2b is not limited to the compounds represented in Compound Group E-2.

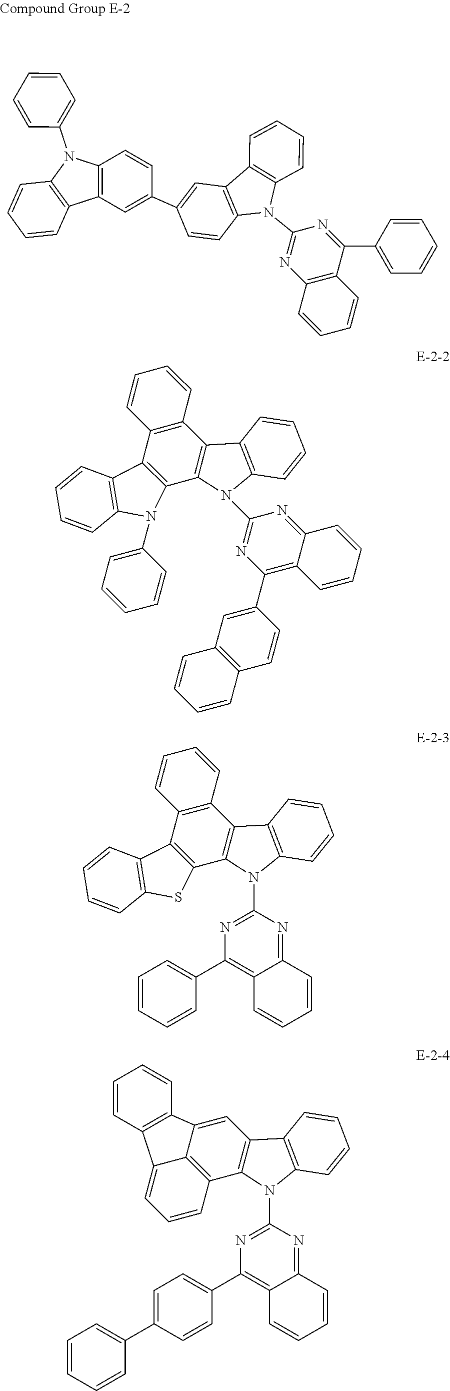

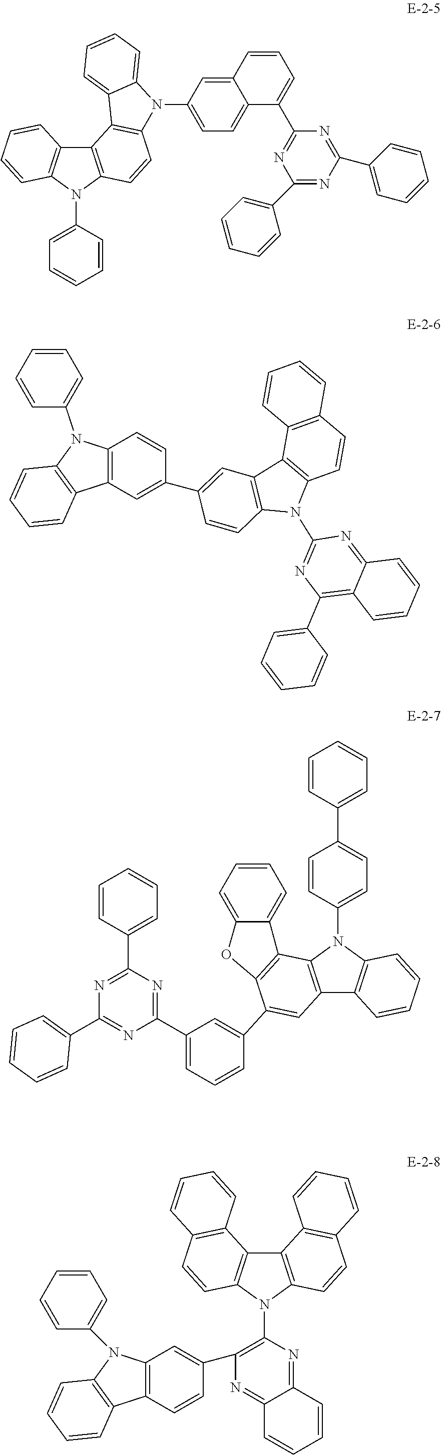 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

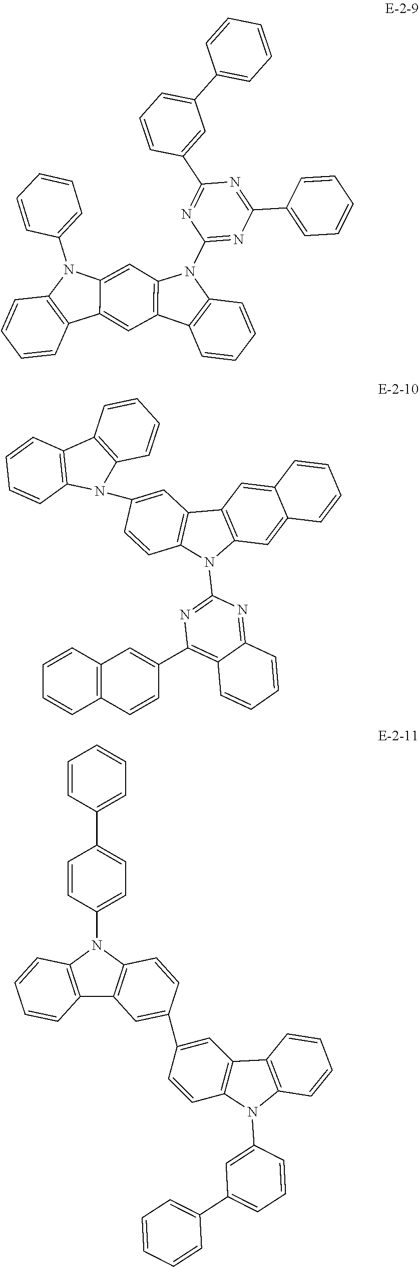

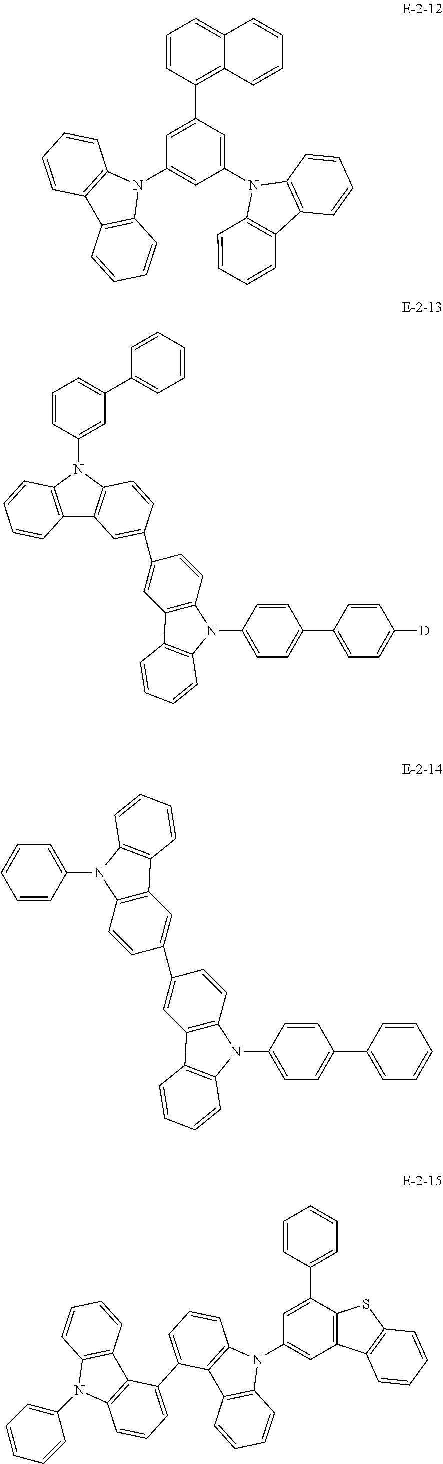 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

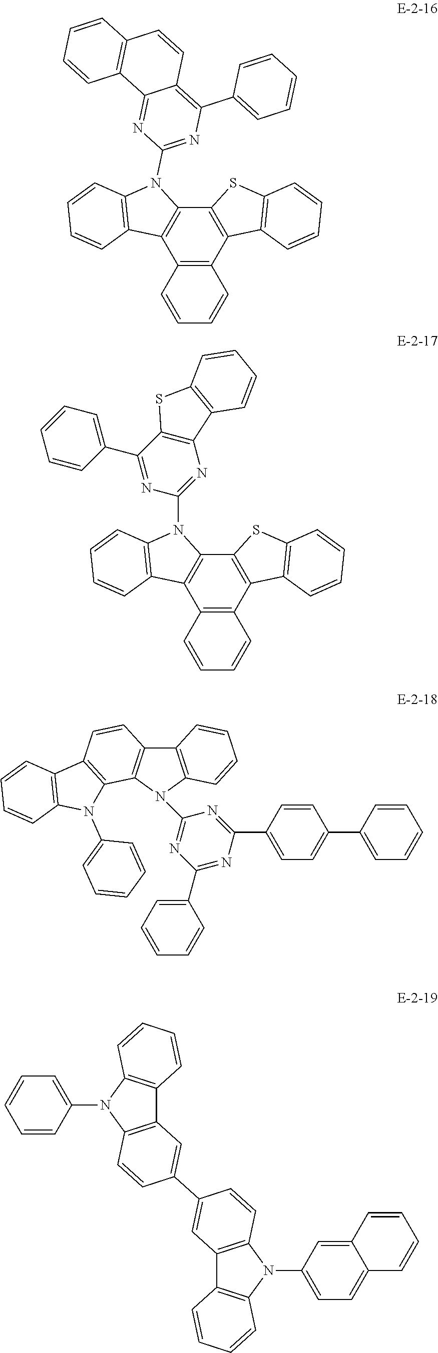

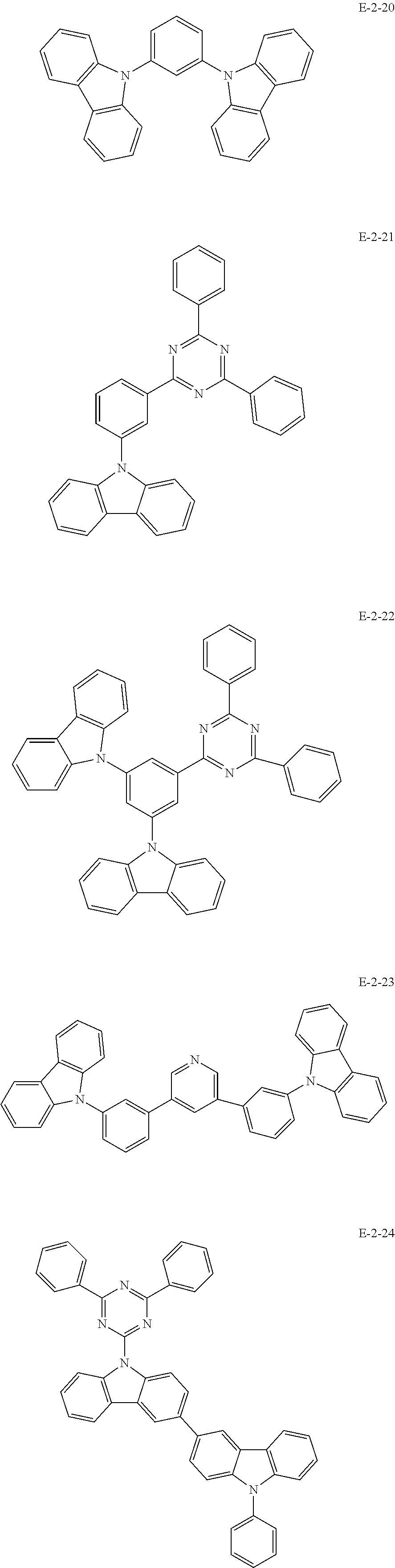 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, embodiments of the present disclosure are not limited thereto. For example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may include a compound represented by Formula M-a or Formula M-b. The compound represented by Formula M-a or Formula M-b may be utilized as a phosphorescence dopant material.

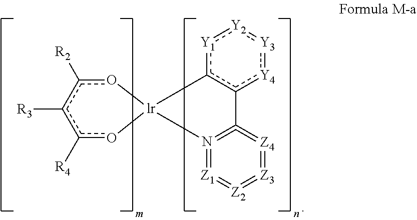

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” may be 0 or 1, and “n” may be 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one among Compounds M-a1 to M-a25. However, Compounds M-a1 to M-a25 are illustrations, and the compound represented by Formula M-a is not limited to the compounds represented by Compounds M-a1 to M-a25.

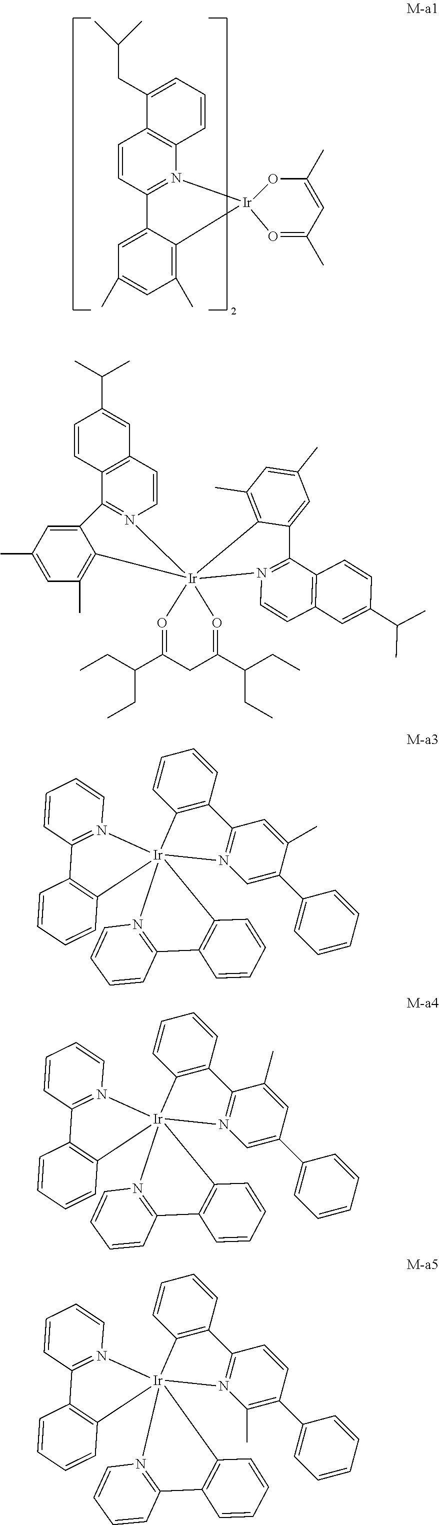

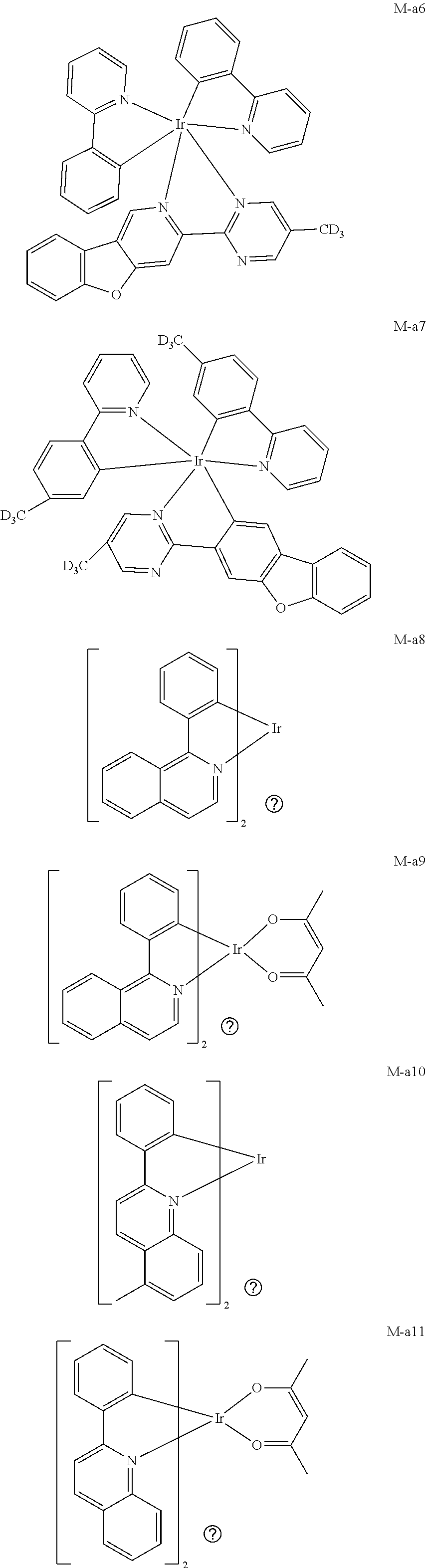

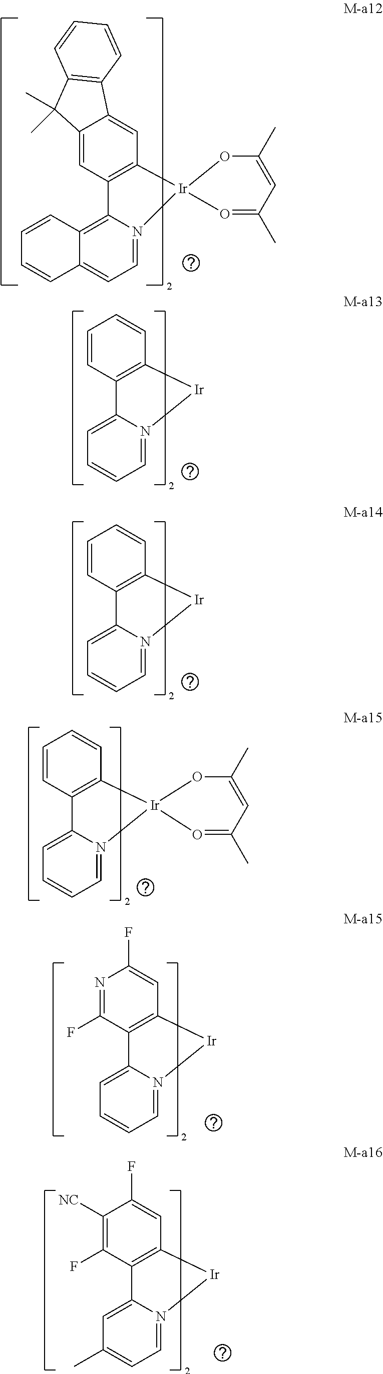

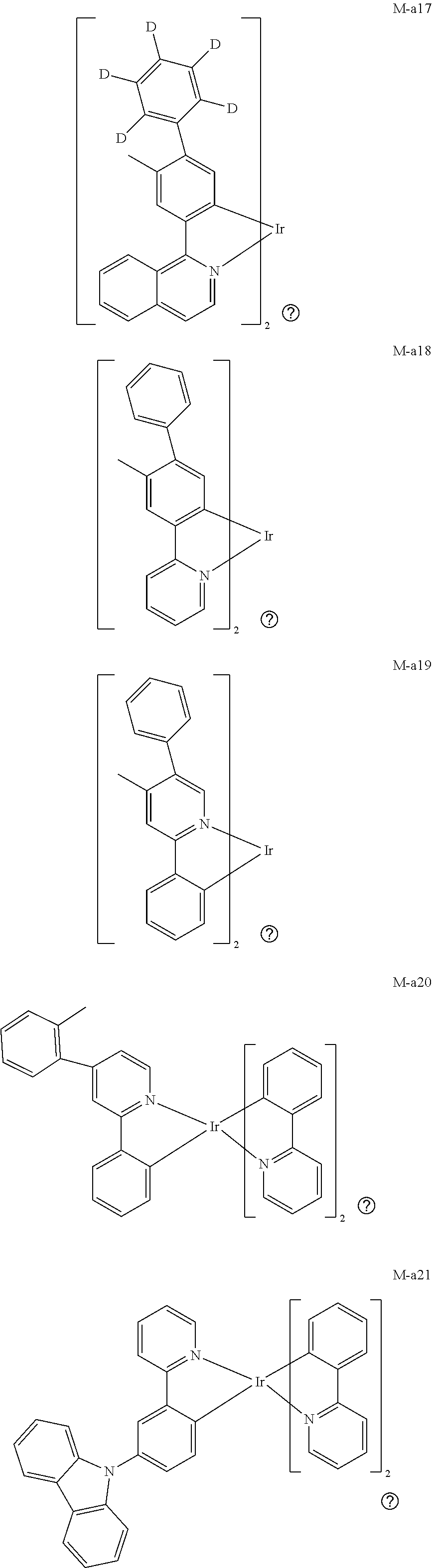

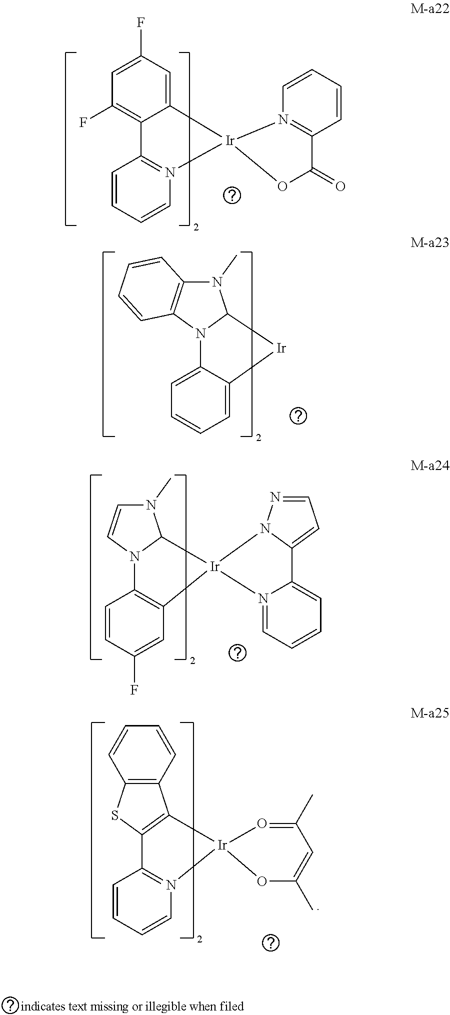

Compound M-a1 and Compound M-a2 may be utilized as red dopant materials, and Compound M-a3 to Compound M-a7 may be utilized as green dopant materials.

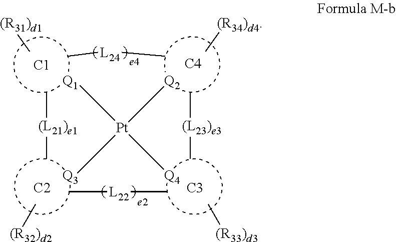

In Formula M-b, Q₁ to Q₄ may each independently be C or N; and C1 to C4 may each independently be a substituted or unsubstituted hydrocarbon ring of 5 to 30 ring-forming carbon atoms, or a substituted or unsubstituted heterocycle of 2 to 30 ring-forming carbon atoms. L₂₁ to L₂₄ may each independently be a direct linkage,

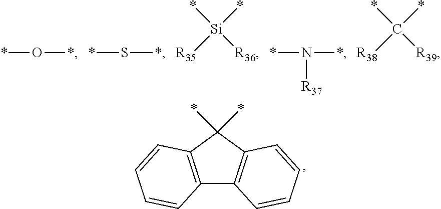

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, and e1 to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and d1 to d4 may each independently be an integer of 0 to 4.

The compound represented by Formula M-b may be utilized as a blue phosphorescence dopant or as a green phosphorescence dopant.

The compound represented by Formula M-b may be represented by any one among the compounds below. However, the compounds below are illustrations, and the compound represented by Formula M-b is not limited to the compounds represented below.

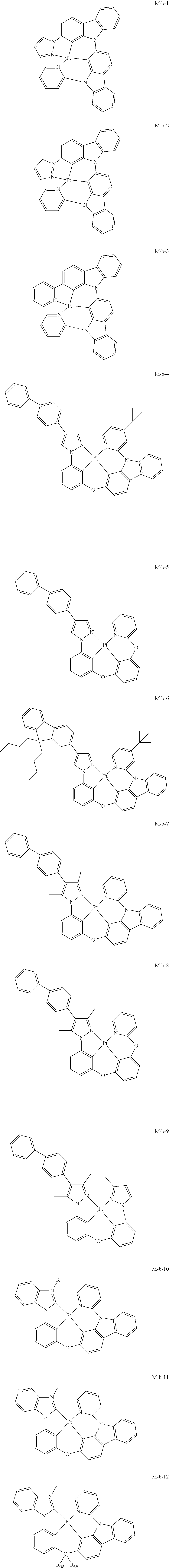

In the compounds above, R, R₃₈, and R₃₉ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The emission layer EML may include any one among Formula F-a to Formula F-c. The compounds represented by Formula F-a to Formula F-c may be utilized as fluorescence dopant materials.

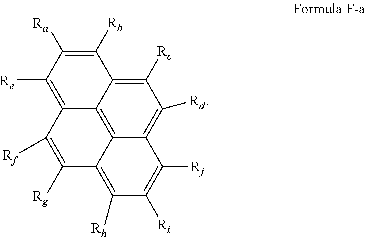

In Formula F-a, two selected from Rₐ to Rⱼ may each independently be substituted with *—NAr₁Ar₂. The remaining groups among Rₐ to Rⱼ that are not substituted with *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

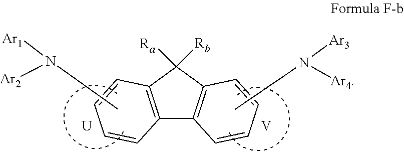

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four fused rings. When the number of both U and V is 0 (e.g., simultaneously), the fused ring of Formula F-b may be a ring compound with three fused rings. When the number of both U and V is 1 (e.g., simultaneously), a fused ring having the fluorene core of Formula F-b may be a ring compound with five fused rings.

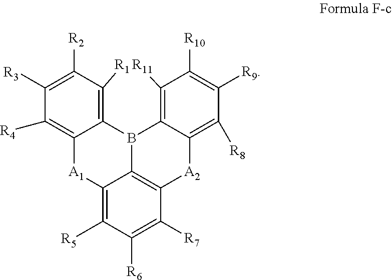

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ is NRₘ, A₁ may be combined with R₄ or R₅ to form a ring. When A₂ is NRₘ, A₂ may be combined with R₇ or R₈ to form a ring.

In an embodiment, the emission layer EML may include, as a suitable dopant material, styryl derivatives (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and derivatives thereof (for example, 2,5,8,11-tetra-t-butylperylene (TBP)), pyrene and derivatives thereof (for example, 1,1-dipyrene, 1,4-dipyrenylbenzene, and/or 1,4-(bis(N,N-diphenylamino)pyrene), etc.

The emission layer EML may include any suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as the phosphorescence dopant. However, embodiments of the present disclosure are not limited thereto.

In the organic electroluminescent elements ED of embodiments, as shown in FIG. 3 to FIG. 6, an electron transport region ETR is provided on an emission layer EML. The electron transport region ETR may include at least one of a hole blocking layer HBL, an electron transport layer ETL, and/or an electron injection layer EIL. However, embodiments of the present disclosure are not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. In some embodiments, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, about 1,000 Å to about 1,500 Å.

The electron transport region ETR may be formed utilizing one or more suitable methods (such as a vacuum deposition method, a spin coating method, a cast method, a Langmuir-Blodgett (LB) method, an inkjet printing method, a laser printing method, and/or a laser induced thermal imaging (LITI) method).

The electron transport layer ETL may include a compound represented by Formula ET-1.

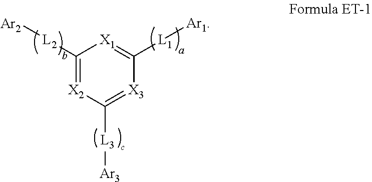

In Formula ET-1, at least one among X₁ to X₃ may be N, and the remainder may be CRₐ. Rₐ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may each independently be an integer of 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. When “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and mixtures thereof, without limitation.

The electron transport region ETR may include at least one among Compounds ET1 to ET36.

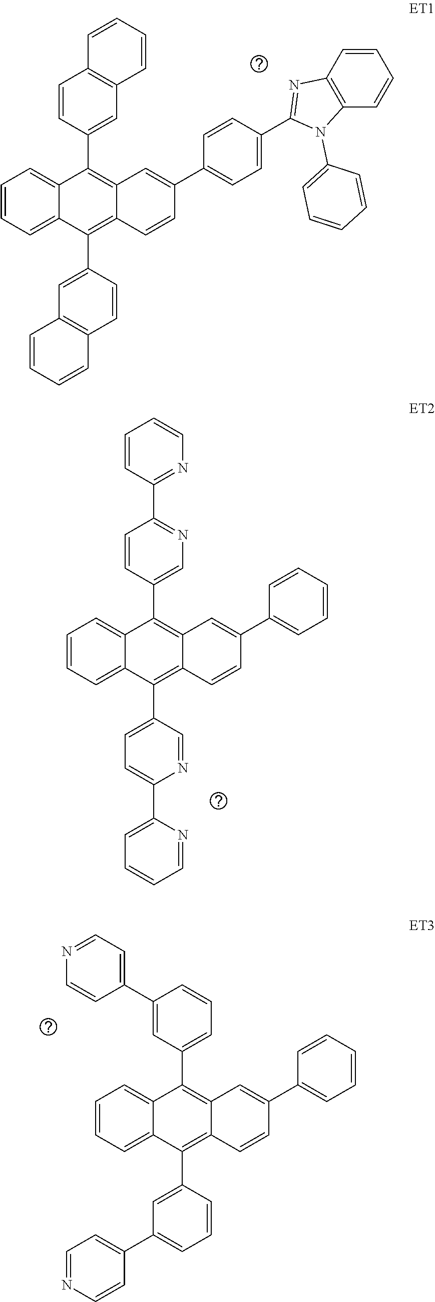 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

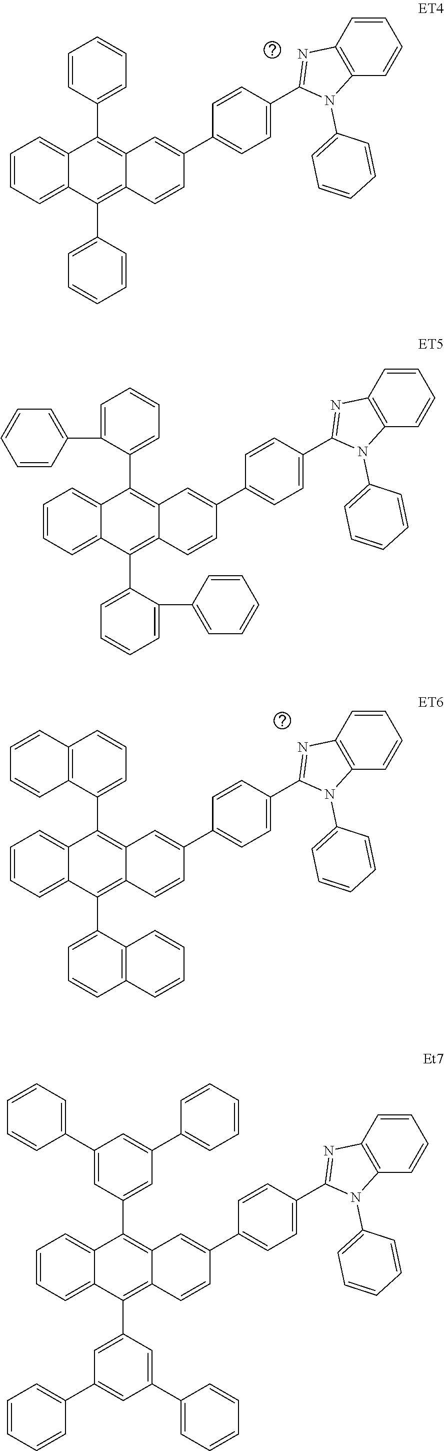 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

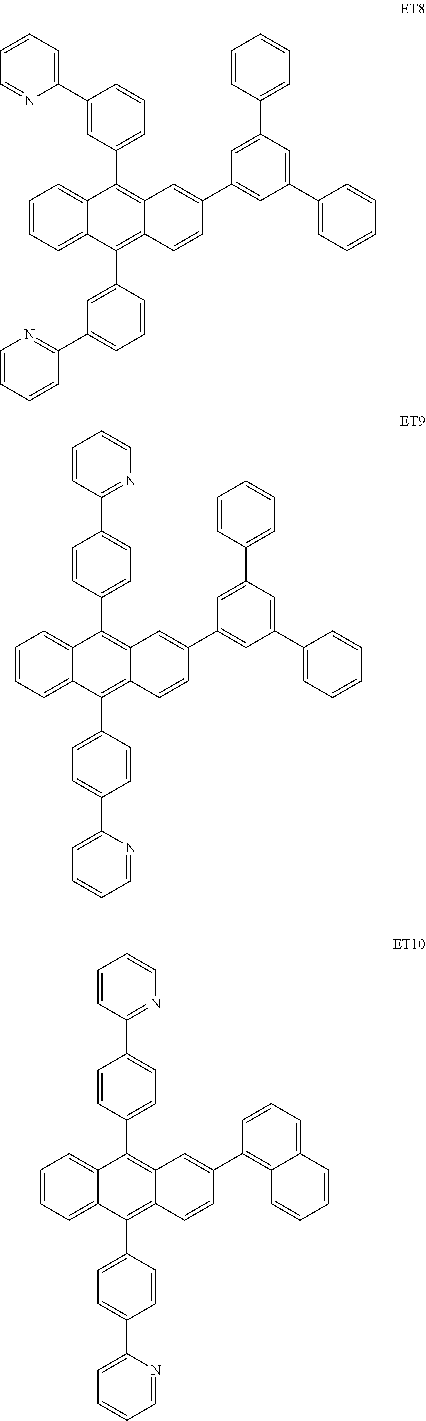 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

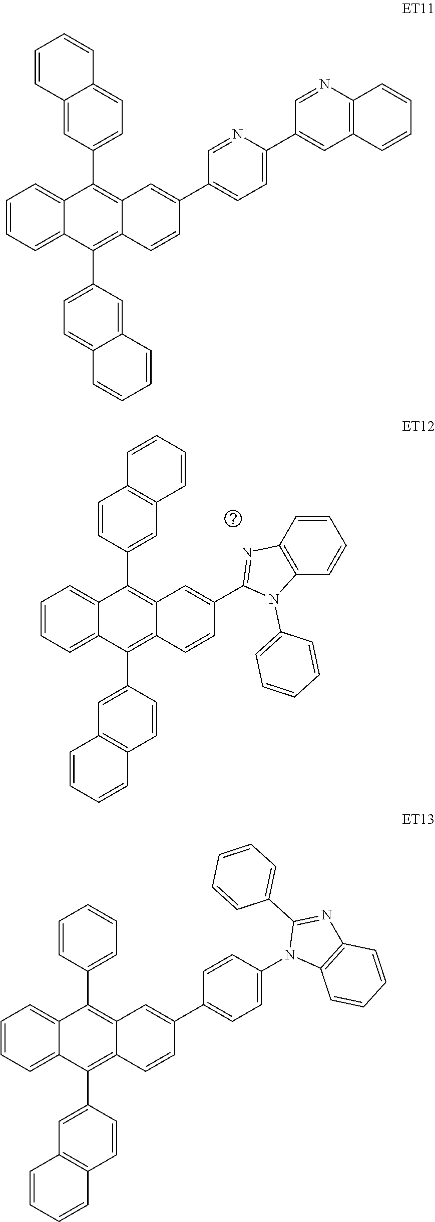 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

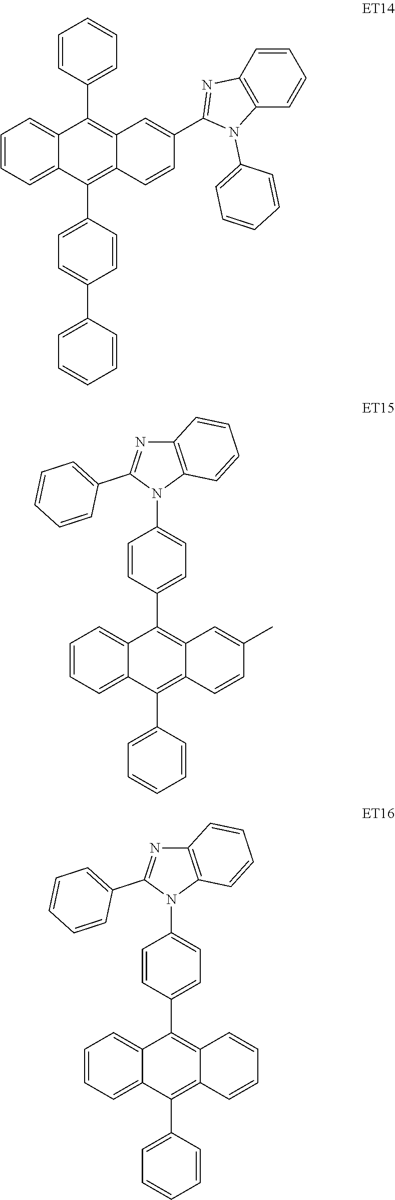

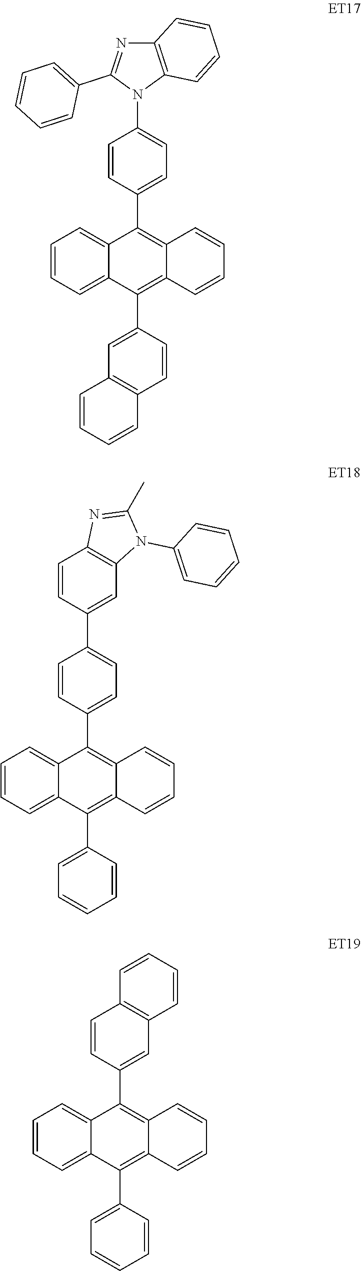

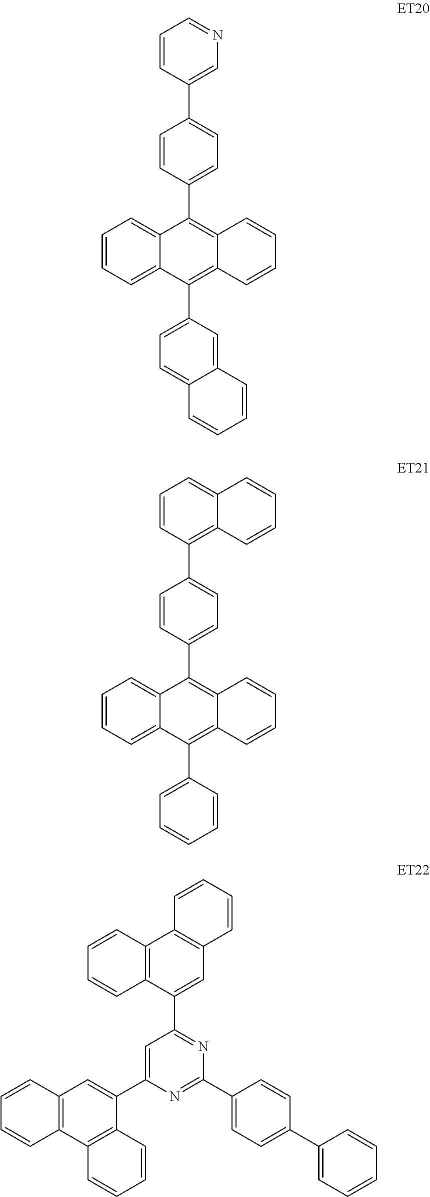

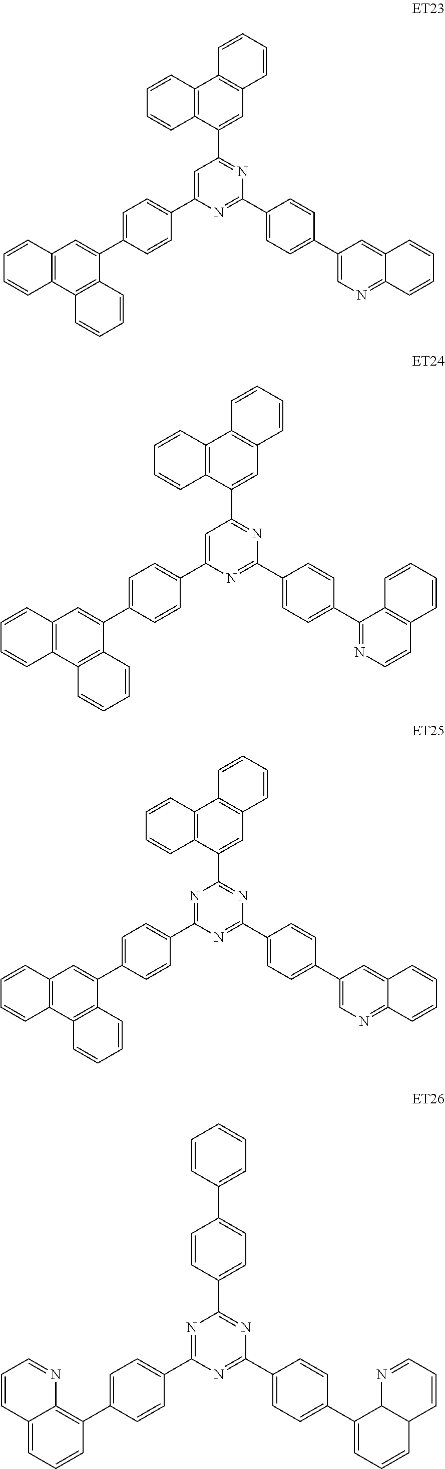 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5ccc(-c6cc7ccccc7c7ccccc67)cc5)cc(-c5cc6ccccc6c6ccccc56)n4)cc3)nccc2c1 ; c1ccc2ncc(-c3ccc(-c4nc(-c5ccc(-c6cc7ccccc7c7ccccc67)cc5)nc(-c5cc6ccccc6c6ccccc56)n4)cc3)cc2c1 ; C1=CC2C=CC=C(c3ccc(-c4nc(-c5ccc(-c6ccccc6)cc5)nc(-c5ccc(-c6cccc7cccnc67)cc5)n4)cc3)C2N=C1]

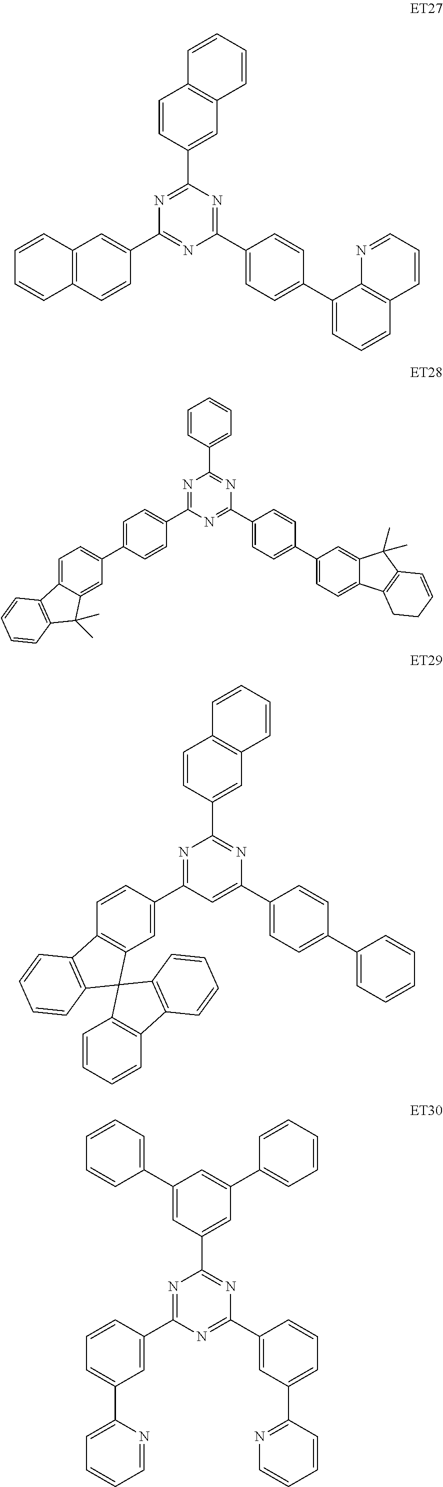

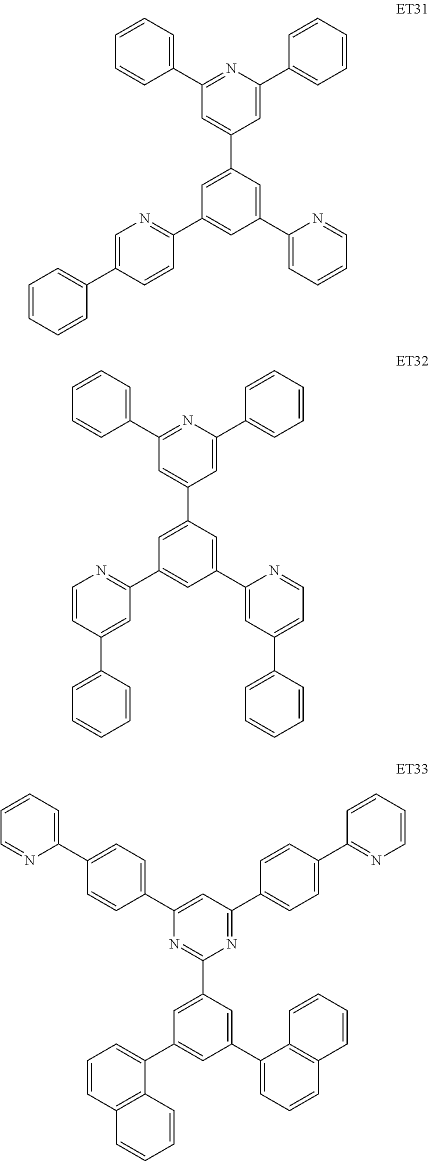 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

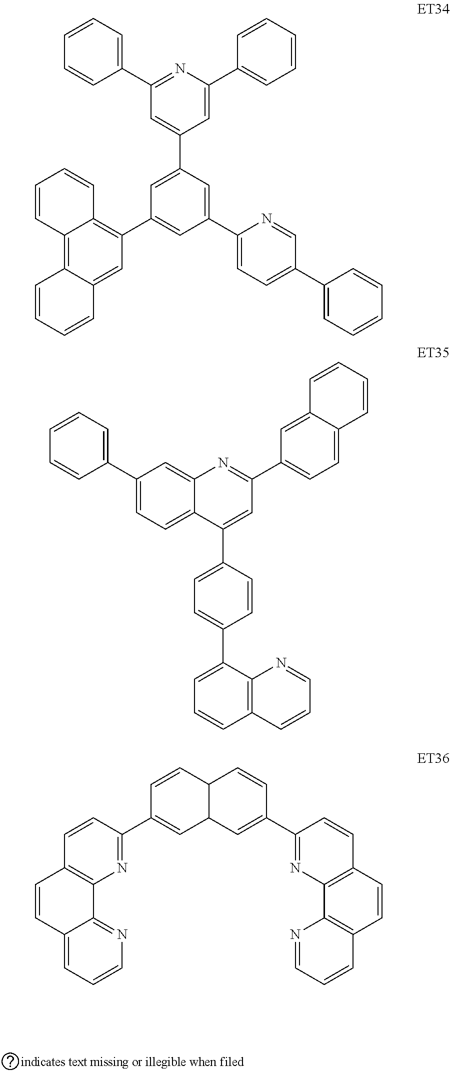

In some embodiments, the electron transport region ETR may include a metal halide (such as LiF, NaCl, CsF, RbCl, RbI, CuI, and/or KI), a lanthanide metal (such as Yb), or a co-deposited material of the metal halide and the lanthanide metal. For example, the electron transport region ETR may include KI:Yb, RbI:Yb, etc., as the co-deposited material. In some embodiments, the electron transport region ETR may utilize a metal oxide (such as Li₂O and/or BaO), or 8-hydroxy-lithium quinolate (LiQ). However, embodiments of the present disclosure are not limited thereto. The electron transport region ETR also may be formed utilizing a mixture material of an electron transport material and an insulating organo metal salt. The organo metal salt may be a material having an energy band gap of about 4 eV or more. For example, the organo metal salt may be or include, for example, metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), and/or 4,7-diphenyl-1,10-phenanthroline (Bphen) in addition to the aforementioned materials. However, embodiments of the present disclosure are not limited thereto.

The electron transport region ETR may include the compounds of the electron transport region in at least one among an electron injection layer EIL, an electron transport layer ETL, and a hole blocking layer HBL.

When the electron transport region ETR includes the electron transport layer ETL, the thickness of the electron transport layer ETL may be about 100 Å to about 1,000 Å, for example, about 150 Å to about 500 Å. When the thickness of the electron transport layer ETL satisfies the above-described range, satisfactory electron transport properties may be obtained without substantial increase of a driving voltage. When the electron transport region ETR includes the electron injection layer EIL, the thickness of the electron injection layer EIL may be about 1 Å to about 100 Å, for example about 3 Å to about 90 Å. When the thickness of the electron injection layer EIL satisfies the above described range, satisfactory electron injection properties may be obtained without inducing a substantial increase in driving voltage.

A second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is a transmissive electrode, the second electrode EL2 may include a transparent metal oxide, for example, ITO, IZO, ZnO, ITZO, etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, compounds including thereof, or mixtures thereof (for example, AgMg, AgYb, or MgAg). In some embodiments, the second electrode EL2 may have a multilayered structure including a reflective layer or a transflective layer formed utilizing the above-described materials and a transparent conductive layer formed utilizing ITO, IZO, ZnO, ITZO, etc.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the organic electroluminescent element ED of an embodiment, a capping layer CPL may be further disposed. The capping layer CPL may include a multilayer or a single layer.

In an embodiment, the capping layer CPL may be an organic material layer or an inorganic material layer. For example, when the capping layer CPL includes an inorganic material, the inorganic material may be or include an alkali metal compound (such as LiF), an alkaline earth metal compound (such as MgF₂, SiON, SiNₓ, and/or SiO_{y}), etc.

For example, when the capping layer CPL includes an organic material, the organic material may be or include α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol-9-yl) triphenylamine (TCTA), an epoxy resin, an acrylate (such as methacrylate), etc.

In some embodiments, the capping layer CPL may include at least one among Compounds P1 to P5, but embodiments of the present disclosure are not limited thereto.

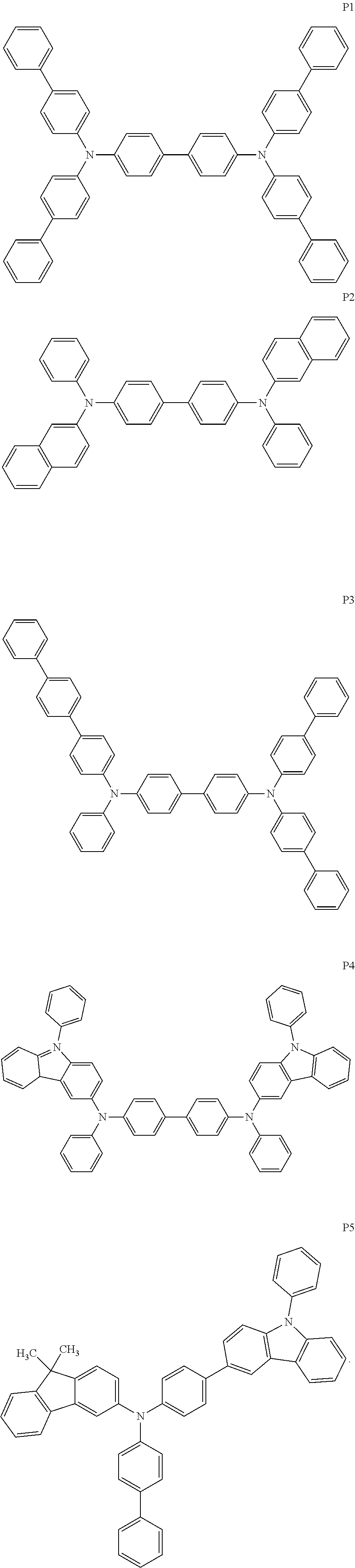

In some embodiments, the refractive index of the capping layer CPL may be about 1.6 or more. For example, the refractive index of the capping layer CPL with respect to light in a wavelength range of about 550 nm to about 660 nm may be about 1.6 or more.

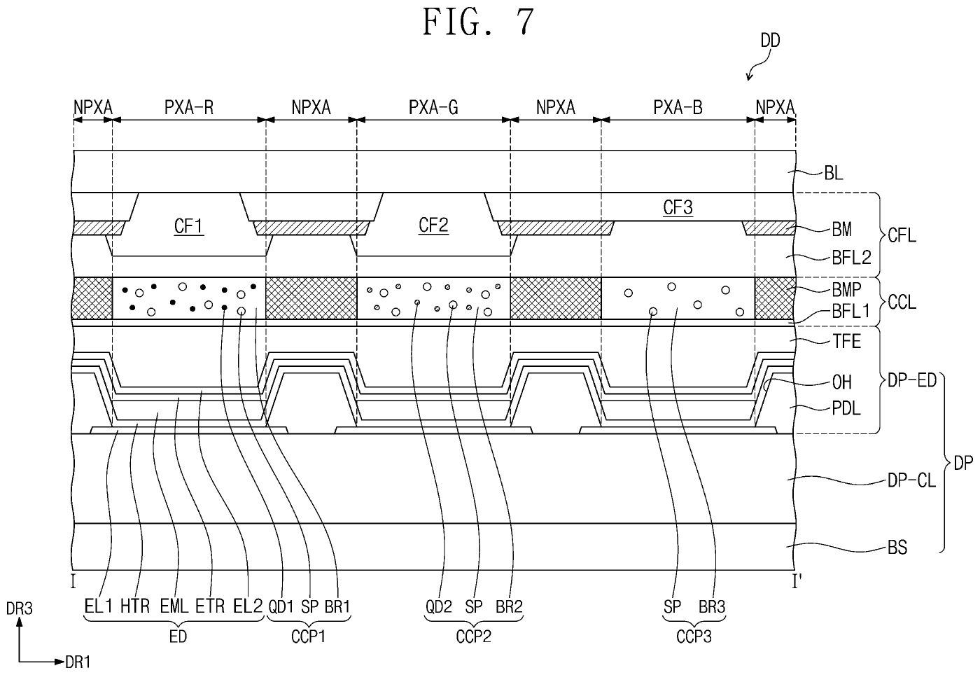

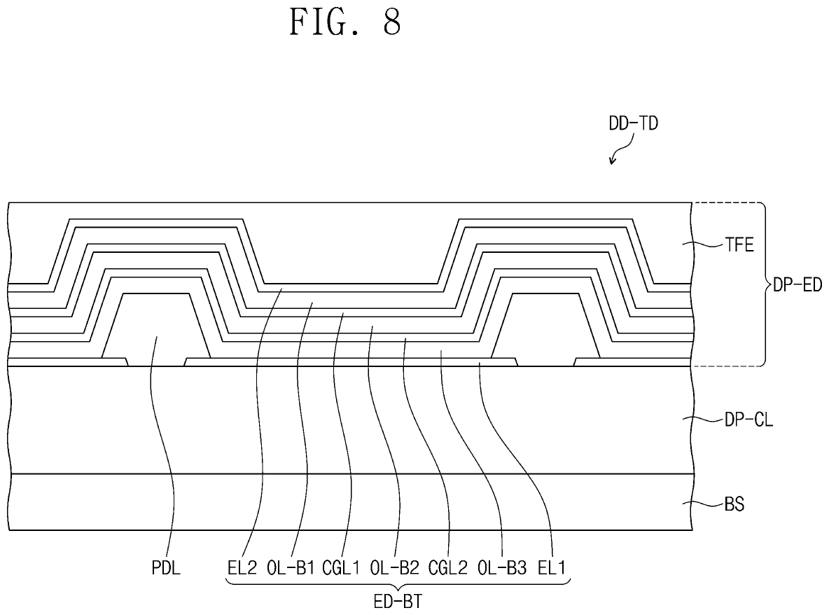

FIG. 7 and FIG. 8 are cross-sectional views of display apparatuses according to respective embodiments. In the explanation on the display apparatuses of embodiments, referring to FIG. 7 and FIG. 8, the overlapping parts with the explanation on FIG. 1 to FIG. 6 will not be explained again, and the different features will be explained chiefly.

Referring to FIG. 7, the display apparatus DD according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED, and the display device layer DP-ED may include an organic electroluminescent element ED.

The organic electroluminescent element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the organic electroluminescent elements of FIG. 4 to FIG. 6 may be applied to the structure of the organic electroluminescent element ED shown in FIG. 7.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G, and PXA-B may be to emit light in substantially the same wavelength region (e.g., in all areas). In the display apparatus DD of an embodiment, the emission layer EML may be to emit blue light. In some embodiments, the emission layer EML may be provided as a common layer to all luminous areas PXA-R, PXA-G, and PXA-B.

The light controlling layer CCL may be disposed on the display panel DP. The light controlling layer CCL may include a light converter. The light converter may be a quantum dot or a phosphor. The light converter may be to transform the wavelength of light provided and then emit the transformed light. For example, the light controlling layer CCL may be a layer including a quantum dot or a layer including a phosphor.

The core of the quantum dot may be selected from a Group II-VI compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-VI compound may be or include a binary compound (such as In₂S₃ and/or In₂Se₃), a ternary compound (such as InGaS₃ and/or InGaSe₃), or optional combinations thereof.

The Group I-III-VI compound may be selected from a ternary compound selected from the group consisting of AgInS, AgInS₂, CuInS, CulnS₂, AgGaS₂, CuGaS₂, CuGaO₂, AgGaO₂, AgAlO₂ and mixtures thereof, or a quaternary compound (such as AgInGaS₂ and/or CulnGaS₂).

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

The binary compound, the ternary compound, and/or the quaternary compound may each be present at substantially uniform concentrations in a particle, or may be present at a partially different concentration (e.g., gradient) distribution state in the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may be or include a metal or non-metal oxide, a semiconductor compound, or combinations thereof.

For example, the metal or non-metal oxide may be or include a binary compound (such as SiO₂, Al₂O₃, TiO₂, ZnO, MnO, Mn₂O₃, Mn₃O₄, CuO, FeO, Fe₂O₃, Fe₃O₄, CoO, CO₃O₄ and/or NiO), or a ternary compound (such as MgAl₂O₄, CoFe₂O₄, NiFe₂O₄ and/or CoMn₂O₄), but embodiments of the present disclosure are not limited thereto.

The semiconductor compound may be or include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have an emission wavelength spectrum full width at half maximum (FWHM) of about 45 nm or less, about 40 nm or less, or about 30 nm or less. Within this range, color purity or color reproducibility may be improved. In some embodiments, light emitted via such quantum dots may be emitted in all directions, and light view angle properties may be improved.

The shape of the quantum dot may be any generally utilized shape in the art, without specific limitation. For example, a spherical, pyramidal, multi-arm, or cubic nanoparticle, nanotube, nanowire, nanofiber, or nanoplate particle, etc. may be utilized.

The quantum dot may control the color of light emitted according to the particle size, and accordingly, the quantum dot may provide various suitable emission colors (such as blue, red and/or green).

The light controlling layer CCL may include multiple light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but at least a portion of the edge of the light controlling parts CCP1, CCP2, and CCP3 may be overlapped with the partition pattern BMP.

The light controlling layer CCL may include a first light controlling part CCP1 including a first quantum dot QD1 converting first color light provided from the organic electroluminescent element ED into second color light, a second light controlling part CCP2 including a second quantum dot QD2 converting first color light into third color light, and a third light controlling part CCP3 transmitting first color light.

In an embodiment, the first light controlling part CCP1 may provide red light (which is the second color light), and the second light controlling part CCP2 may provide green light (which is the third color light). The third color controlling part CCP3 may be to transmit and provide blue light (which is the first color light provided from the organic electroluminescent element ED). For example, the first quantum dot QD1 may be a red quantum dot, and the second quantum dot QD2 may be a green quantum dot. The quantum dots QD1 and QD2 may be the same as described above.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but may include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica, or may be a mixture of two or more materials selected among TiO₂, ZnO, Al₂O₃, SiO₂, and hollow silica.

The light controlling layer CCL may include a barrier layer BFL1. The barrier layer BFL1 may block or reduce the penetration of moisture and/or oxygen (hereinafter referred to as “humidity/oxygen”). The barrier layer BFL1 may be disposed on the light controlling parts CCP1, CCP2, and CCP3 to block or reduce the exposure of the light controlling parts CCP1, CCP2, and CCP3 to humidity/oxygen. In some embodiments, the barrier layer BFL1 may cover the light controlling parts CCP1, CCP2 and CCP3. In some embodiments, the barrier layer BFL2 may be provided between the color filter layer CFL and each of the light controlling parts CCP1, CCP2, and CCP3.

The barrier layers BFL1 and BFL2 may each include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film that transmits light. In some embodiments, the barrier layers BFL1 and BFL2 may each further include an organic layer. The barrier layers BFL1 and BFL2 may each independently be composed of a single layer or multiple layers.

In the display apparatus DD of an embodiment, the color filter layer CFL may be disposed on the light controlling layer CCL. For example, the color filter layer CFL may be disposed directly on the light controlling layer CCL. In this case, the barrier layer BFL2 may not be provided.

The color filter layer CFL may include a light blocking part BM and filters CF1, CF2, and CF3. The color filter layer CFL may include a first filter CF1 to transmit second color light, a second filter CF2 to transmit third color light, and a third filter CF3 to transmit first color light. For example, the first filter CF1 may be a red filter, the second filter CF2 may be a green filter, and the third filter CF3 may be a blue filter. Each of the filters CF1, CF2, and CF3 may include a polymer photosensitive resin, a pigment, and/or a dye. The first filter CF1 may include a red pigment and/or dye, the second filter CF2 may include a green pigment and/or dye, and the third filter CF3 may include a blue pigment and/or dye. In some embodiments, embodiments of the present disclosure are not limited thereto, and the third filter CF3 may not include (e.g., may exclude) the pigment or dye. The third filter CF3 may include a polymer photosensitive resin and may not include a pigment or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided as one body without distinction.

The light blocking part BM may be a black matrix. The light blocking part BM may be formed by including an organic light blocking material and/or an inorganic light blocking material including a black pigment and/or black dye. The light blocking part BM may prevent or reduce light leakage phenomenon and divide the boundaries among adjacent filters CF1, CF2, and CF3. In some embodiments, the light blocking part BM may be formed as a blue filter.

Each of the first to third filters CF1, CF2, and CF3 may be disposed to correspond to each of a red luminous area PXA-R, a green luminous area PXA-G, and a blue luminous area PXA-B.

On the color filter layer CFL, a base substrate BL may be disposed. The base substrate BL may provide a base surface on which the color filter layer CFL, the light controlling layer CCL, etc. are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

FIG. 8 is a cross-sectional view showing a portion of the display apparatus corresponding to the display panel DP in FIG. 7. In a display apparatus DD-TD of an embodiment, the organic electroluminescent element ED-BT may include multiple light emitting structures OL-B1, OL-B2, and OL-B3. The organic electroluminescent element ED-BT may include a first electrode EL1 and a second electrode EL2 oppositely disposed, and multiple light emitting structures OL-B1, OL-B2, and OL-B3 stacked in order in a thickness direction between the first electrode EL1 and the second electrode EL2. Each of the light emitting structures OL-B1, OL-B2, and OL-B3 may include an emission layer EML (FIG. 7), and a hole transport region HTR and an electron transport region ETR disposed with the emission layer EML (FIG. 7) therebetween.

For example, the organic electroluminescent element ED-BT included in the display apparatus DD-TD of an embodiment may be an organic electroluminescent element of a tandem structure including multiple emission layers.

In an embodiment shown in FIG. 8, light emitted from all of the light emitting structures OL-B1, OL-B2, and OL-B3 may be blue light. However, embodiments of the present disclosure are not limited thereto, and the wavelength regions of light emitted from the light emitting structures OL-B1, OL-B2, and OL-B3 may be different from each other. For example, the organic electroluminescent element ED-BT including the multiple light emitting structures OL-B1, OL-B2, and OL-B3 to emit light in different wavelength regions may be to emit white light.

A charge generating layer CGL may be disposed between neighboring light emitting structures OL-B1, OL-B2, and OL-B3. The charge generating layer CGL may include a p-type charge generating layer and/or an n-type charge generating layer.

Hereinafter, the compound of an embodiment of the present disclosure and the organic electroluminescent element of an embodiment will be explained referring to Example embodiments and Comparative embodiments. The embodiments are only illustrations to assist in understanding of the present disclosure, and the scope of the present disclosure is not limited thereto.

### Examples

### 1. Synthesis of Fused Polycyclic Compounds

First, a synthetic method of the fused polycyclic compound according to an embodiment will be explained by referring to the synthetic methods of Compounds 2, 16, 29, 38, and 50. The synthetic methods of the fused polycyclic compounds explained below are only illustrations, and are not limited to the embodiments below.

### (1) Synthesis of Compound 2

Fused Polycyclic Compound 2 according to an embodiment may be synthesized by, for example, the reaction below.

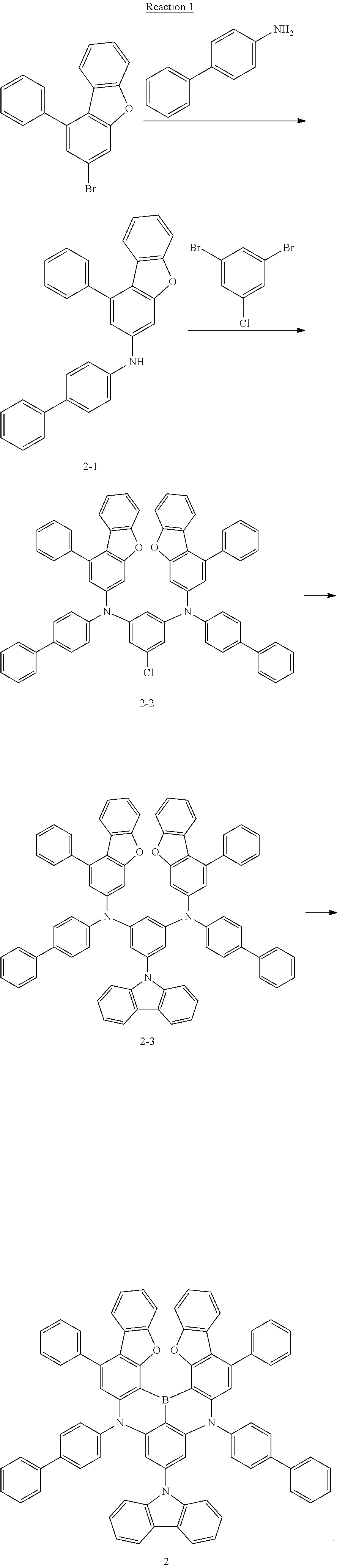

### Synthesis of Intermediate 2-1

3-bromo-1-phenyldibenzo[b,d]furan (1 eq), [1,1′-biphenyl]-4-amine (1 eq), tris(dibenzylideneacetone)dipalladium(0) (0.05 eq), P(tBu)₃ (0.1 eq), and sodium tert-butoxide (2 eq) were dissolved in toluene, followed by stirring under a nitrogen atmosphere at about 110 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 2-1 (yield: 80%).

### Synthesis of Intermediate 2-2

Intermediate 2-1 (2 eq), 1,3-dibromo-5-chlorobenzene (1 eq), tris(dibenzylideneacetone)dipalladium(0) (0.05 eq), P(tBu)₃ (0.1 eq), and sodium tert-butoxide (2 eq) were dissolved in toluene, followed by stirring under a nitrogen atmosphere at about 110 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 2-2 (yield: 75%).

### Synthesis of Intermediate 2-3

Intermediate 2-2 (1 eq), 9H-carbazole (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 2-3 (yield: 70%).

### Synthesis of Compound 2

Intermediate 2-3 (1 eq) and boron tribromide (3 eq) were dissolved in orthodichlorobenzene (ODCB), followed by stirring under a nitrogen atmosphere at about 180 degrees centigrade for about 24 hours. After cooling, the stirred mixture was quenched with triethylamine and filtered with methanol, and the solid thus obtained was dried. The residue thus obtained was separated and purified by column chromatography to obtain Compound 2 (yield: 20%).

### (2) Synthesis of Compound 16

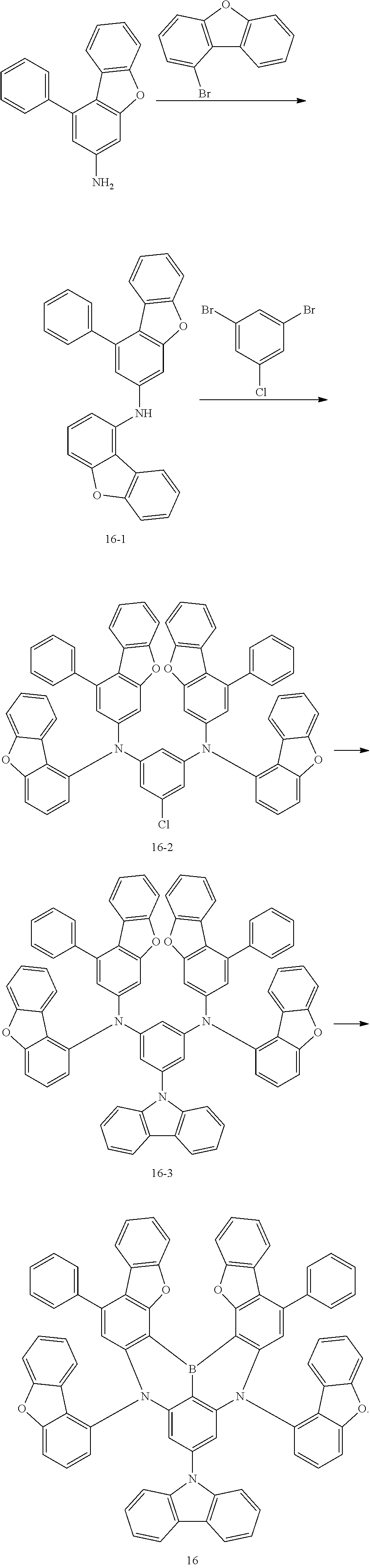

### Synthesis of Intermediate 16-1

1-phenyldibenzo[b,d]furan-3-amine (1 eq), 1-bromodibenzo[b,d]furan (1 eq), tris(dibenzylideneacetone)dipalladium(0) (0.05 eq), P(tBu)₃ (0.1 eq), and sodium tert-butoxide (2 eq) were dissolved in toluene, followed by stirring under a nitrogen atmosphere at about 110 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 16-1 (yield: 73%).

### Synthesis of Intermediate 16-2

Intermediate 16-1 (2 eq), 1,3-dibromo-5-chlorobenzene (1 eq), tris(dibenzylideneacetone)dipalladium(0) (0.05 eq), P(tBu)₃ (0.1 eq), and sodium tert-butoxide (2 eq) were dissolved in toluene, followed by stirring under a nitrogen atmosphere at about 110 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 16-2 (yield: 70%).

### Synthesis of Intermediate 16-3

Intermediate 16-2 (1 eq), 9H-carbazole (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 16-3 (yield: 78%).

### Synthesis of Compound 16

Intermediate 16-3 (1 eq), and boron tribromide (3 eq) were dissolved in ODCB, followed by stirring under a nitrogen atmosphere at about 180 degrees centigrade for about 24 hours. After cooling, the stirred mixture was quenched with triethylamine and filtered with methanol, and the solid thus obtained was dried. The residue thus obtained was separated and purified by column chromatography to obtain Compound 16 (yield: 25%).

### (3) Synthesis of Compound 29

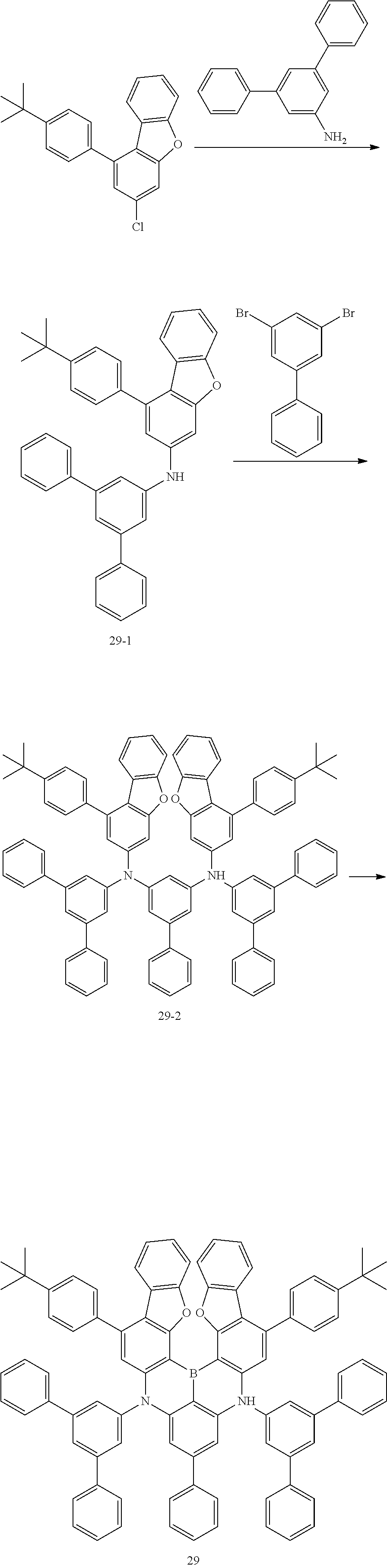

### Synthesis of Intermediate 29-1

1-(4-(tert-butyl)phenyl)-3-chlorodibenzo[b,d]furan (1 eq), [1,1′:3′,1″-terphenyl]-5′-amine (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄), and then dried under reduced pressure. The residue thus obtained was separated and purified by column chromatography to obtain Intermediate 29-1 (yield: 75%).

### Synthesis of Intermediate 29-2

Intermediate 29-1 (2 eq), 3,5-dibromo-1,1′-biphenyl (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 29-2 (yield: 80%).

### Synthesis of Compound 29

Intermediate 29-2 (1 eq), and boron tribromide (3 eq) were dissolved in ODCB, followed by stirring under a nitrogen atmosphere at about 180 degrees centigrade for about 24 hours. After cooling, the stirred mixture was quenched with triethylamine and filtered with methanol, and the solid thus obtained was dried. The residue thus obtained was separated and purified by column chromatography to obtain Compound 29 (yield: 31%).

### (4) Synthesis of Compound 38

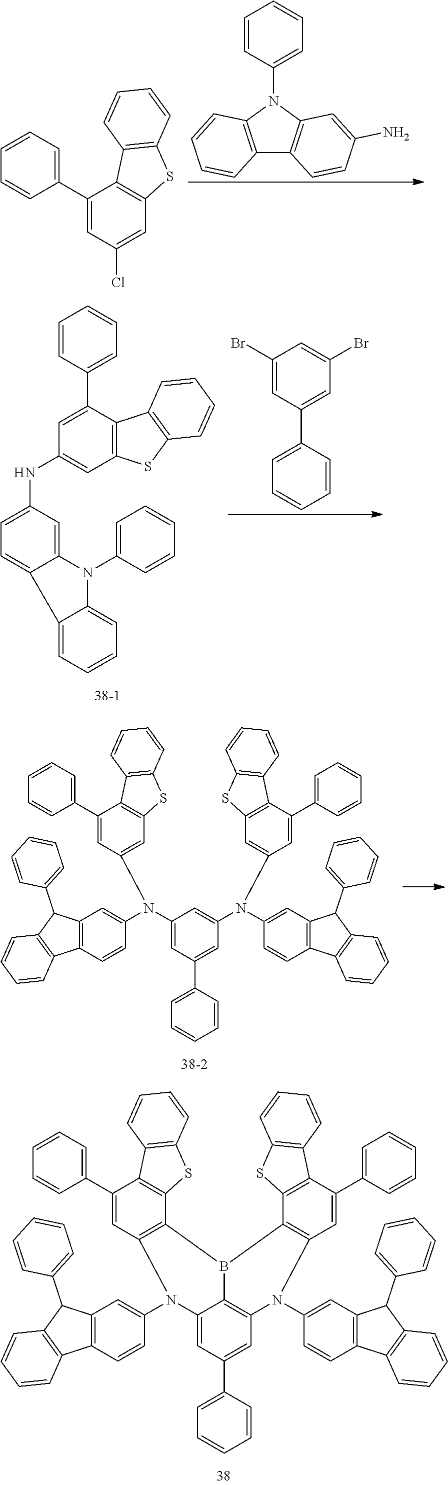

### Synthesis of Intermediate 38-1

3-chloro-1-phenyldibenzo[b,d]thiophene (1 eq), 9-phenyl-9H-carbazol-3-amine (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then, dried under a reduced pressure. The residue thus obtained was separated and purified by column chromatography to obtain Intermediate 38-1 (yield: 70%).

### Synthesis of Intermediate 38-2

Intermediate 38-1 (2 eq), 3,5-dibromo-1,1′-biphenyl (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 38-2 (yield: 76%).

### Synthesis of Compound 38

Intermediate 38-2 (1 eq), and boron tribromide (3 eq) were dissolved in ODCB, followed by stirring under a nitrogen atmosphere at about 180 degrees centigrade for about 24 hours. After cooling, the stirred mixture was quenched with triethylamine and filtered with methanol, and the solid thus obtained was dried. The residue thus obtained was separated and purified by column chromatography to obtain Compound 38 (yield: 23%).

### (5) Synthesis of Compound 50

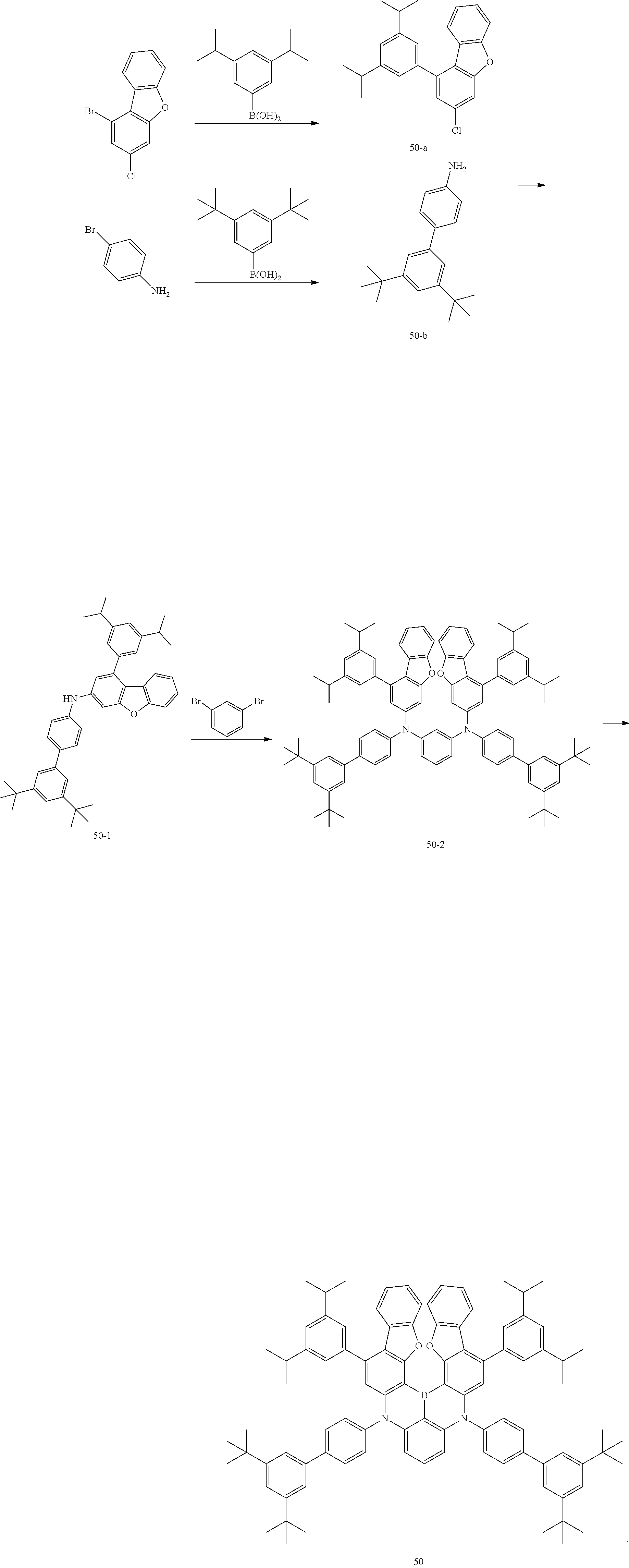

### Synthesis of Intermediate 50-a

1-bromo-3-chlorodibenzo[b,d]furan (1 eq), (3,5-diisopropylphenyl)boronic acid (1.5 eq), CuI (0.05 eq), tetrabutylammonium bromide (TBAB) (0.1 eq), and Na₂CO₃ (2.5 eq) were dissolved in a solvent of toluene/EtOH/H₂O (5:1:2), followed by stirring under a nitrogen atmosphere at about 100 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 50-a (yield: 63%).

### Synthesis of Intermediate 50-b

1-bromoaniline (1 eq), (3,5-di-tert-butylphenyl)boronic acid (1.5 eq), CuI (0.05 eq), TBAB (0.1 eq), and Na₂CO₃ (2.5 eq) were dissolved in a solvent of toluene/EtOH/H₂O (5:1:2), followed by stirring under a nitrogen atmosphere at about 100 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 50-b (yield: 82%).

### Synthesis of Intermediate 50-1

Intermediate 50-a (1 eq), Intermediate 50-b (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 50-1 (yield: 85%).

### Synthesis of Intermediate 50-2

Intermediate 50-1 (2 eq), 1,3-dibromobenzene (1 eq), tris(dibenzylideneacetone)dipalladium(0) (0.05 eq), P(tBu)₃ (0.1 eq), and sodium tert-butoxide (2 eq) were dissolved in xylene, followed by stirring under a nitrogen atmosphere at about 140 degrees centigrade for about 12 hours. After cooling, the stirred mixture was washed with ethyl acetate and water three times each to obtain an organic layer, and the organic layer was dried with magnesium sulfate (MgSO₄) and then dried under reduced pressure. The residue thus obtained was separated and purified by column chromatography to obtain Intermediate 50-2 (yield: 80%).

### Synthesis of Compound 50

Intermediate 50-2 (1 eq), and boron tribromide (3 eq) were dissolved in ODCB, followed by stirring under a nitrogen atmosphere at about 180 degrees centigrade for about 24 hours. After cooling, the stirred mixture was quenched with triethylamine and filtered with methanol, and the solid thus obtained was dried. The residue thus obtained was separated and purified by column chromatography to obtain Compound 50 (yield: 26%).

The ¹H NMR and MS/FAB of the compounds thus synthesized are shown in Table 1. The synthetic methods of other compounds other than the compounds shown in Table 1 may be easily recognized by a person skilled in the art referring to the synthetic methods and raw materials above.

TABLE 1

| | | MS/FAB | |
|---|---|---|---|
| Compound | H NMR (δ) | Calc | Found |
| 2 | 1H-NMR (400 MHz, CDCl3): 8.45 (s, | 1069.38 | 1069.39 |
| | 2H), 8.22 (dd, 2H), 7.98-7.92 (m, 4H), | | |
| | 7.82-7.69 (m, 4H), 7.62-7.43 (m, 16H), | | |
| | 7.41-7.23 (m, 14H), 7.20-7.16 (m, 4H), | | |
| | 6.89 (s, 2H). | | |
| 16 | 1H-NMR (400 MHz, CDCl3): 8.40 (s, | 1097.34 | 1097.35 |
| | 2H), 8.03 (dd, 2H), 7.98 (dd, 4H), 7.79- | | |
| | 7.72 (m, 4H), 7.58-7.46 (m, 15H), 7.41- | | |
| | 7.20 (m, 15H), 6.88 (s, 2H). | | |
| 29 | 1H-NMR (400 MHz, CDCl3): 8.41 (s, | 1244.55 | 1244.53 |
| | 2H), 8.20 (dd, 2H), 7.75-7.69 (m, 12H), | | |
| | 7.60-7.49 (m, 16H), 7.49-7.27 (m, | | |
| | 17H), 6.93 (s, 2H), 1.35 (s, 18H). | | |
| 38 | 1H-NMR (400 MHz, CDCl3): 8.50 (s, | 1190.36 | 1190.35 |
| | 2H), 8.24 (dd, 4H), 7.94 (d, 2H), 7.79- | | |
| | 7.65 (m, 9H), 7.62-7.55 (m, 15H), 7.54- | | |
| | 7.16 (m, 17H), 6.90 (s, 2H). | | |
| 50 | 1H-NMR (400 MHz, CDCl3): 8.41 (s, | 1297.77 | 1297.76 |
| | 2H), 7.98 (d, 2H), 7.84-7.73 (ss, 8H), | | |
| | 7.61-7.52 (m, 10H), 7.50-7.24 (m, 9H), | | |
| | 6.95 (s, 2H), 2.85 (m, 4H), 1.34 (s, | | |
| | 36H), 1.28 (d, 24H). | | |

### 2. Manufacture and Evaluation of Organic Electroluminescent Elements Including Fused Polycyclic Compounds

Organic electroluminescent elements including the Example Compounds and Comparative Compounds in an emission layer were manufactured by a method below.

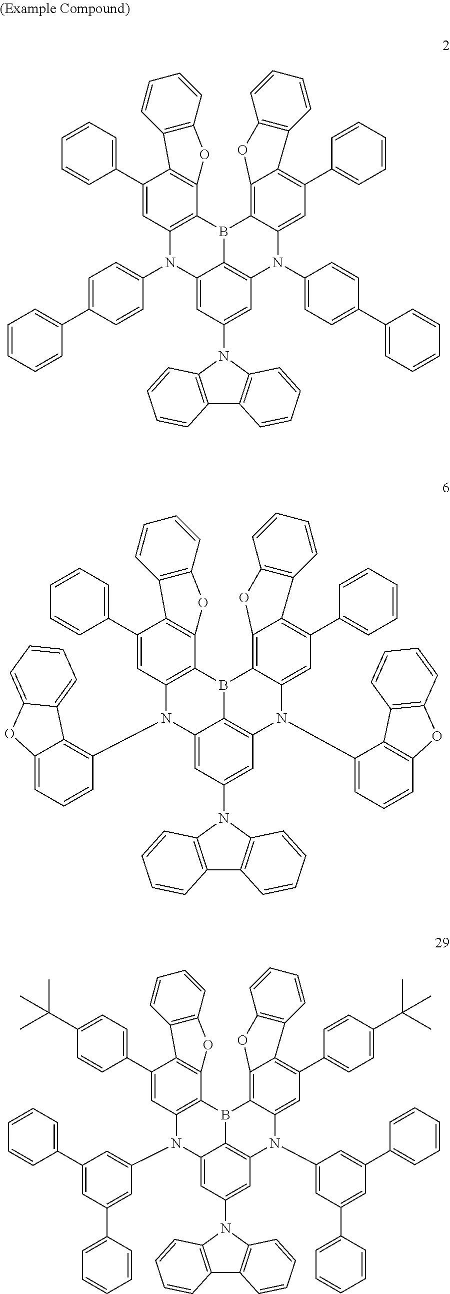 [SMILES: c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2cc3c(c4oc5ccccc5c24)B2c4c(cc(-n5c6ccccc6c6ccccc65)cc4N(c4cccc5oc6ccccc6c45)c4cc(-c5ccccc5)c5c(oc6ccccc65)c42)N3c2cccc3oc4ccccc4c23)cc1 ; CC(C)(C)c1ccc(-c2cc3c(c4oc5ccccc5c24)B2c4c(cc(-n5c6ccccc6c6ccccc65)cc4N(c4cc(-c5ccccc5)cc(-c5ccccc5)c4)c4cc(-c5ccc(C(C)(C)C)cc5)c5c(oc6ccccc65)c42)N3c2cc(-c3ccccc3)cc(-c3ccccc3)c2)cc1]

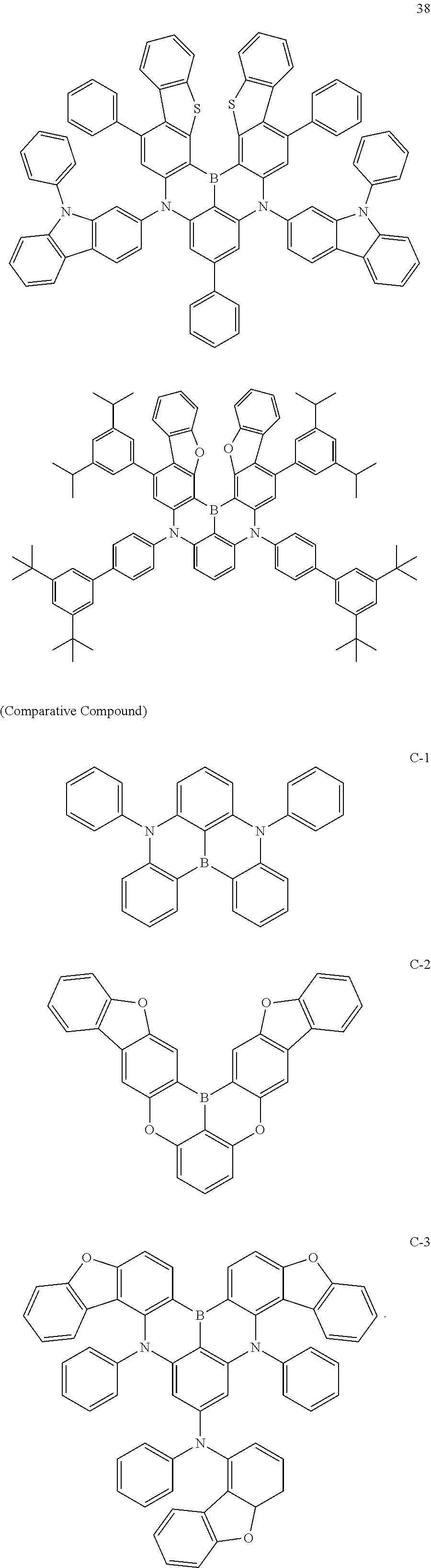

### (Manufacture of Organic Electroluminescent Elements)

In order to form a first electrode, an ITO glass substrate with about 15 Ω/cm² (1200 Å) of Corning Co. was cut into a size of 50 mm×50 mm×0.7 mm, washed with ultrasonic waves utilizing isopropyl alcohol and pure water for about five minutes each, exposed to ultraviolet rays for about 30 minutes and cleansed by exposing to ozone. Then, the glass substrate was installed on a vacuum deposition apparatus.

On the glass substrate, NPD was vacuum deposited to a thickness of about 300 Å to form a hole injection layer, and the compound according to Table 1 above was vacuum deposited on the hole injection layer to a thickness of about 200 Å to form a hole transport layer. On the hole transport layer, CzSi was vacuum deposited to a thickness of about 100 Å.

On the layer, mCP and the Example Compound according to Table 1 or Comparative Compound were deposited concurrently (e.g., simultaneously) in a weight ratio of 99:1 to form an emission layer having a thickness of about 200 Å.

Then, TSPO1 was vacuum deposited to a thickness of about 200 Å to form an electron transport layer, and TPBi was vacuum deposited to a thickness of about 300 Å to form an electron injection layer.

On the electron transport layer, an alkali metal halide of LiF was deposited to a thickness of about 10 Å, and Al was vacuum deposited to a thickness of about 3,000 Å to form a LiF/AI second electrode to manufacture an organic electroluminescent element.

The compounds utilized for the manufacture of the organic electroluminescent elements are shown.

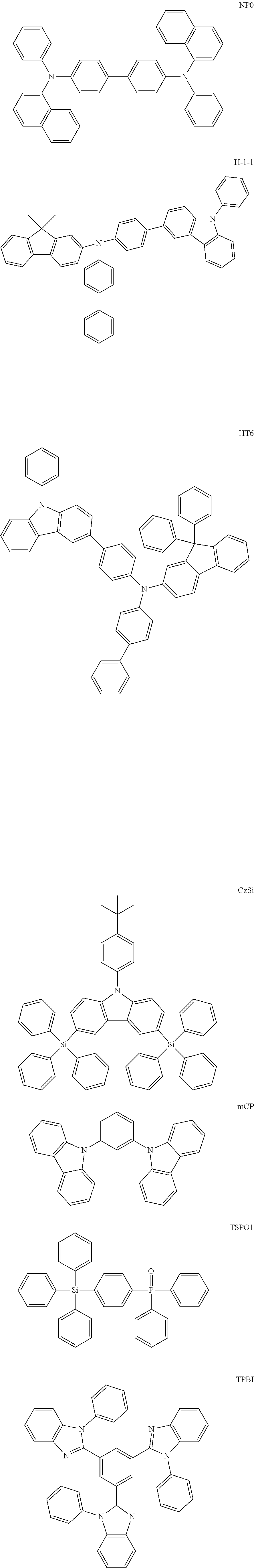

### (Evaluation of Properties of Organic Electroluminescent Elements)

In Table 2, evaluation results for the organic electroluminescent elements of Example 1-1 to Example 2-5, and Comparative Example 1 to Comparative Example 4 are shown.

In the evaluation results on the properties of the Examples and Comparative Examples, shown in Table 2, a driving voltage and emission efficiency were measured at a current density of about 10 mA/cm².

TABLE 2

| | Hole | | Driving | Emission | Maximum | |
|---|---|---|---|---|---|---|
| | transport | Dopant in | voltage | efficiency | external quantum | Emission |
| | layer material | emission layer | (V) | (cd/A) | efficiency (%) | color |
| Example 1-1 | H-1-1 | Compound 2 | 4.6 | 25.3 | 25.0 | Blue |
| Example 1-2 | H-1-1 | Compound 16 | 4.6 | 25.3 | 24.8 | Blue |
| Example 1-3 | H-1-1 | Compound 29 | 4.6 | 25.7 | 25.4 | Blue |
| Example 1-4 | H-1-1 | Compound 38 | 4.7 | 24.6 | 24.1 | Blue |
| Example 1-5 | H-1-1 | Compound 50 | 4.6 | 24.8 | 24.7 | Blue |
| Example 2-1 | HT6 | Compound 2 | 4.6 | 25.1 | 24.8 | Blue |
| Example 2-2 | HT6 | Compound 16 | 4.7 | 25.0 | 24.7 | Blue |
| Example 2-3 | HT6 | Compound 29 | 4.6 | 25.4 | 25.0 | Blue |
| Example 2-4 | HT6 | Compound 38 | 4.7 | 24.4 | 24.0 | Blue |
| Example 2-5 | HT6 | Compound 50 | 4.6 | 24.5 | 24.3 | Blue |
| Comparative | H-1-1 | C-1 | 5.6 | 14.6 | 14.3 | Blue |
| Example 1 | | | | | | |
| Comparative | HT6 | C-1 | 5.6 | 14.4 | 14.2 | Blue |
| Example 2 | | | | | | |
| Comparative | H-1-1 | C-2 | 5.7 | 12.3 | 11.9 | Blue |
| Example 3 | | | | | | |
| Comparative | H-1-1 | C-3 | 5.7 | 13.0 | 12.6 | Blue |
| Example 4 | | | | | | |

Referring to the results of Table 2, it could be found that the Examples of the organic electroluminescent elements utilizing the embodiment fused polycyclic compounds as emission layer materials showed lower driving voltages and higher emission efficiencies when compared to the Comparative Examples.

The organic electroluminescent element of an embodiment includes the fused polycyclic compound of an embodiment and may show an improved driving voltage and/or emission efficiency. The organic electroluminescent element of an embodiment includes the fused polycyclic compound of an embodiment as a material for an emission layer, and may accomplish a low driving voltage and/or a high emission efficiency in a blue light wavelength region.

The organic electroluminescent element of an embodiment may show improved device characteristics of a low driving voltage and/or a high efficiency.

Terms such as “substantially,” “about,” and “˜” are used as terms of approximation and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Although embodiments of the present disclosure have been described, it is understood that the present disclosure should not be limited to these embodiments, but various changes and modifications can be made by one ordinary skilled in the art within the spirit and scope of the present disclosure as hereinafter claimed.

What is claimed is:

1. An organic electroluminescent element, comprising:
a first electrode;
a hole transport region on the first electrode;
an emission layer on the hole transport region;
an electron transport region on the emission layer; and
a second electrode on the electron transport region,
wherein the hole transport region comprises an amine compound represented by Formula H-1, and
the emission layer comprises a fused polycyclic compound represented by Formula 1: 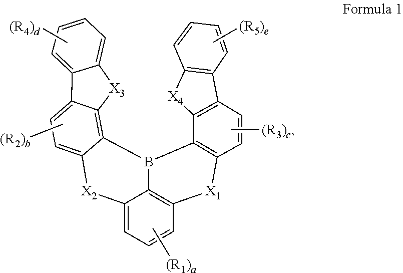
wherein in Formula 1,
X₁ to X₄ are each independently CRₐ₁Rₐ₂, NRₐ₃, O, S, or Se,
R₁ to R₅ and Rₐ₁ to Rₐ₃ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
“a” is an integer of 0 to 3,
“b” and “c” are each independently an integer of 0 to 2, and
“d” and “e” are each independently an integer of 0 to 4, 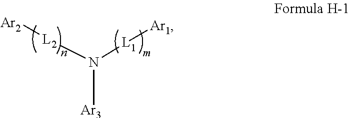
and
wherein in Formula H-1,
L₁ and L₂ are each independently a direct linkage, a substituted or unsubstituted arylene group of 6 to 30 ring-forming carbon atoms, or a substituted or unsubstituted heteroarylene group of 2 to 30 ring-forming carbon atoms,
“m” and “n” are each independently an integer of 0 to 10,
Ar₁ and Ar₂ are each independently a substituted or unsubstituted aryl group of 6 to 30 ring-forming carbon atoms, or a substituted or unsubstituted heteroaryl group of 2 to 30 ring-forming carbon atoms, and
Ar₃ is a substituted or unsubstituted aryl group of 6 to 30 ring-forming carbon atoms.

2. The organic electroluminescent element of claim 1, wherein the emission layer is to emit delayed fluorescence.

3. The organic electroluminescent element of claim 1, wherein:
the emission layer comprises a host and a dopant, and
the dopant comprises the fused polycyclic compound represented by Formula 1.

4. The organic electroluminescent element of claim 1, wherein the hole transport region comprises:
a hole injection layer on the first electrode; and
a hole transport layer on the hole injection layer, and
the hole transport layer comprises the amine compound represented by Formula H-1.

5. The organic electroluminescent element of claim 4, wherein the hole transport region further comprises an electron blocking layer on the hole transport layer.

6. The organic electroluminescent element of claim 1, further comprising a capping layer on the second electrode and having a refractive index of about 1.6 or more.

7. The organic electroluminescent element of claim 1, wherein X₁ and X₂ are the same.

8. The organic electroluminescent element of claim 1, wherein:
“b” and “c” are integers of 1 or more, and
R₂ and R₃ are each independently a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

9. The organic electroluminescent element of claim 1, wherein the fused polycyclic compound represented by Formula 1 is represented by Formula 2: 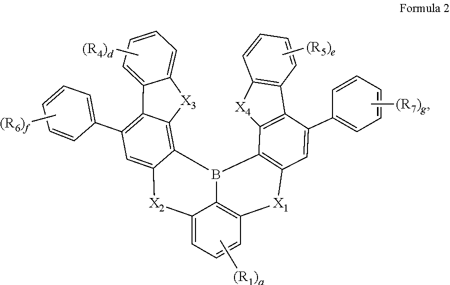
and
wherein in Formula 2,
R₆ and R₇ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
“f” and “g” are each independently an integer of 0 to 5, and
X₁ to X₄, R₁, R₄, R₅, “a”, “d”, and “e” are each independently the same as defined in Formula 1.

10. The organic electroluminescent element of claim 9, wherein the fused polycyclic compound represented by Formula 2 is represented by Formula 3: 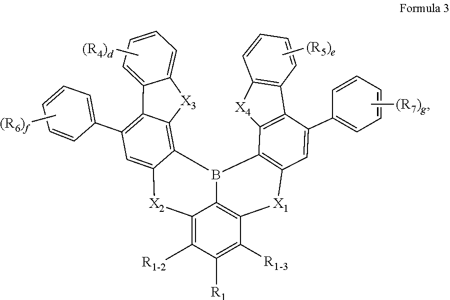
and
wherein in Formula 3,
R₁ is a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
R₁₋₂ and R₁₋₃ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, and
X₁ to X₄, R₄ to R₇, and “d” to “g” are each independently the same as defined in Formula 2.

11. The organic electroluminescent element of claim 10, wherein:
R₁₋₂ and R₁₋₃ are each independently a hydrogen atom, and
R₁ is a substituted or unsubstituted aryl group of 6 to 60 ring-forming carbon atoms, or a substituted or unsubstituted heteroaryl group of 2 to 60 ring-forming carbon atoms.

12. The organic electroluminescent element of claim 10, wherein the fused polycyclic compound represented by Formula 3 is represented by Formula 4: 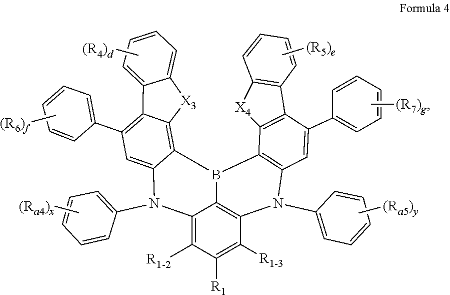
and
wherein in Formula 4,
Rₐ₄ and Rₐ₅ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring,
“x” and “y” are each independently an integer of 0 to 5, and
X₃, X₄, R₁, R₁₋₂, R₁₋₃, R₄ to R₇, and “d” to “g” are each independently the same as defined in Formula 3.

13. The organic electroluminescent element of claim 1, wherein the fused polycyclic compound represented by Formula 1 is represented by at least one among Compound Group 1:

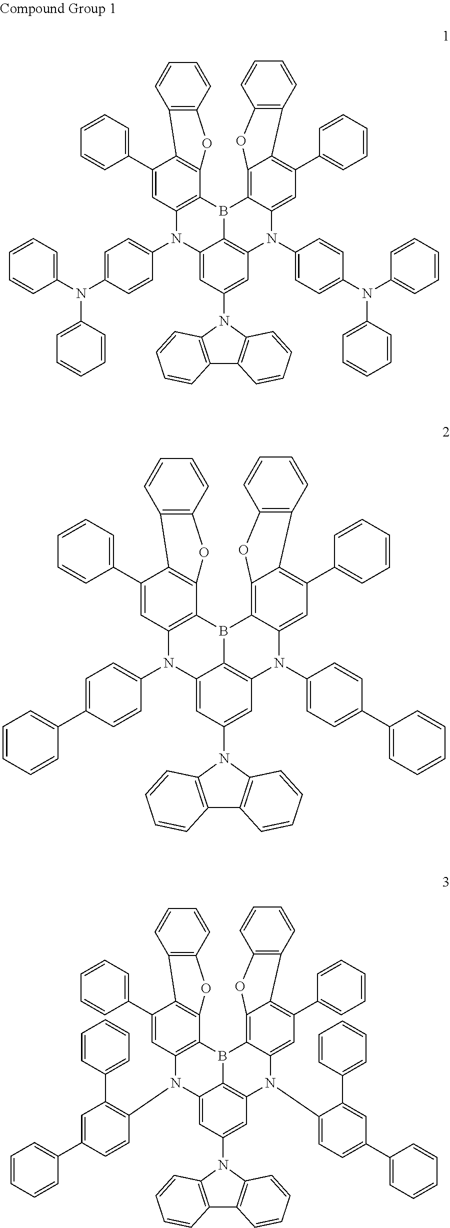 [SMILES: c1ccc(-c2cc3c(c4oc5ccccc5c24)B2c4c(cc(-n5c6ccccc6c6ccccc65)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1]

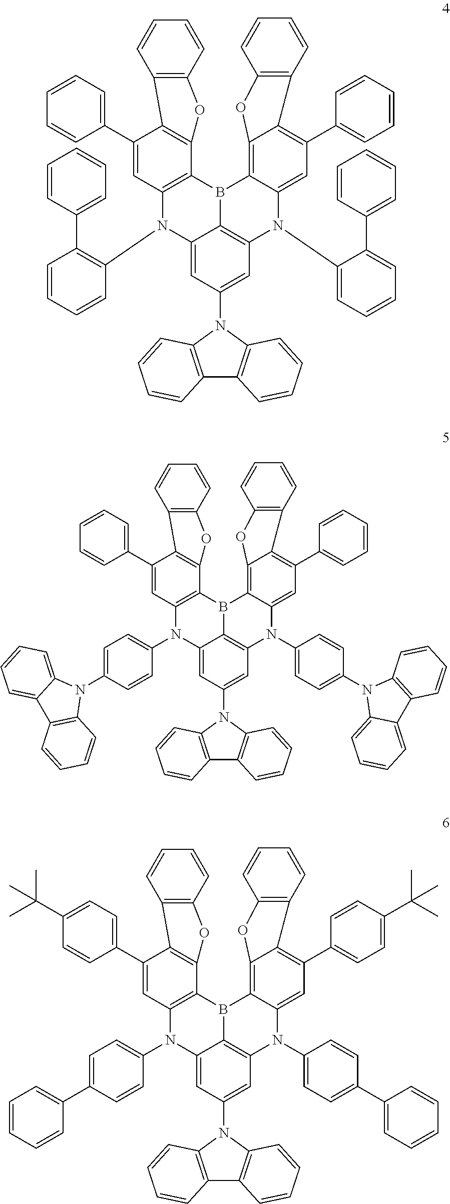 [SMILES: c1ccc(-c2ccccc2N2c3cc(-n4c5ccccc5c5ccccc54)cc4c3B(c3c2cc(-c2ccccc2)c2c3oc3ccccc32)c2c(cc(-c3ccccc3)c3c2oc2ccccc23)N4c2ccccc2-c2ccccc2)cc1 ; c1ccc(-c2cc3c(c4oc5ccccc5c24)B2c4c(cc(-n5c6ccccc6c6ccccc65)cc4N(c4ccc(-n5c6ccccc6c6ccccc65)cc4)c4cc(-c5ccccc5)c5c(oc6ccccc65)c42)N3c2ccc(-n3c4ccccc4c4ccccc43)cc2)cc1 ; CC(C)(C)c1ccc(-c2cc3c(c4oc5ccccc5c24)B2c4c(cc(-n5c6ccccc6c6ccccc65)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1]

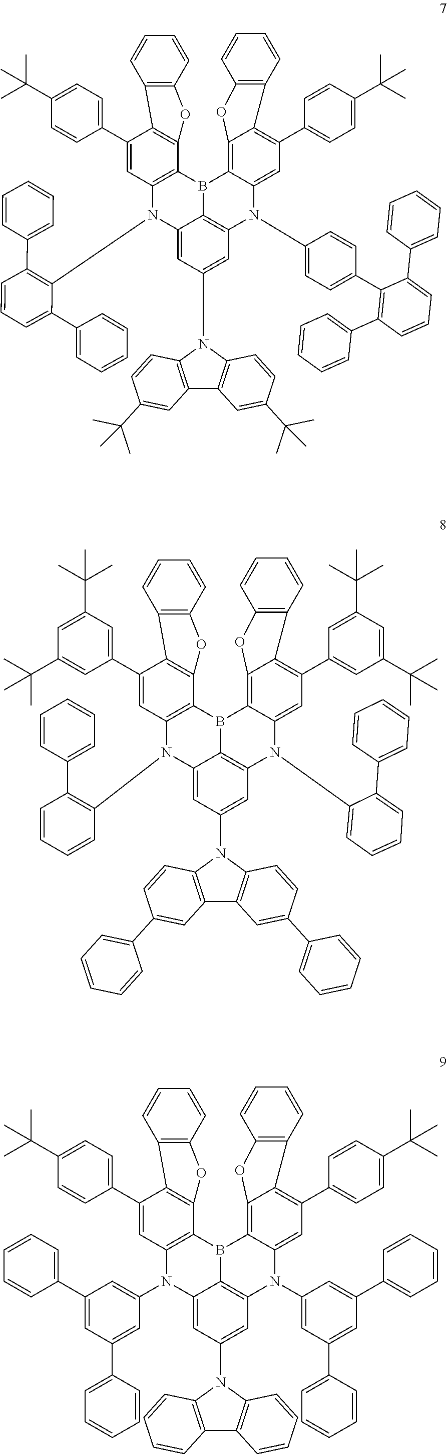

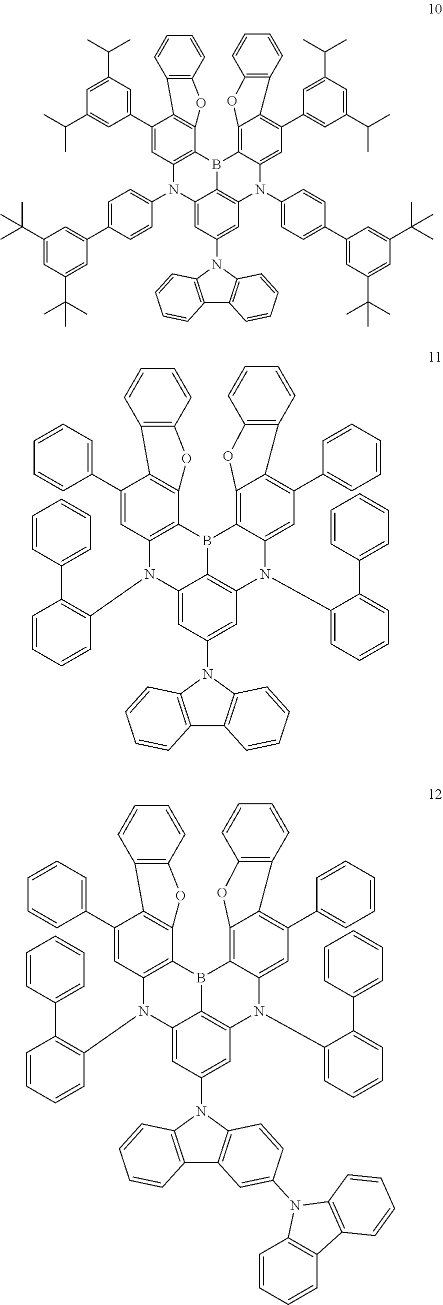

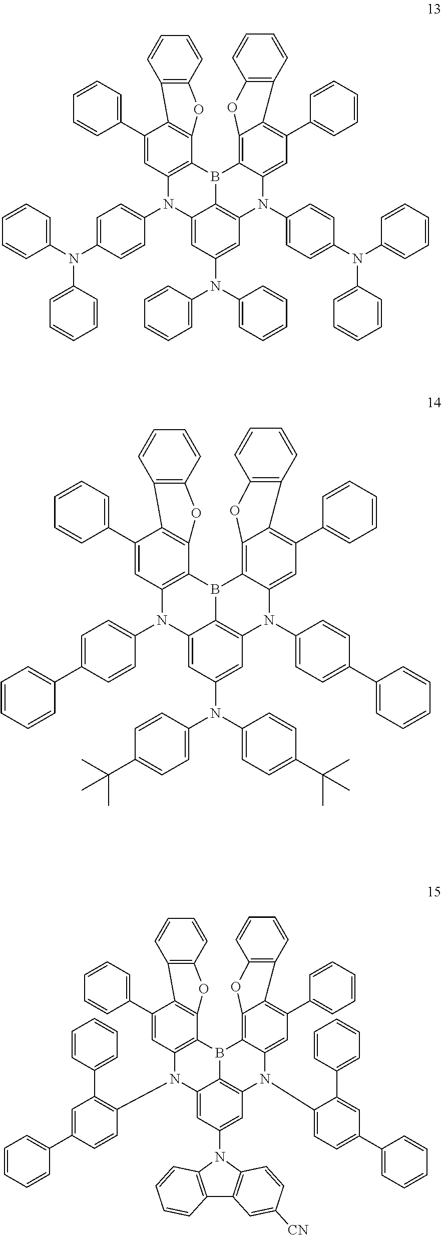 [SMILES: c1ccc(-c2cc3c(c4oc5ccccc5c24)B2c4c(cc(N(c5ccccc5)c5ccccc5)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; CC(C)(C)c1ccc(N(c2ccc(C(C)(C)C)cc2)c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc1 ; N#Cc1ccc2c(c1)c1ccccc1n2-c1cc2c3c(c1)N(c1ccc(-c4ccccc4)cc1-c1ccccc1)c1cc(-c4ccccc4)c4c(oc5ccccc54)c1B3c1c(cc(-c3ccccc3)c3c1oc1ccccc13)N2c1ccc(-c2ccccc2)cc1-c1ccccc1]

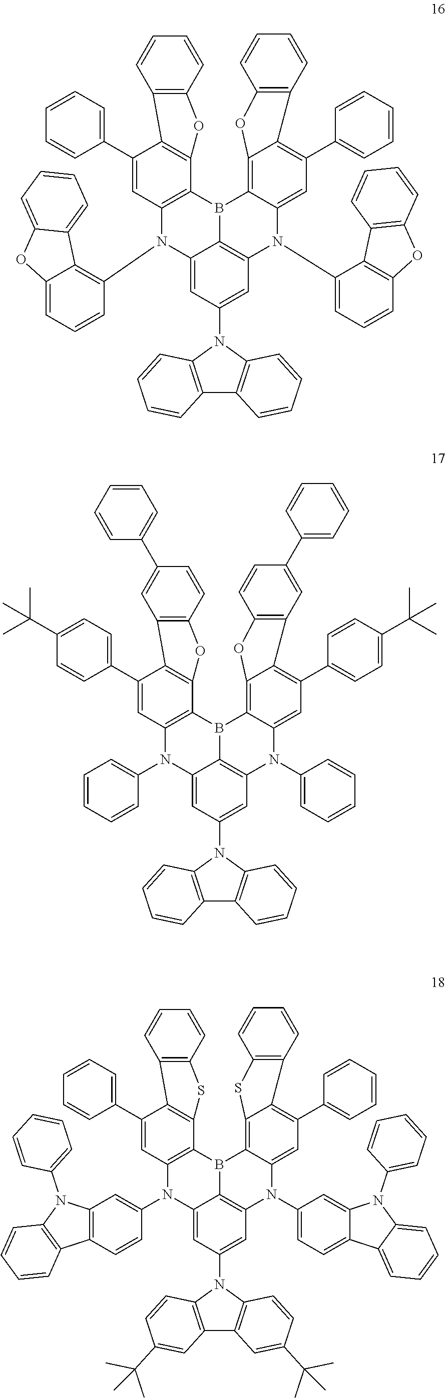 [SMILES: c1ccc(-c2cc3c(c4oc5ccccc5c24)B2c4c(cc(-n5c6ccccc6c6ccccc65)cc4N(c4cccc5oc6ccccc6c45)c4cc(-c5ccccc5)c5c(oc6ccccc65)c42)N3c2cccc3oc4ccccc4c23)cc1 ; CC(C)(C)c1ccc(-c2cc3c(c4oc5ccc(-c6ccccc6)cc5c24)B2c4c(cc(-n5c6ccccc6c6ccccc65)cc4N(c4ccccc4)c4cc(-c5ccc(C(C)(C)C)cc5)c5c(oc6ccc(-c7ccccc7)cc65)c42)N3c2ccccc2)cc1 ; CC(C)(C)c1ccc2c(c1)c1cc(C(C)(C)C)ccc1n2-c1cc2c3c(c1)N(c1ccc4c5ccccc5n(-c5ccccc5)c4c1)c1cc(-c4ccccc4)c4c(sc5ccccc54)c1B3c1c(cc(-c3ccccc3)c3c1sc1ccccc13)N2c1ccc2c3ccccc3n(-c3ccccc3)c2c1]

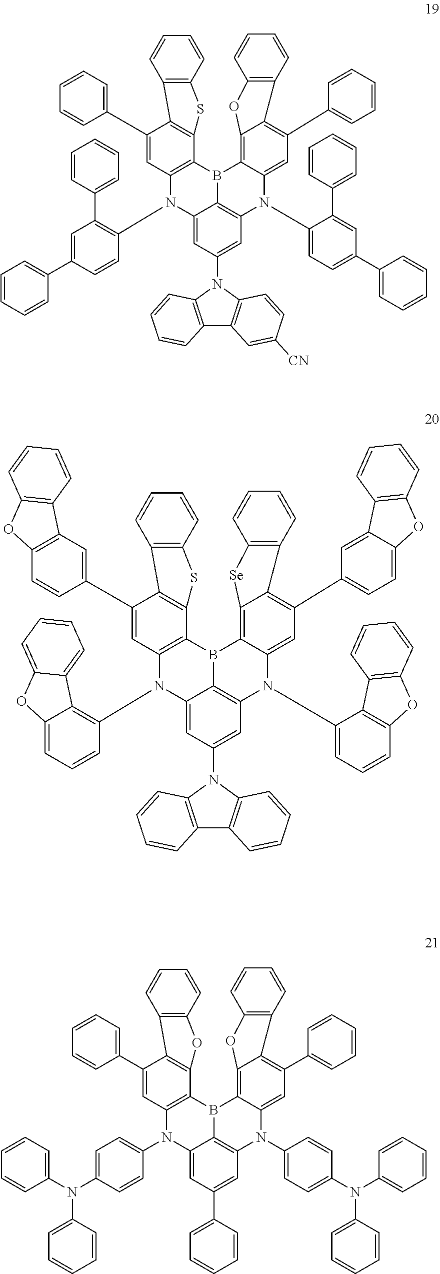 [SMILES: N#Cc1ccc2c(c1)c1ccccc1n2-c1cc2c3c(c1)N(c1ccc(-c4ccccc4)cc1-c1ccccc1)c1cc(-c4ccccc4)c4c(sc5ccccc54)c1B3c1c(cc(-c3ccccc3)c3c1oc1ccccc13)N2c1ccc(-c2ccccc2)cc1-c1ccccc1 ; c1ccc2c(c1)oc1ccc(-c3cc4c(c5sc6ccccc6c35)B3c5c(cc(-n6c7ccccc7c7ccccc76)cc5N(c5cccc6oc7ccccc7c56)c5cc(-c6ccc7oc8ccccc8c7c6)c6c([se]c7ccccc76)c53)N4c3cccc4oc5ccccc5c34)cc12 ; c1ccc(-c2cc3c4c(c2)N(c2ccc(N(c5ccccc5)c5ccccc5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)cc1]

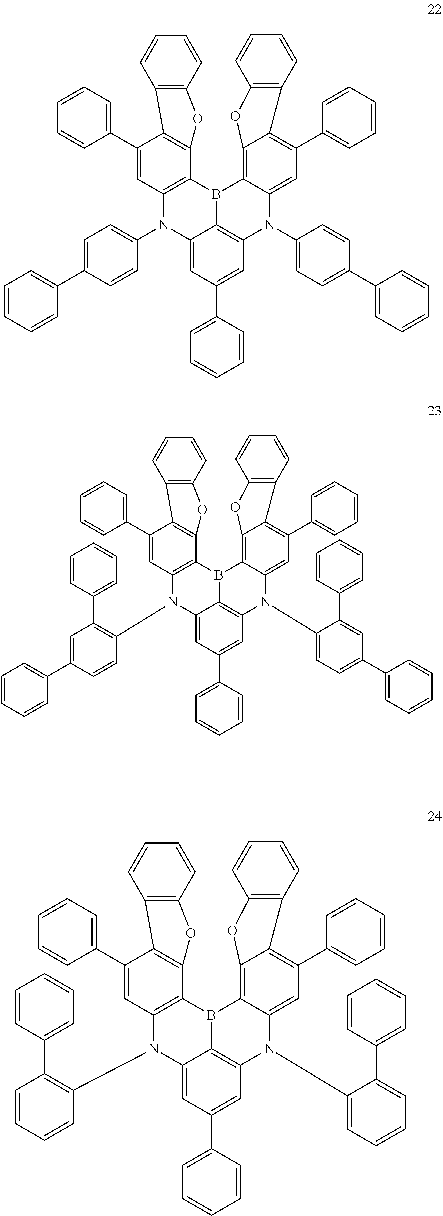 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1]

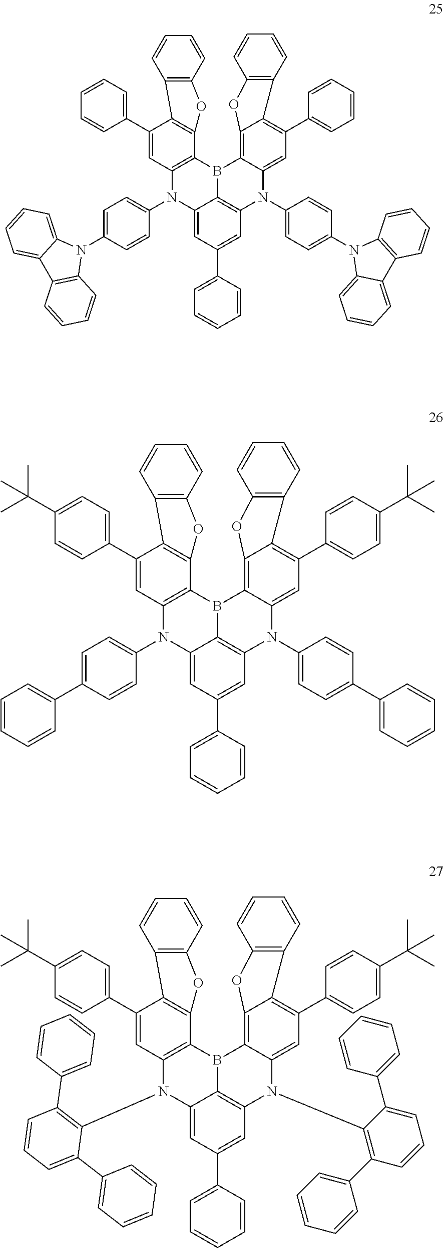 [SMILES: c1ccc(-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1 ; CC(C)(C)c1ccc(-c2cc3c(c4oc5ccccc5c24)B2c4c(cc(-c5ccccc5)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1 ; CC(C)(C)c1ccc(-c2cc3c(c4oc5ccccc5c24)B2c4c(cc(-c5ccccc5)cc4N(c4c(-c5ccccc5)cccc4-c4ccccc4)c4cc(-c5ccc(C(C)(C)C)cc5)c5c(oc6ccccc65)c42)N3c2c(-c3ccccc3)cccc2-c2ccccc2)cc1]

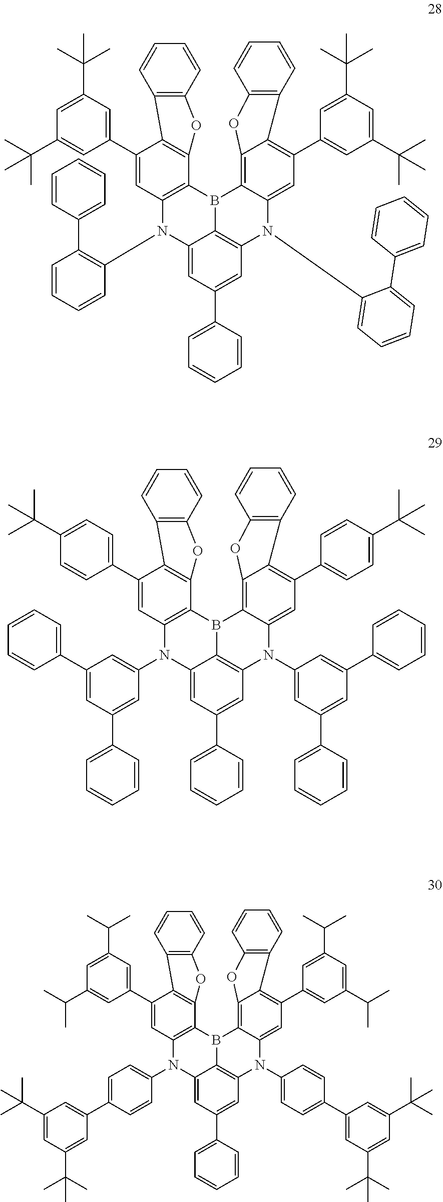

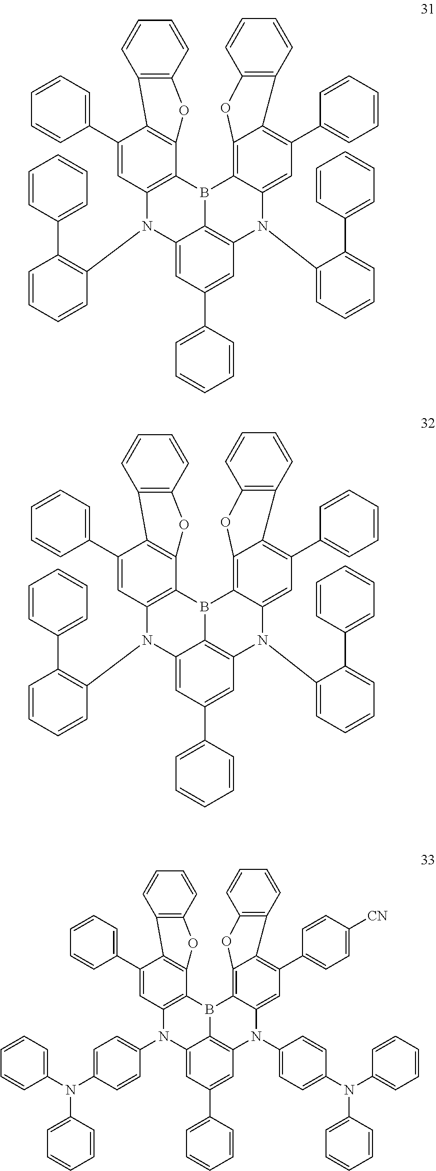 [SMILES: c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; N#Cc1ccc(-c2cc3c(c4oc5ccccc5c24)B2c4c(cc(-c5ccccc5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1]

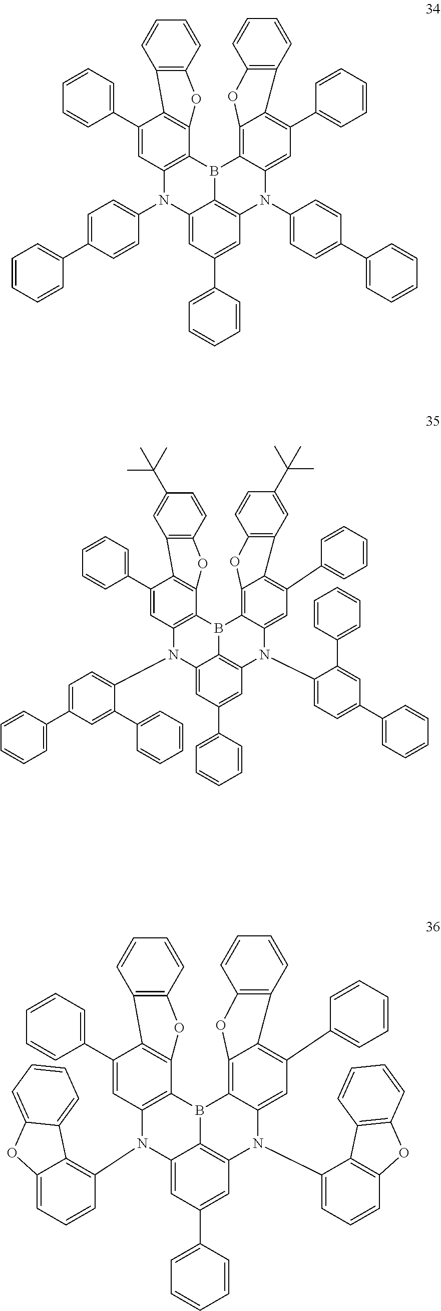 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; CC(C)(C)c1ccc2oc3c4c(cc(-c5ccccc5)c3c2c1)N(c1ccc(-c2ccccc2)cc1-c1ccccc1)c1cc(-c2ccccc2)cc2c1B4c1c(cc(-c3ccccc3)c3c1oc1ccc(C(C)(C)C)cc13)N2c1ccc(-c2ccccc2)cc1-c1ccccc1 ; c1ccc(-c2cc3c4c(c2)N(c2cccc5oc6ccccc6c25)c2cc(-c5ccccc5)c5c(oc6ccccc65)c2B4c2c(cc(-c4ccccc4)c4c2oc2ccccc24)N3c2cccc3oc4ccccc4c23)cc1]

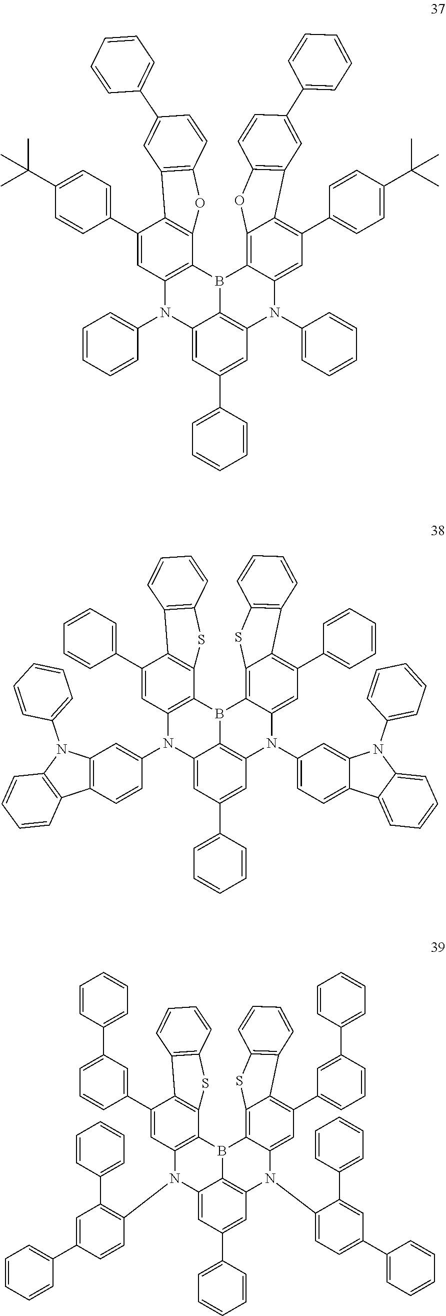 [SMILES: CC(C)(C)c1ccc(-c2cc3c(c4oc5ccc(-c6ccccc6)cc5c24)B2c4c(cc(-c5ccccc5)cc4N(c4ccccc4)c4cc(-c5ccc(C(C)(C)C)cc5)c5c(oc6ccc(-c7ccccc7)cc65)c42)N3c2ccccc2)cc1 ; c1ccc(-c2cc3c4c(c2)N(c2ccc5c6ccccc6n(-c6ccccc6)c5c2)c2cc(-c5ccccc5)c5c(sc6ccccc65)c2B4c2c(cc(-c4ccccc4)c4c2sc2ccccc24)N3c2ccc3c4ccccc4n(-c4ccccc4)c3c2)cc1 ; c1ccc(-c2cccc(-c3cc4c(c5sc6ccccc6c35)B3c5c(cc(-c6ccccc6)cc5N(c5ccc(-c6ccccc6)cc5-c5ccccc5)c5cc(-c6cccc(-c7ccccc7)c6)c6c(sc7ccccc76)c53)N4c3ccc(-c4ccccc4)cc3-c3ccccc3)c2)cc1]

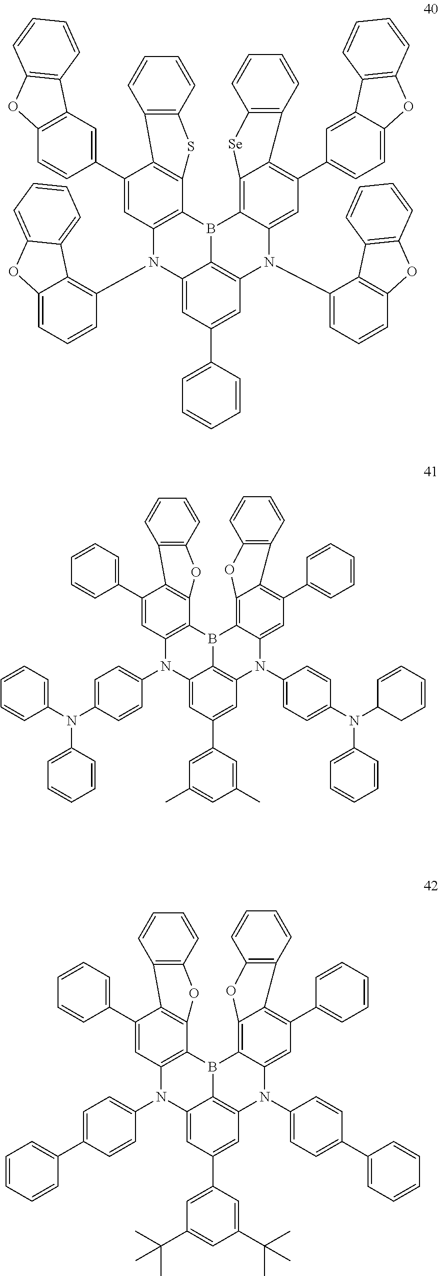 [SMILES: c1ccc(-c2cc3c4c(c2)N(c2cccc5oc6ccccc6c25)c2cc(-c5ccc6oc7ccccc7c6c5)c5c([se]c6ccccc65)c2B4c2c(cc(-c4ccc5oc6ccccc6c5c4)c4c2sc2ccccc24)N3c2cccc3oc4ccccc4c23)cc1 ; Cc1cc(C)cc(-c2cc3c4c(c2)N(c2ccc(N(c5ccccc5)C5C=CC=CC5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)c1 ; CC(C)(C)c1cc(-c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc(C(C)(C)C)c1]

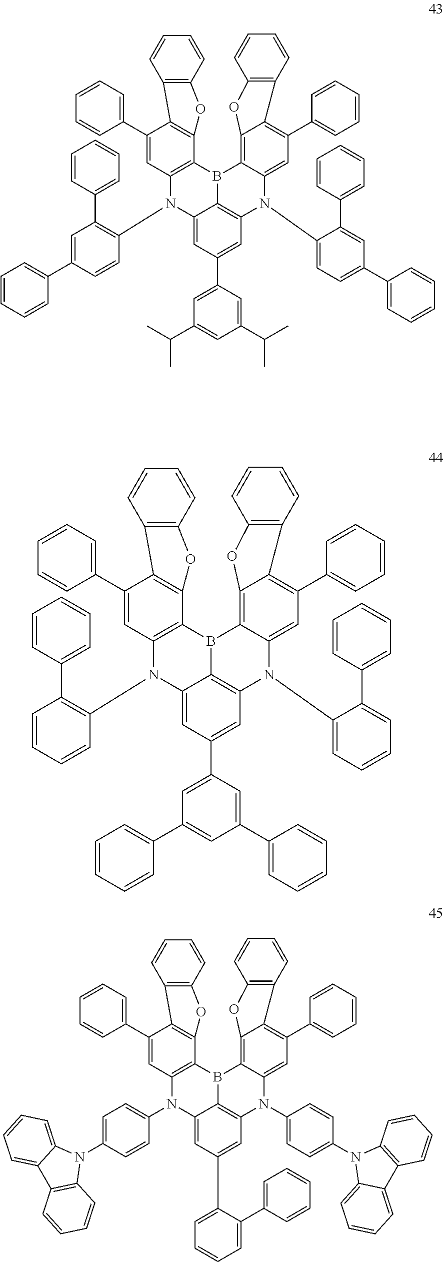 [SMILES: CC(C)c1cc(-c2cc3c4c(c2)N(c2ccc(-c5ccccc5)cc2-c2ccccc2)c2cc(-c5ccccc5)c5c(oc6ccccc65)c2B4c2c(cc(-c4ccccc4)c4c2oc2ccccc24)N3c2ccc(-c3ccccc3)cc2-c2ccccc2)cc(C(C)C)c1 ; c1ccc(-c2cc(-c3ccccc3)cc(-c3cc4c5c(c3)N(c3ccccc3-c3ccccc3)c3cc(-c6ccccc6)c6c(oc7ccccc76)c3B5c3c(cc(-c5ccccc5)c5c3oc3ccccc35)N4c3ccccc3-c3ccccc3)c2)cc1 ; c1ccc(-c2ccccc2-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1]

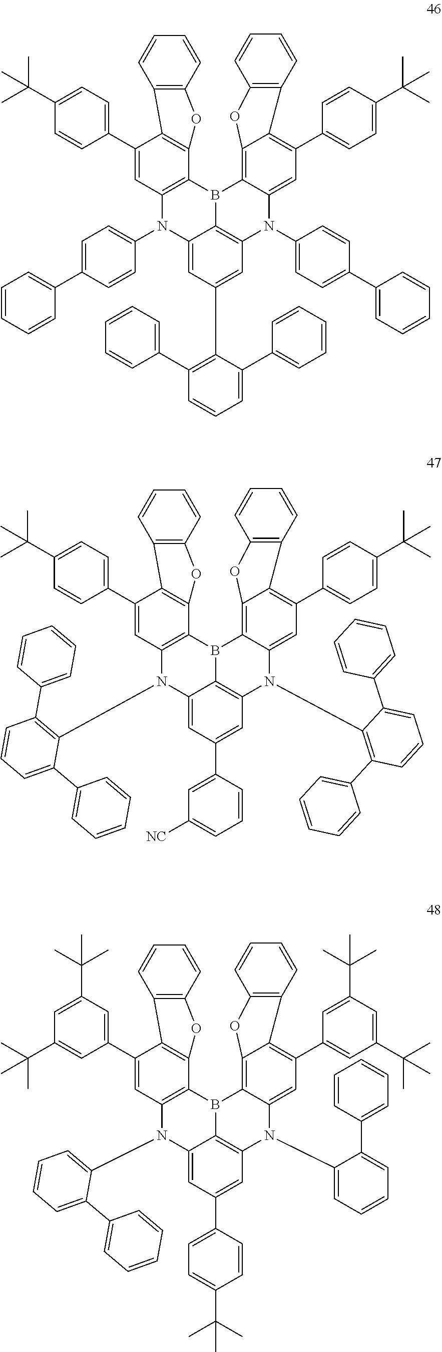

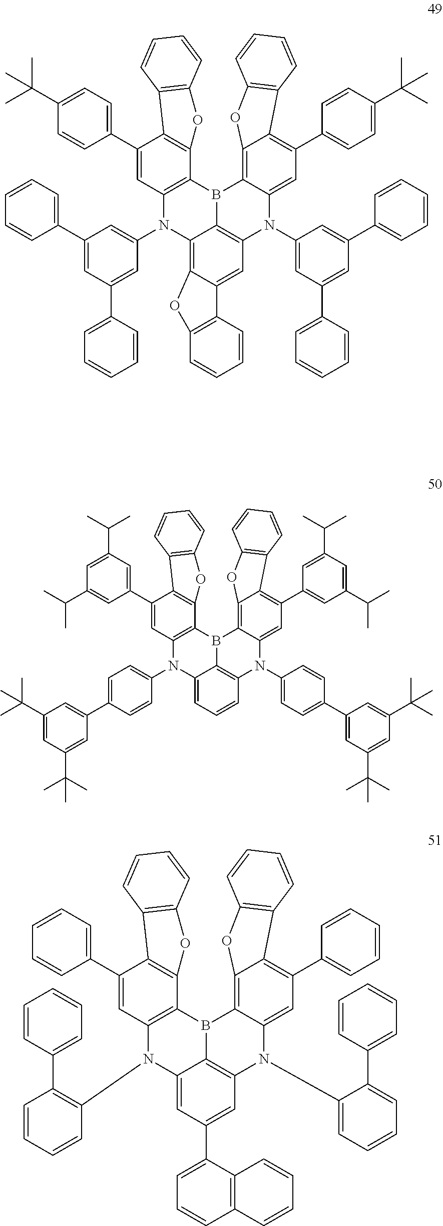 [SMILES: CC(C)(C)c1ccc(-c2cc3c(c4oc5ccccc5c24)B2c4c(cc5c(oc6ccccc65)c4N(c4cc(-c5ccccc5)cc(-c5ccccc5)c4)c4cc(-c5ccc(C(C)(C)C)cc5)c5c(oc6ccccc65)c42)N3c2cc(-c3ccccc3)cc(-c3ccccc3)c2)cc1 ; CC(C)c1cc(-c2cc3c(c4oc5ccccc5c24)B2c4c(cccc4N(c4ccc(-c5cc(C(C)(C)C)cc(C(C)(C)C)c5)cc4)c4cc(-c5cc(C(C)C)cc(C(C)C)c5)c5c(oc6ccccc65)c42)N3c2ccc(-c3cc(C(C)(C)C)cc(C(C)(C)C)c3)cc2)cc(C(C)C)c1 ; c1ccc(-c2ccccc2N2c3cc(-c4cccc5ccccc45)cc4c3B(c3c2cc(-c2ccccc2)c2c3oc3ccccc32)c2c(cc(-c3ccccc3)c3c2oc2ccccc23)N4c2ccccc2-c2ccccc2)cc1]

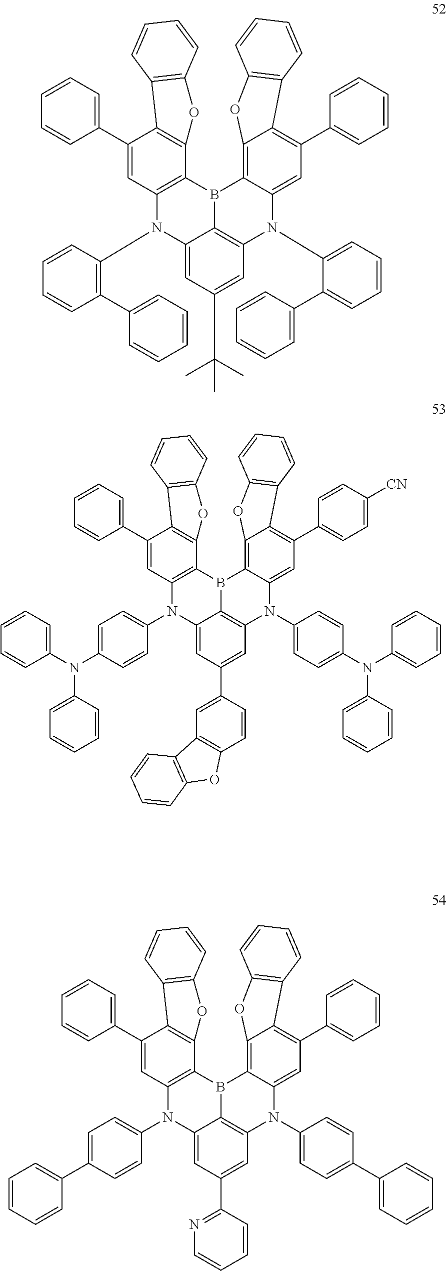 [SMILES: CC(C)(C)c1cc2c3c(c1)N(c1ccccc1-c1ccccc1)c1cc(-c4ccccc4)c4c(oc5ccccc54)c1B3c1c(cc(-c3ccccc3)c3c1oc1ccccc13)N2c1ccccc1-c1ccccc1 ; N#Cc1ccc(-c2cc3c(c4oc5ccccc5c24)B2c4c(cc(-c5ccc6oc7ccccc7c6c5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1 ; c1ccc(-c2ccc(N3c4cc(-c5ccccn5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1]

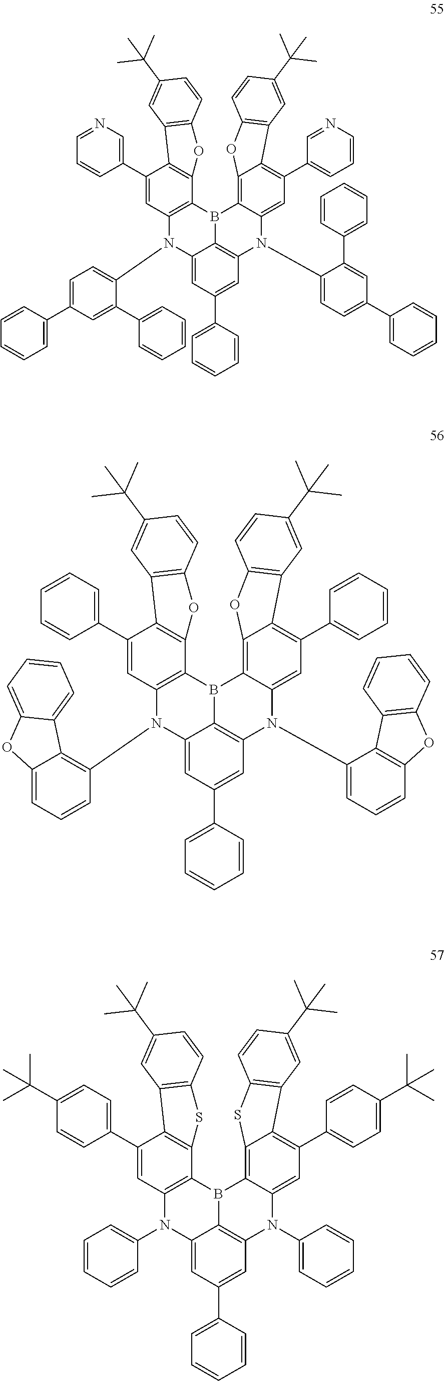 [SMILES: CC(C)(C)c1ccc2oc3c4c(cc(-c5cccnc5)c3c2c1)N(c1ccc(-c2ccccc2)cc1-c1ccccc1)c1cc(-c2ccccc2)cc2c1B4c1c(cc(-c3cccnc3)c3c1oc1ccc(C(C)(C)C)cc13)N2c1ccc(-c2ccccc2)cc1-c1ccccc1 ; CC(C)(C)c1ccc2oc3c4c(cc(-c5ccccc5)c3c2c1)N(c1cccc2oc3ccccc3c12)c1cc(-c2ccccc2)cc2c1B4c1c(cc(-c3ccccc3)c3c1oc1ccc(C(C)(C)C)cc13)N2c1cccc2oc3ccccc3c12 ; CC(C)(C)c1ccc(-c2cc3c(c4sc5ccc(C(C)(C)C)cc5c24)B2c4c(cc(-c5ccccc5)cc4N(c4ccccc4)c4cc(-c5ccc(C(C)(C)C)cc5)c5c(sc6ccc(C(C)(C)C)cc65)c42)N3c2ccccc2)cc1]

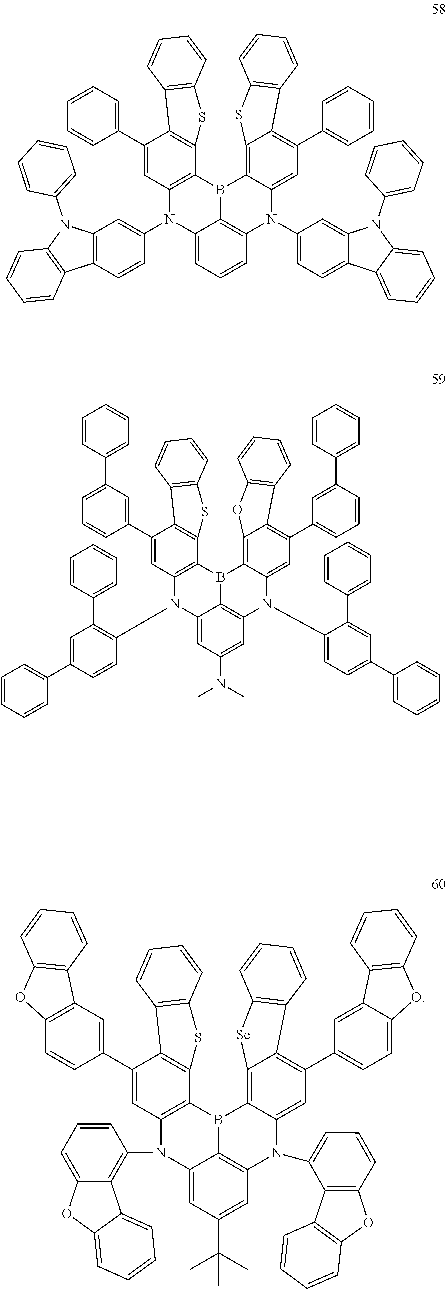 [SMILES: c1ccc(-c2cc3c(c4sc5ccccc5c24)B2c4c(cccc4N(c4ccc5c6ccccc6n(-c6ccccc6)c5c4)c4cc(-c5ccccc5)c5c(sc6ccccc65)c42)N3c2ccc3c4ccccc4n(-c4ccccc4)c3c2)cc1 ; CN(C)c1cc2c3c(c1)N(c1ccc(-c4ccccc4)cc1-c1ccccc1)c1cc(-c4cccc(-c5ccccc5)c4)c4c(sc5ccccc54)c1B3c1c(cc(-c3cccc(-c4ccccc4)c3)c3c1oc1ccccc13)N2c1ccc(-c2ccccc2)cc1-c1ccccc1 ; CC(C)(C)c1cc2c3c(c1)N(c1cccc4oc5ccccc5c14)c1cc(-c4ccc5oc6ccccc6c5c4)c4c([se]c5ccccc54)c1B3c1c(cc(-c3ccc4oc5ccccc5c4c3)c3c1sc1ccccc13)N2c1cccc2oc3ccccc3c12]

14. A fused polycyclic compound represented by Formula 1: 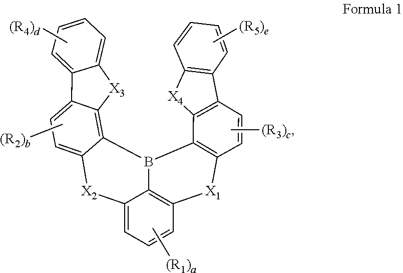
wherein in Formula 1,
X₁ to X₄ are each independently CRₐ₁Rₐ₂, NRₐ₃, O, S, or Se,
R₁ to R₅ and Rₐ₁ to Rₐ₃ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
“a” is an integer of 0 to 3,
“b” and “c” are each independently an integer of 0 to 2, and
“d” and “e” are each independently an integer of 0 to 4.

15. The fused polycyclic compound of claim 14, wherein:
“b” and “c” are integers of 1 or more, and
R₂ and R₃ are each independently a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

16. The fused polycyclic compound of claim 14, wherein the fused polycyclic compound represented by Formula 1 is represented by Formula 2: 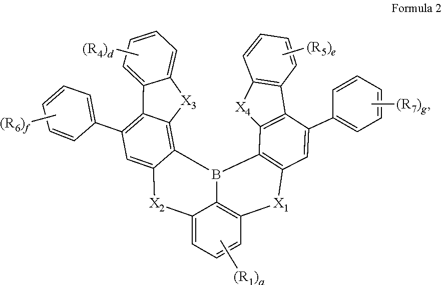
and
wherein in Formula 2,
R₆ and R₇ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
“f” and “g” are each independently an integer of 0 to 5, and
X₁ to X₄, R₁, R₄, R₅, “a”, “d”, and “e” are each independently the same as defined in Formula 1.

17. The fused polycyclic compound of claim 16, wherein the fused polycyclic compound represented by Formula 2 is represented by Formula 3: 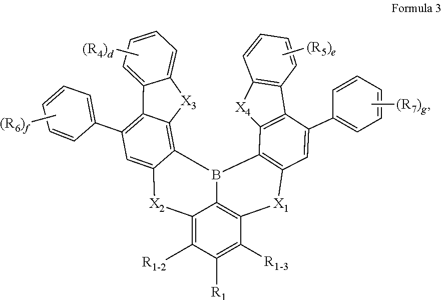
and
wherein in Formula 3,
R₁ is a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
R₁₋₂ and R₁₋₃ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, and
X₁ to X₄, R₄ to R₇, and “d” to “g” are each independently the same as defined in Formula 2.

18. The fused polycyclic compound of claim 17, wherein:
R₁₋₂ and R₁₋₃ are each independently a hydrogen atom, and
R₁ is a substituted or unsubstituted aryl group of 6 to 60 ring-forming carbon atoms, or a substituted or unsubstituted heteroaryl group of 2 to 60 ring-forming carbon atoms.

19. The fused polycyclic compound of claim 17, wherein the fused polycyclic compound represented by Formula 3 is represented by Formula 4: 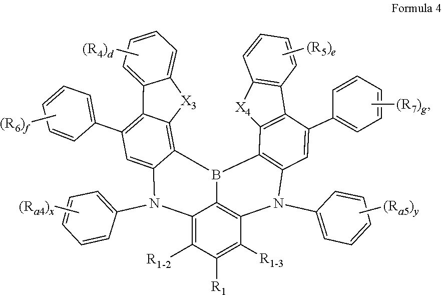
and
wherein in Formula 4,
Rₐ₄ and Rₐ₅ are each independently a hydrogen atom, a deuterium atom, a halogen atom, a cyano group, a nitro group, a substituted or unsubstituted oxy group, a substituted or unsubstituted silyl group, a substituted or unsubstituted amino group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring,
“x” and “y” are each independently an integer of 0 to 5, and
X₃, X₄, R₁, R₁₋₂, R₁₋₃, R₄ to R₇, and “d” to “g” are each independently the same as defined in Formula 3.

20. The fused polycyclic compound of claim 15, wherein the fused polycyclic compound represented by Formula 1 is represented by at least one among Compound Group 1: 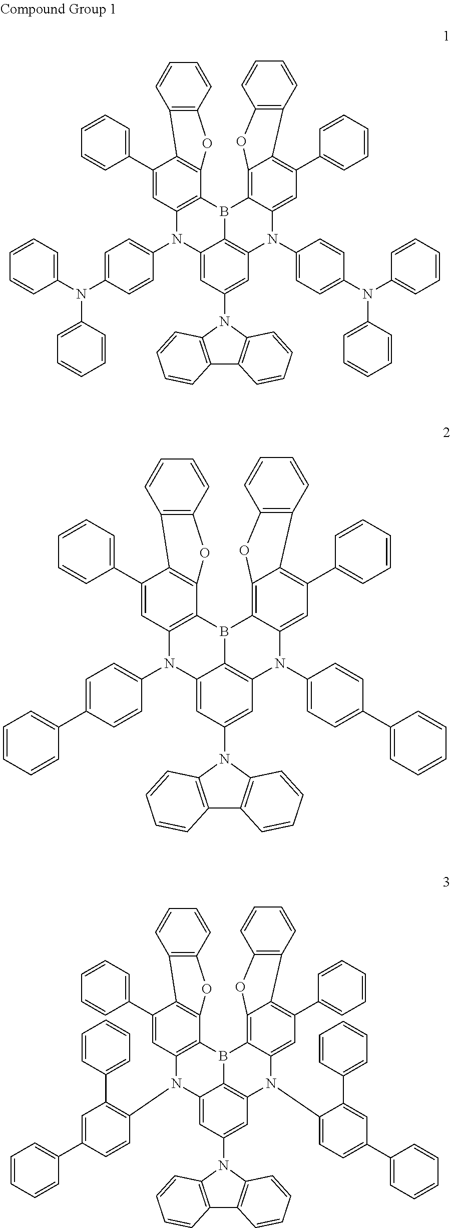 [SMILES: c1ccc(-c2cc3c(c4oc5ccccc5c24)B2c4c(cc(-n5c6ccccc6c6ccccc65)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-n5c6ccccc6c6ccccc65)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1] 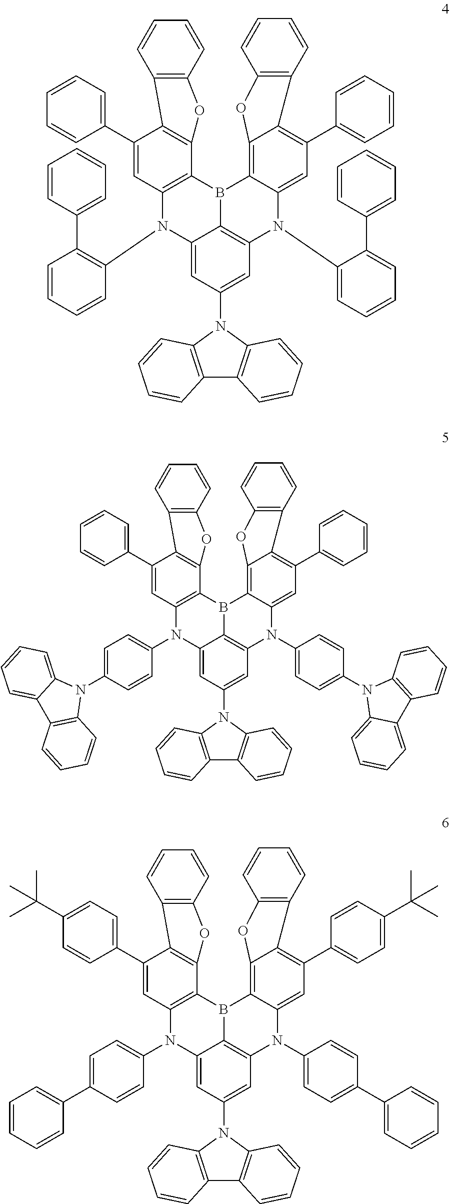 [SMILES: c1ccc(-c2ccccc2N2c3cc(-n4c5ccccc5c5ccccc54)cc4c3B(c3c2cc(-c2ccccc2)c2c3oc3ccccc32)c2c(cc(-c3ccccc3)c3c2oc2ccccc23)N4c2ccccc2-c2ccccc2)cc1 ; c1ccc(-c2cc3c(c4oc5ccccc5c24)B2c4c(cc(-n5c6ccccc6c6ccccc65)cc4N(c4ccc(-n5c6ccccc6c6ccccc65)cc4)c4cc(-c5ccccc5)c5c(oc6ccccc65)c42)N3c2ccc(-n3c4ccccc4c4ccccc43)cc2)cc1 ; CC(C)(C)c1ccc(-c2cc3c(c4oc5ccccc5c24)B2c4c(cc(-n5c6ccccc6c6ccccc65)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1] 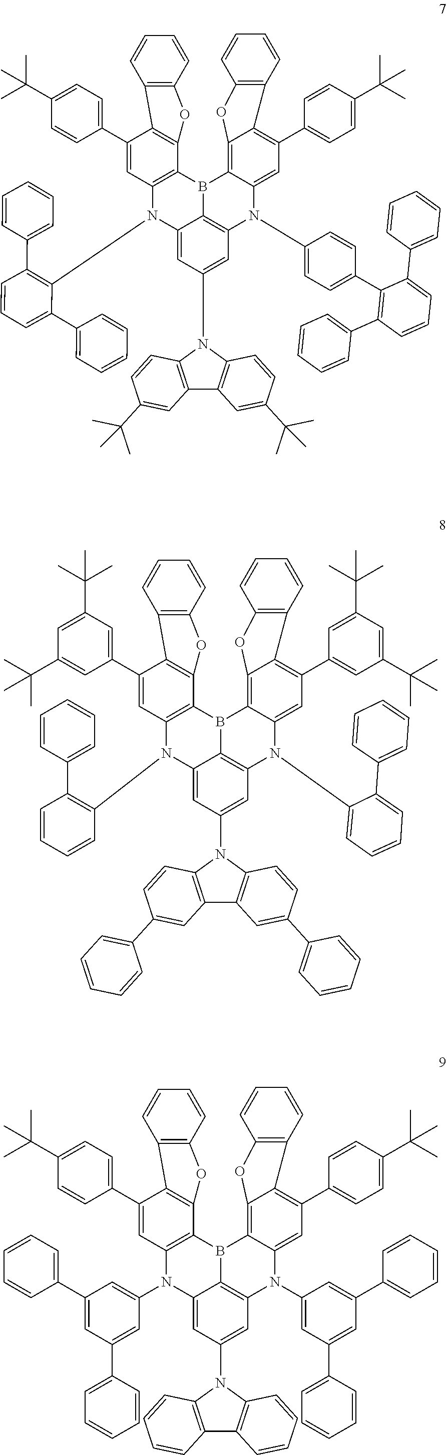 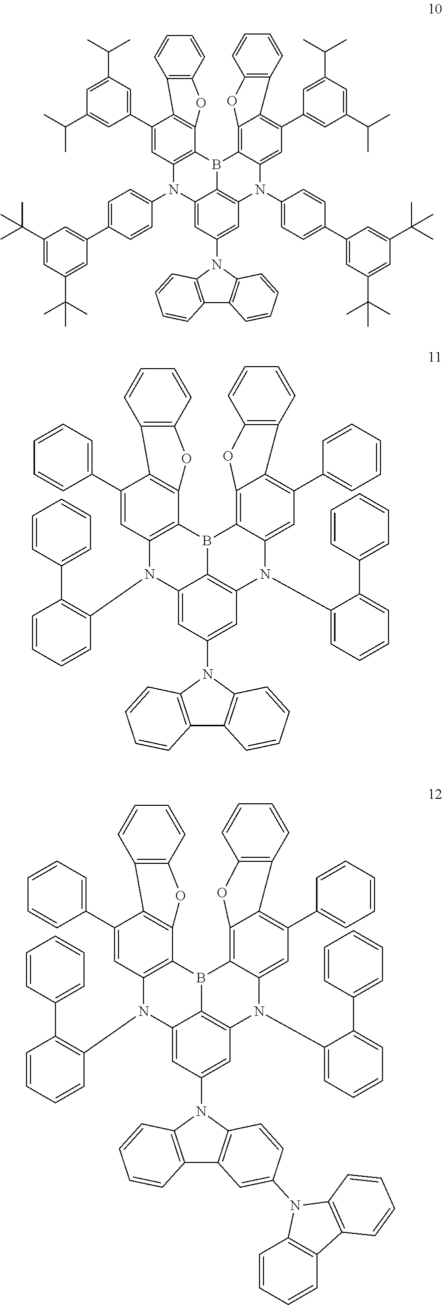 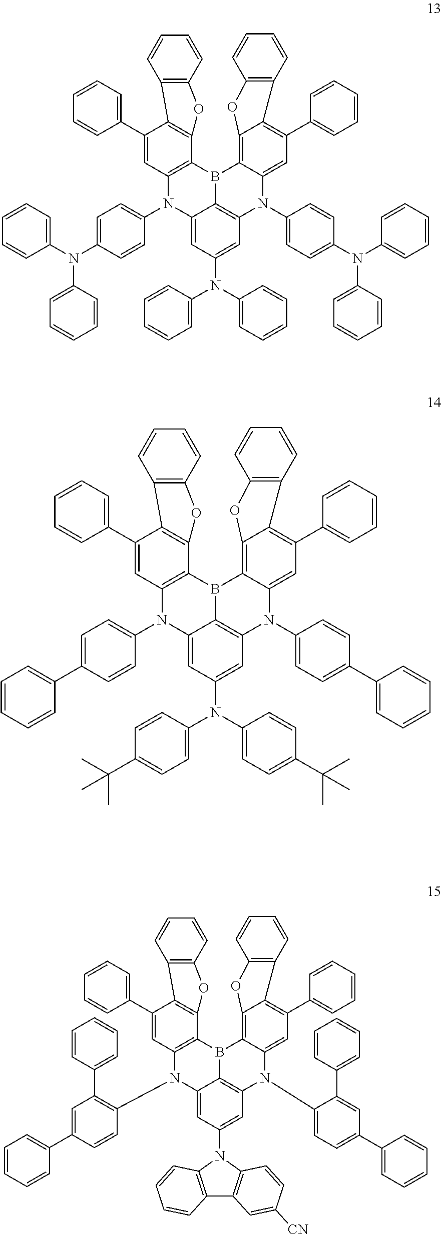 [SMILES: c1ccc(-c2cc3c(c4oc5ccccc5c24)B2c4c(cc(N(c5ccccc5)c5ccccc5)cc4N(c4ccc(N(c5ccccc5)c5ccccc5)cc4)c4cc(-c5ccccc5)c5c(oc6ccccc65)c42)N3c2ccc(N(c3ccccc3)c3ccccc3)cc2)cc1 ; CC(C)(C)c1ccc(N(c2ccc(C(C)(C)C)cc2)c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc1 ; N#Cc1ccc2c(c1)c1ccccc1n2-c1cc2c3c(c1)N(c1ccc(-c4ccccc4)cc1-c1ccccc1)c1cc(-c4ccccc4)c4c(oc5ccccc54)c1B3c1c(cc(-c3ccccc3)c3c1oc1ccccc13)N2c1ccc(-c2ccccc2)cc1-c1ccccc1] 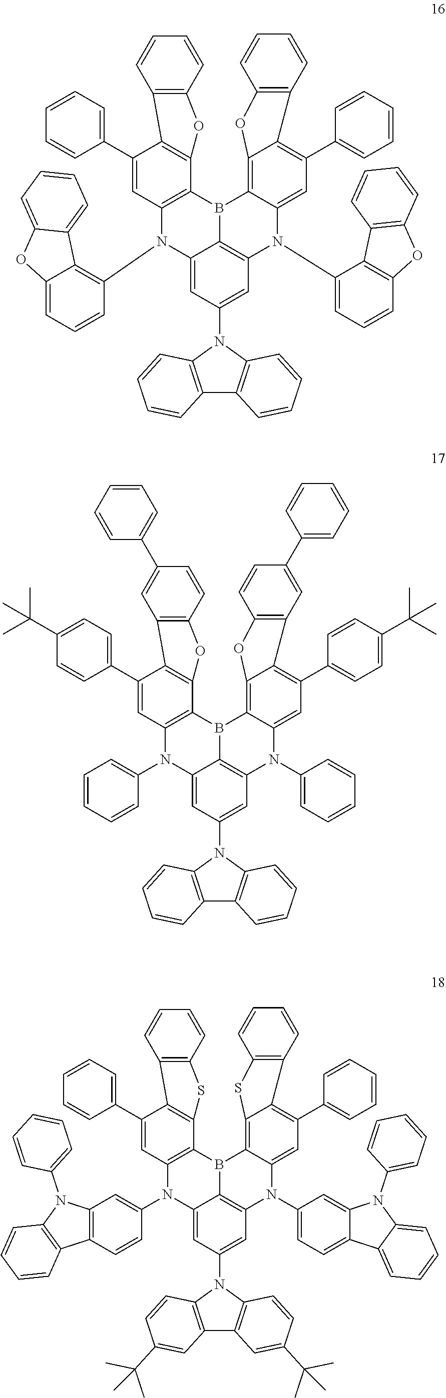 [SMILES: c1ccc(-c2cc3c(c4oc5ccccc5c24)B2c4c(cc(-n5c6ccccc6c6ccccc65)cc4N(c4cccc5oc6ccccc6c45)c4cc(-c5ccccc5)c5c(oc6ccccc65)c42)N3c2cccc3oc4ccccc4c23)cc1 ; CC(C)(C)c1ccc(-c2cc3c(c4oc5ccc(-c6ccccc6)cc5c24)B2c4c(cc(-n5c6ccccc6c6ccccc65)cc4N(c4ccccc4)c4cc(-c5ccc(C(C)(C)C)cc5)c5c(oc6ccc(-c7ccccc7)cc65)c42)N3c2ccccc2)cc1 ; CC(C)(C)c1ccc2c(c1)c1cc(C(C)(C)C)ccc1n2-c1cc2c3c(c1)N(c1ccc4c5ccccc5n(-c5ccccc5)c4c1)c1cc(-c4ccccc4)c4c(sc5ccccc54)c1B3c1c(cc(-c3ccccc3)c3c1sc1ccccc13)N2c1ccc2c3ccccc3n(-c3ccccc3)c2c1] 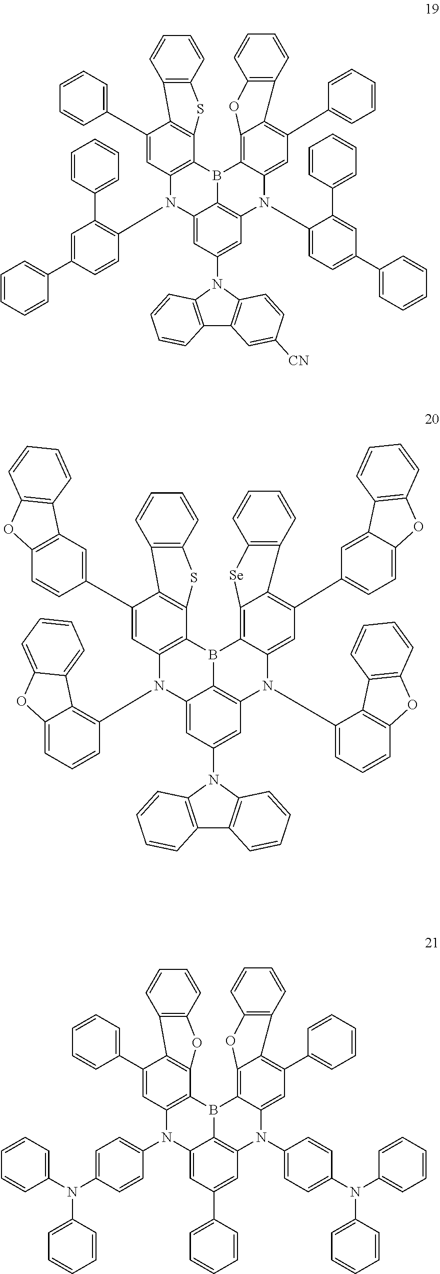 [SMILES: N#Cc1ccc2c(c1)c1ccccc1n2-c1cc2c3c(c1)N(c1ccc(-c4ccccc4)cc1-c1ccccc1)c1cc(-c4ccccc4)c4c(sc5ccccc54)c1B3c1c(cc(-c3ccccc3)c3c1oc1ccccc13)N2c1ccc(-c2ccccc2)cc1-c1ccccc1 ; c1ccc2c(c1)oc1ccc(-c3cc4c(c5sc6ccccc6c35)B3c5c(cc(-n6c7ccccc7c7ccccc76)cc5N(c5cccc6oc7ccccc7c56)c5cc(-c6ccc7oc8ccccc8c7c6)c6c([se]c7ccccc76)c53)N4c3cccc4oc5ccccc5c34)cc12 ; c1ccc(-c2cc3c4c(c2)N(c2ccc(N(c5ccccc5)c5ccccc5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)cc1] 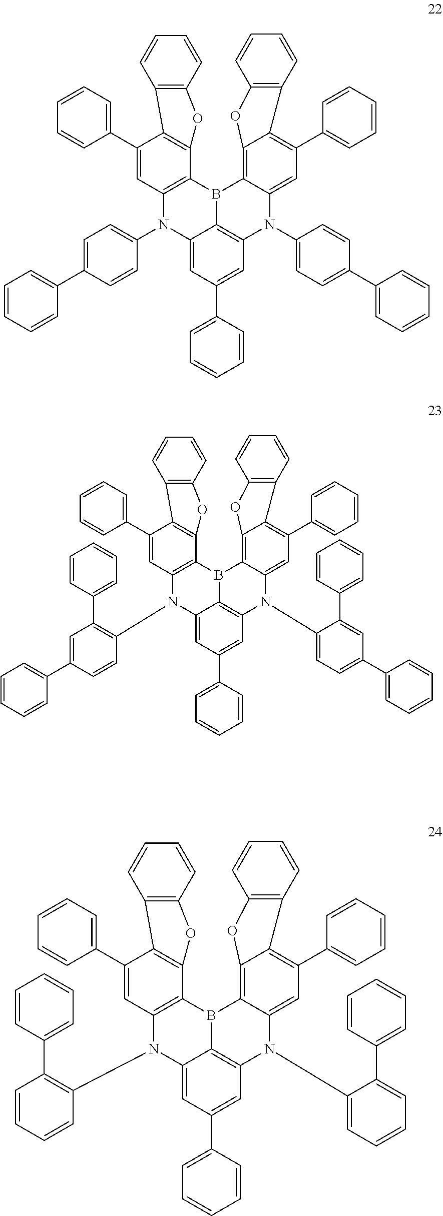 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3-c3ccccc3)c(-c3ccccc3)c2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1] 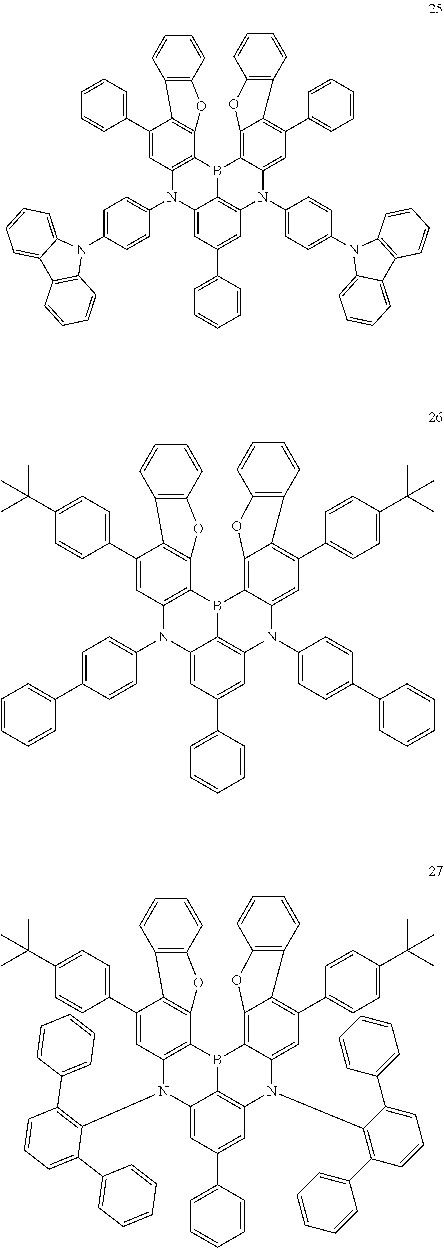 [SMILES: c1ccc(-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1 ; CC(C)(C)c1ccc(-c2cc3c(c4oc5ccccc5c24)B2c4c(cc(-c5ccccc5)cc4N(c4ccc(-c5ccccc5)cc4)c4cc(-c5ccc(C(C)(C)C)cc5)c5c(oc6ccccc65)c42)N3c2ccc(-c3ccccc3)cc2)cc1 ; CC(C)(C)c1ccc(-c2cc3c(c4oc5ccccc5c24)B2c4c(cc(-c5ccccc5)cc4N(c4c(-c5ccccc5)cccc4-c4ccccc4)c4cc(-c5ccc(C(C)(C)C)cc5)c5c(oc6ccccc65)c42)N3c2c(-c3ccccc3)cccc2-c2ccccc2)cc1] 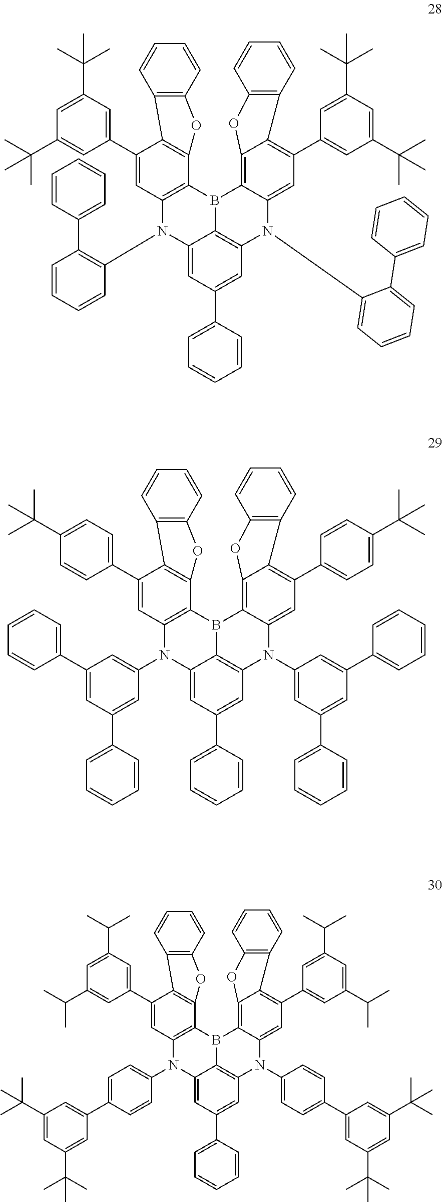 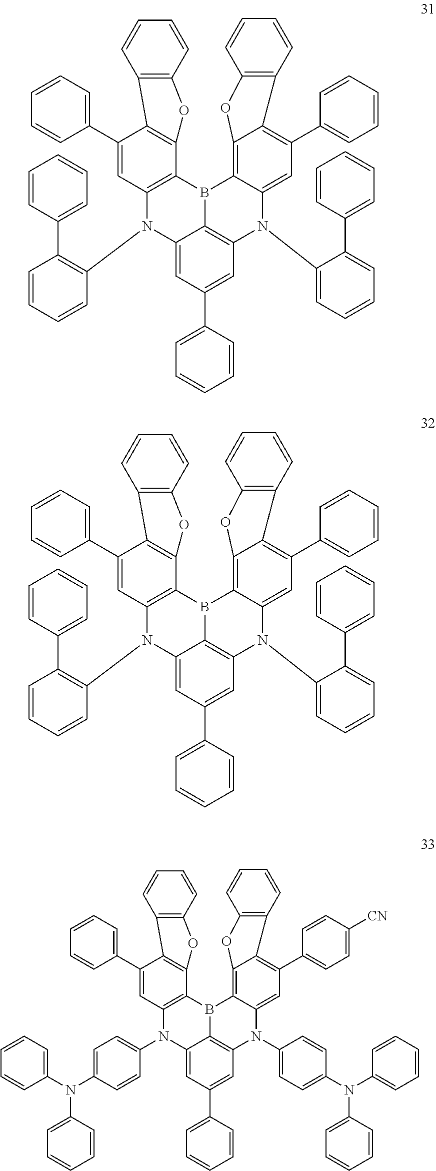 [SMILES: c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; c1ccc(-c2cc3c4c(c2)N(c2ccccc2-c2ccccc2)c2cc(-c5ccccc5)c5c(oc6ccccc65)c2B4c2c(cc(-c4ccccc4)c4c2oc2ccccc24)N3c2ccccc2-c2ccccc2)cc1 ; N#Cc1ccc(-c2cc3c(c4oc5ccccc5c24)B2c4c(cc(-c5ccccc5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1] 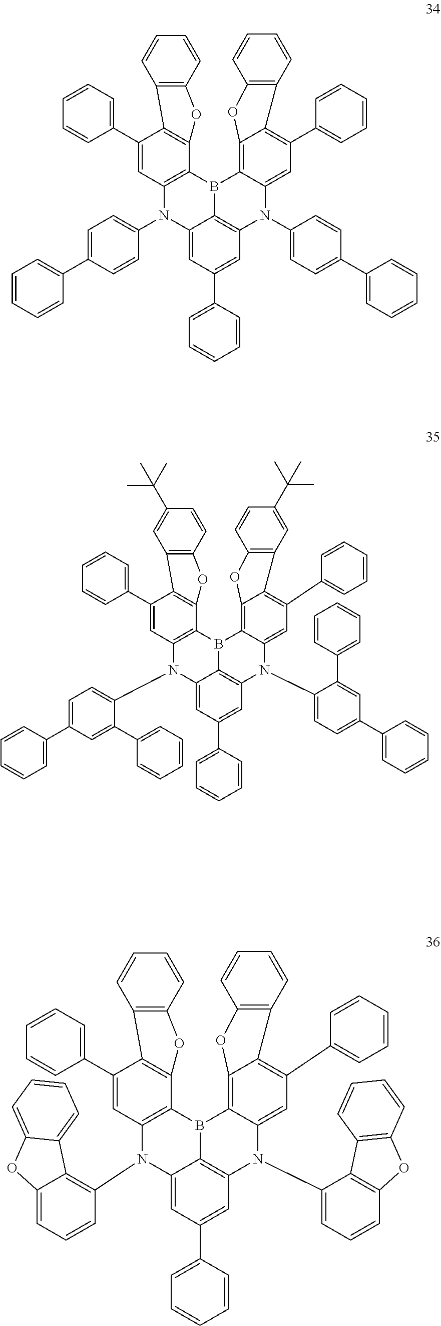 [SMILES: c1ccc(-c2ccc(N3c4cc(-c5ccccc5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1 ; CC(C)(C)c1ccc2oc3c4c(cc(-c5ccccc5)c3c2c1)N(c1ccc(-c2ccccc2)cc1-c1ccccc1)c1cc(-c2ccccc2)cc2c1B4c1c(cc(-c3ccccc3)c3c1oc1ccc(C(C)(C)C)cc13)N2c1ccc(-c2ccccc2)cc1-c1ccccc1 ; c1ccc(-c2cc3c4c(c2)N(c2cccc5oc6ccccc6c25)c2cc(-c5ccccc5)c5c(oc6ccccc65)c2B4c2c(cc(-c4ccccc4)c4c2oc2ccccc24)N3c2cccc3oc4ccccc4c23)cc1] 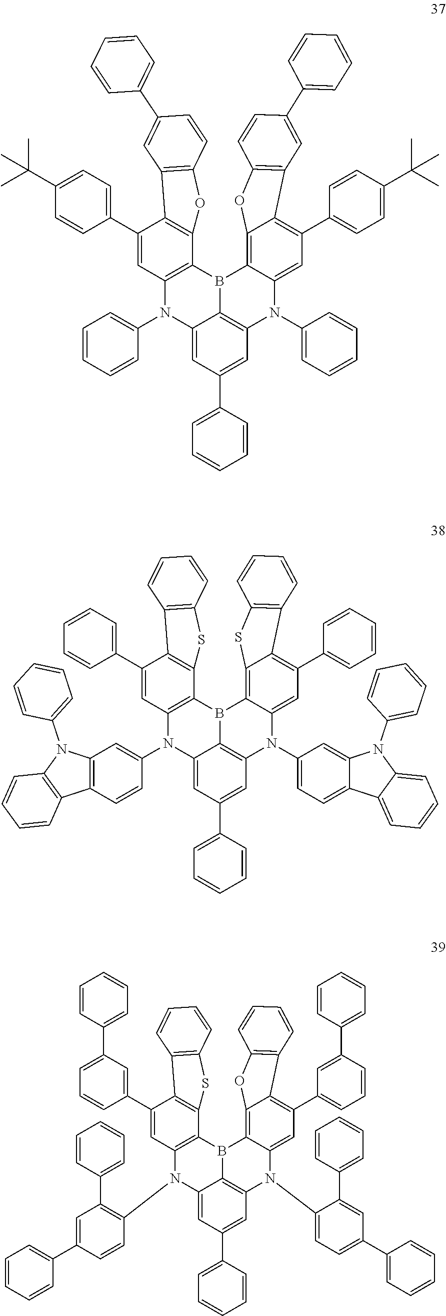 [SMILES: CC(C)(C)c1ccc(-c2cc3c(c4oc5ccc(-c6ccccc6)cc5c24)B2c4c(cc(-c5ccccc5)cc4N(c4ccccc4)c4cc(-c5ccc(C(C)(C)C)cc5)c5c(oc6ccc(-c7ccccc7)cc65)c42)N3c2ccccc2)cc1 ; c1ccc(-c2cc3c4c(c2)N(c2ccc5c6ccccc6n(-c6ccccc6)c5c2)c2cc(-c5ccccc5)c5c(sc6ccccc65)c2B4c2c(cc(-c4ccccc4)c4c2sc2ccccc24)N3c2ccc3c4ccccc4n(-c4ccccc4)c3c2)cc1 ; c1ccc(-c2cccc(-c3cc4c(c5oc6ccccc6c35)B3c5c(cc(-c6ccccc6)cc5N(c5ccc(-c6ccccc6)cc5-c5ccccc5)c5cc(-c6cccc(-c7ccccc7)c6)c6c(sc7ccccc76)c53)N4c3ccc(-c4ccccc4)cc3-c3ccccc3)c2)cc1] 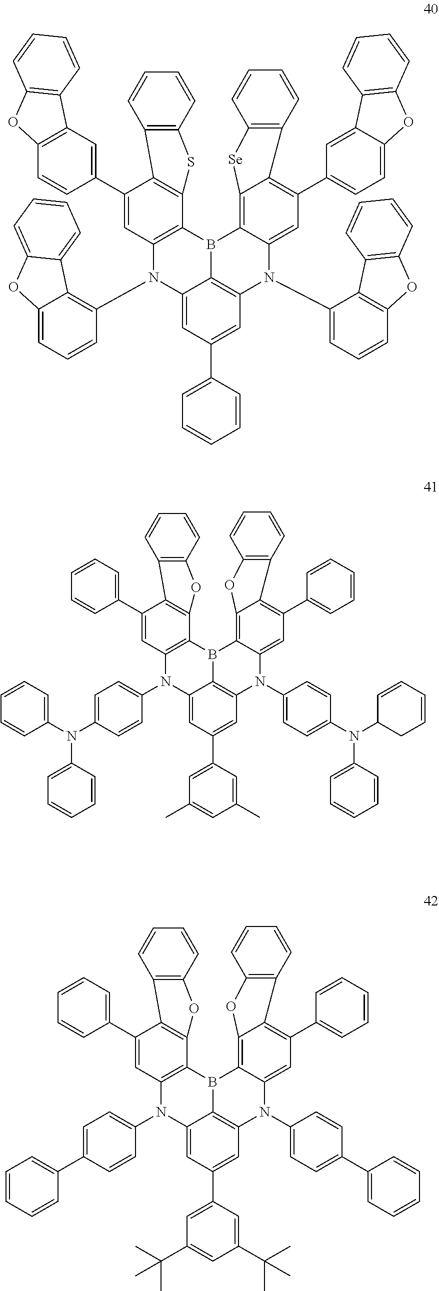 [SMILES: c1ccc(-c2cc3c4c(c2)N(c2cccc5oc6ccccc6c25)c2cc(-c5ccc6oc7ccccc7c6c5)c5c([se]c6ccccc65)c2B4c2c(cc(-c4ccc5oc6ccccc6c5c4)c4c2sc2ccccc24)N3c2cccc3oc4ccccc4c23)cc1 ; Cc1cc(C)cc(-c2cc3c4c(c2)N(c2ccc(N(c5ccccc5)C5C=CC=CC5)cc2)c2cc(-c5ccccc5)c5c(oc6ccccc65)c2B4c2c(cc(-c4ccccc4)c4c2oc2ccccc24)N3c2ccc(N(c3ccccc3)c3ccccc3)cc2)c1 ; CC(C)(C)c1cc(-c2cc3c4c(c2)N(c2ccc(-c5ccccc5)cc2)c2cc(-c5ccccc5)c5c(oc6ccccc65)c2B4c2c(cc(-c4ccccc4)c4c2oc2ccccc24)N3c2ccc(-c3ccccc3)cc2)cc(C(C)(C)C)c1] 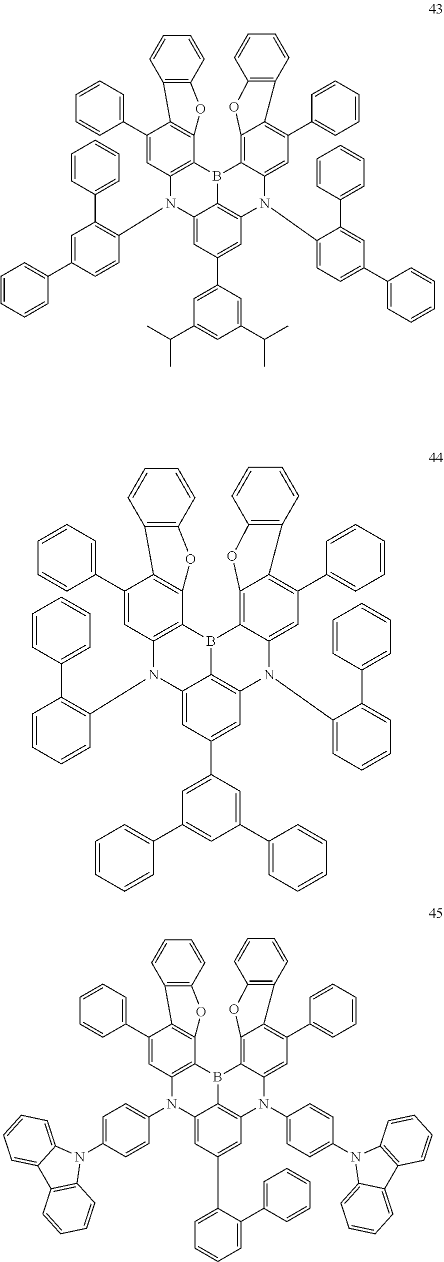 [SMILES: CC(C)c1cc(-c2cc3c4c(c2)N(c2ccc(-c5ccccc5)cc2-c2ccccc2)c2cc(-c5ccccc5)c5c(oc6ccccc65)c2B4c2c(cc(-c4ccccc4)c4c2oc2ccccc24)N3c2ccc(-c3ccccc3)cc2-c2ccccc2)cc(C(C)C)c1 ; c1ccc(-c2cc(-c3ccccc3)cc(-c3cc4c5c(c3)N(c3ccccc3-c3ccccc3)c3cc(-c6ccccc6)c6c(oc7ccccc76)c3B5c3c(cc(-c5ccccc5)c5c3oc3ccccc35)N4c3ccccc3-c3ccccc3)c2)cc1 ; c1ccc(-c2ccccc2-c2cc3c4c(c2)N(c2ccc(-n5c6ccccc6c6ccccc65)cc2)c2cc(-c5ccccc5)c5c(oc6ccccc65)c2B4c2c(cc(-c4ccccc4)c4c2oc2ccccc24)N3c2ccc(-n3c4ccccc4c4ccccc43)cc2)cc1] 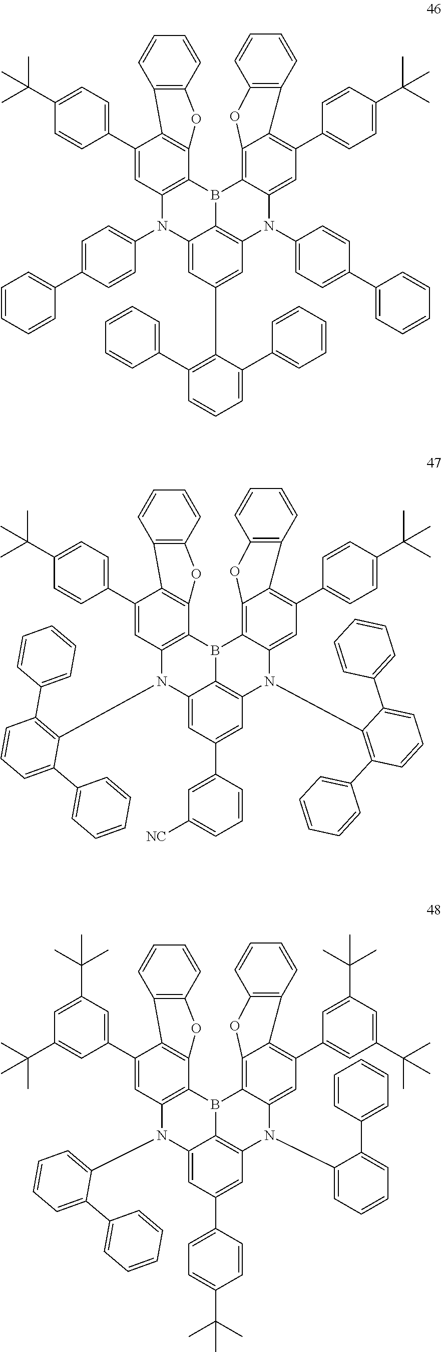 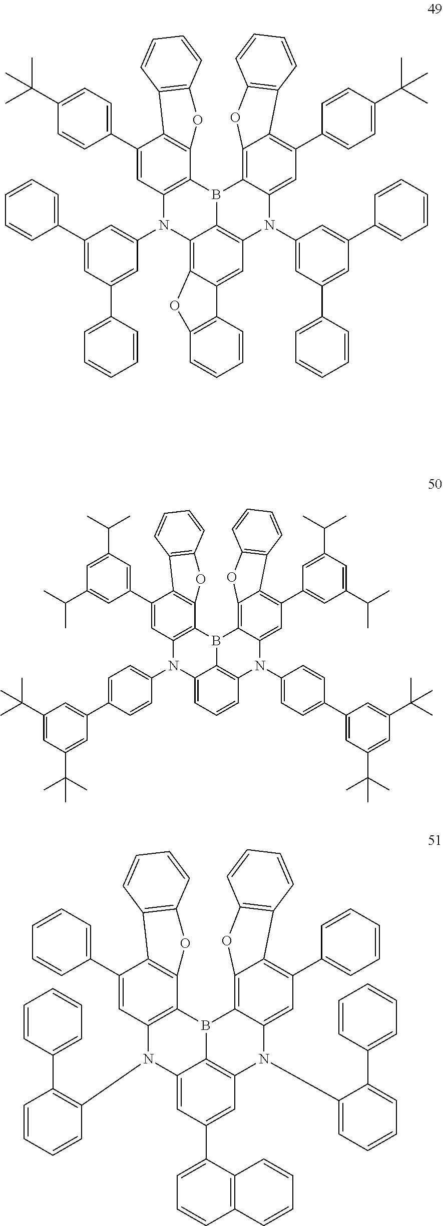 [SMILES: CC(C)(C)c1ccc(-c2cc3c(c4oc5ccccc5c24)B2c4c(cc5c(oc6ccccc65)c4N(c4cc(-c5ccccc5)cc(-c5ccccc5)c4)c4cc(-c5ccc(C(C)(C)C)cc5)c5c(oc6ccccc65)c42)N3c2cc(-c3ccccc3)cc(-c3ccccc3)c2)cc1 ; CC(C)c1cc(-c2cc3c(c4oc5ccccc5c24)B2c4c(cccc4N(c4ccc(-c5cc(C(C)(C)C)cc(C(C)(C)C)c5)cc4)c4cc(-c5cc(C(C)C)cc(C(C)C)c5)c5c(oc6ccccc65)c42)N3c2ccc(-c3cc(C(C)(C)C)cc(C(C)(C)C)c3)cc2)cc(C(C)C)c1 ; c1ccc(-c2ccccc2N2c3cc(-c4cccc5ccccc45)cc4c3B(c3c2cc(-c2ccccc2)c2c3oc3ccccc32)c2c(cc(-c3ccccc3)c3c2oc2ccccc23)N4c2ccccc2-c2ccccc2)cc1] 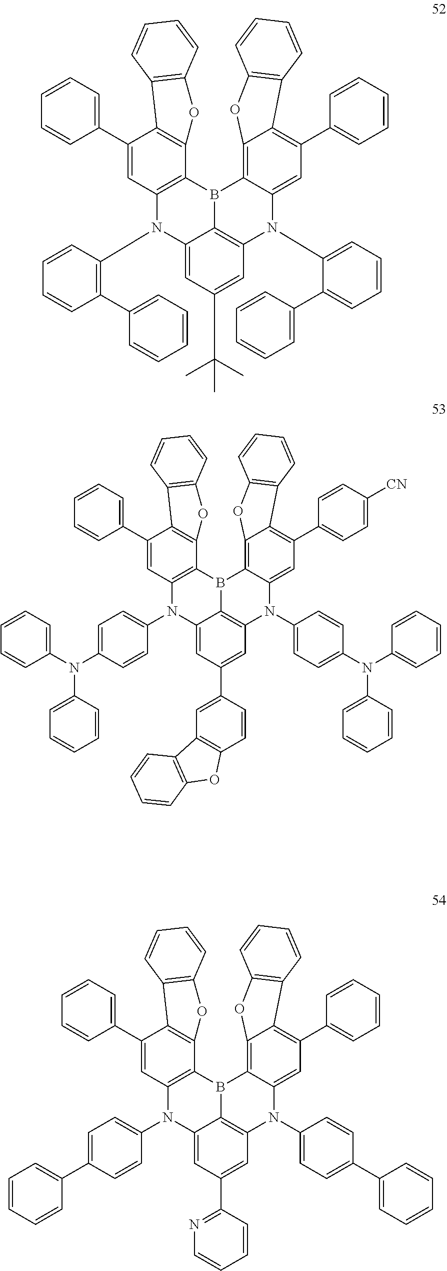 [SMILES: CC(C)(C)c1cc2c3c(c1)N(c1ccccc1-c1ccccc1)c1cc(-c4ccccc4)c4c(oc5ccccc54)c1B3c1c(cc(-c3ccccc3)c3c1oc1ccccc13)N2c1ccccc1-c1ccccc1 ; N#Cc1ccc(-c2cc3c(c4oc5ccccc5c24)B2c4c(cc(-c5ccc6oc7ccccc7c6c5)cc4N3c3ccc(N(c4ccccc4)c4ccccc4)cc3)N(c3ccc(N(c4ccccc4)c4ccccc4)cc3)c3cc(-c4ccccc4)c4c(oc5ccccc54)c32)cc1 ; c1ccc(-c2ccc(N3c4cc(-c5ccccn5)cc5c4B(c4c3cc(-c3ccccc3)c3c4oc4ccccc43)c3c(cc(-c4ccccc4)c4c3oc3ccccc34)N5c3ccc(-c4ccccc4)cc3)cc2)cc1] 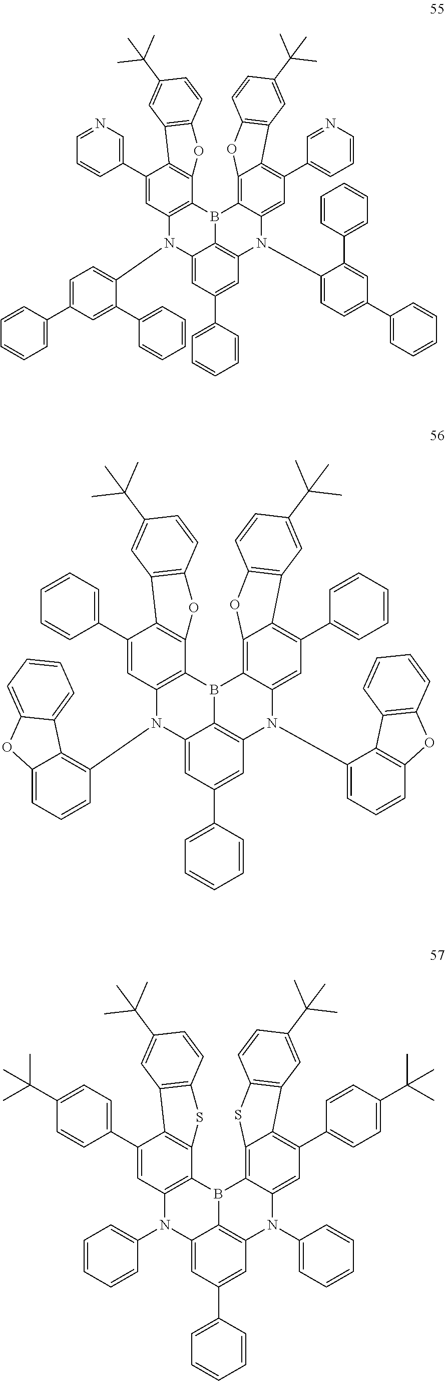 [SMILES: CC(C)(C)c1ccc2oc3c4c(cc(-c5cccnc5)c3c2c1)N(c1ccc(-c2ccccc2)cc1-c1ccccc1)c1cc(-c2ccccc2)cc2c1B4c1c(cc(-c3cccnc3)c3c1oc1ccc(C(C)(C)C)cc13)N2c1ccc(-c2ccccc2)cc1-c1ccccc1 ; CC(C)(C)c1ccc2oc3c4c(cc(-c5ccccc5)c3c2c1)N(c1cccc2oc3ccccc3c12)c1cc(-c2ccccc2)cc2c1B4c1c(cc(-c3ccccc3)c3c1oc1ccc(C(C)(C)C)cc13)N2c1cccc2oc3ccccc3c12 ; CC(C)(C)c1ccc(-c2cc3c(c4sc5ccc(C(C)(C)C)cc5c24)B2c4c(cc(-c5ccccc5)cc4N(c4ccccc4)c4cc(-c5ccc(C(C)(C)C)cc5)c5c(sc6ccc(C(C)(C)C)cc65)c42)N3c2ccccc2)cc1] 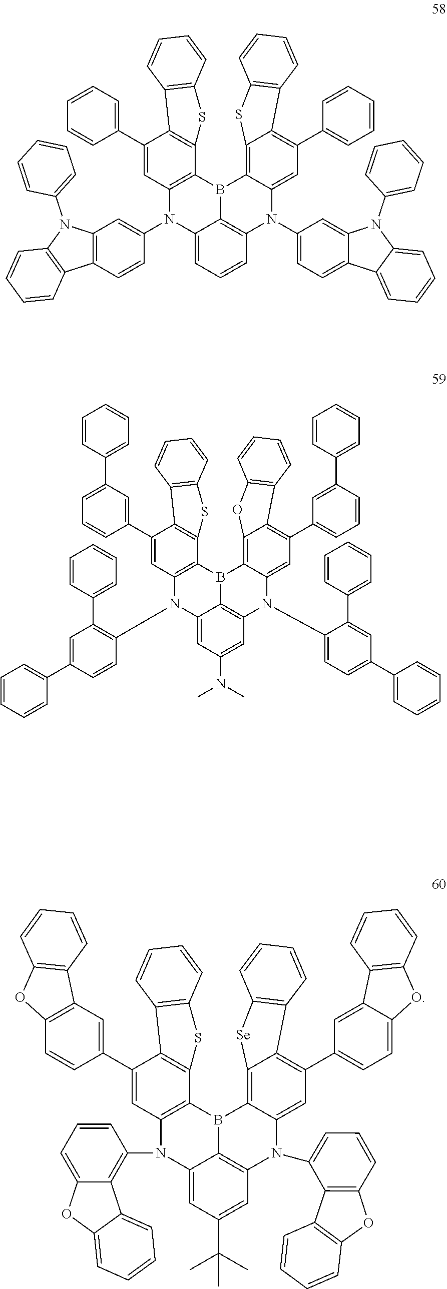 [SMILES: c1ccc(-c2cc3c(c4sc5ccccc5c24)B2c4c(cccc4N(c4ccc5c6ccccc6n(-c6ccccc6)c5c4)c4cc(-c5ccccc5)c5c(sc6ccccc65)c42)N3c2ccc3c4ccccc4n(-c4ccccc4)c3c2)cc1 ; CN(C)c1cc2c3c(c1)N(c1ccc(-c4ccccc4)cc1-c1ccccc1)c1cc(-c4cccc(-c5ccccc5)c4)c4c(sc5ccccc54)c1B3c1c(cc(-c3cccc(-c4ccccc4)c3)c3c1oc1ccccc13)N2c1ccc(-c2ccccc2)cc1-c1ccccc1 ; CC(C)(C)c1cc2c3c(c1)N(c1cccc4oc5ccccc5c14)c1cc(-c4ccc5oc6ccccc6c5c4)c4c([se]c5ccccc54)c1B3c1c(cc(-c3ccc4oc5ccccc5c4c3)c3c1sc1ccccc13)N2c1cccc2oc3ccccc3c12]
